(19) United States
(12) Patent Application Publication
(10) Pub. No.: US 2026/0297115 A1
(43) Pub. Date: Oct. 1, 2026

(54) STABLE LUMINESCENT AZABORAACENIUM IONS

(71) Applicant: University of Virginia Patent Foundation, Charlottesville, VA (US)

(72) Inventors: Robert Jerard Gilliard, Charlottesville, VA (US); Chunlin Deng, Charlottesville, VA (US); Akachukwu Daniel Obi, Charlottesville, VA (US); Samir Kumar Sarkar, Charlottesville, VA (US)

(73) Assignee: University of Virginia Patent Foundation, Charlottesville, VA (US)

(21) Appl. No.: 19/153,599

(22) PCT Filed: Feb. 9, 2024
(86) PCT No.: PCT/US2024/015211

§ 371 Date: Aug. 4, 2025

Related U.S. Application Data
(60) Provisional application No. 63/444,439, filed on Feb. 9, 2023.

(51) Int. Cl. C07F 5/02; C09K 11/06; G01N 21/64; H10K 10/00; H10K 10/46; H10K 30/30; H10K 50/11; H10K 85/60

(52) U.S. Cl. CPC C07F 5/027; C09K 11/06; G01N 21/6428; H10K 85/654; H10K 85/658; C09K 2211/1018; H10K 10/488; H10K 10/701; H10K 30/30; H10K 50/11

(57) ABSTRACT

The present disclosure provides luminescent compounds having air- and photo-stable azaboraacenium ions. The present compounds are stabilized by a variety of N-heterocyclic carbene or carbone ligands and can be useful in light-emitting materials and organic semiconductors.

### CROSS-REFERENCE TO RELATED APPLICATIONS

The present application claims priority to U.S. Provisional Patent Application No. 63/444,439 filed on Feb. 9, 2023, the entire content of which is hereby incorporated by reference.

### STATEMENT REGARDING FEDERALLY SPONSORED RESEARCH

This invention was made with government support under CHE2018870 awarded by the National Science Foundation. The government has certain rights in the invention.

### FIELD OF THE INVENTION

The disclosed technology is generally directed to air- and photo-stable cationic compounds. More particularly the technology is directed to azaboraacenium ions stabilized by electron donating ligands, such as carbodicarbenes.

### BACKGROUND OF THE INVENTION

Acenes are a type of polycyclic aromatic hydrocarbon (PAH) made up of linearly n annulated benzene rings. Higher order acenes (n≥4) are appealing for optoelectronic devices and applications for their narrow bandgap and energetically low-lying triplet state. Replacing a C═C of all-carbon acenes with a B—N unit (so called ‘B—N doping’) is an established approach for further tuning acene electronic characteristics. Unfortunately, all-carbon and B—N doped acenes are plagued with instability under ambient conditions, including photooxidation and/or photocyclization, due to high-lying highest occupied molecular orbital (HOMO) energy level and their increased open shell character. This instability restricts the use of higher order acenes in electronic devices. Further, cationic B—N doped acenes—even those stabilized by a central boron cation or by ligand coordination with N-heterocyclic carbene (NHC)—have been historically considered too unstable for use in optoelectronic materials applications.

Accordingly, the field widely recognizes the need for cationic B—N doped acenes displaying narrow band gaps and/or red emissive properties in combination with good air- and photo-stability.

### SUMMARY OF THE INVENTION

In one aspect, the present disclosure provides a compound of formula (I-a), (I-b), or (I-c),

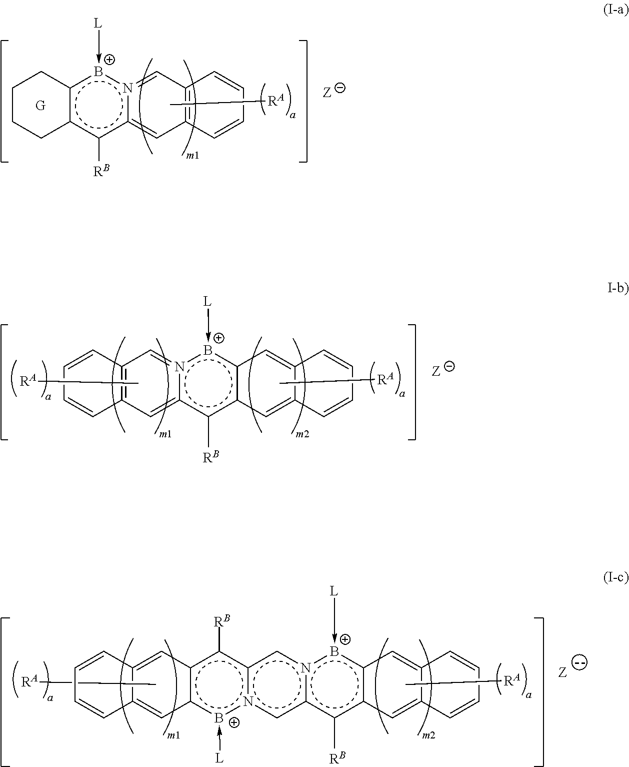

wherein

L is N-heterocyclic carbene (NHC) or a carbone having a structure of

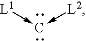

wherein each of L¹ and L² is independently a Lewis base;
G is a heteroaryl or heterocyclyl, which is optionally substituted;
R^{A} at each occurrence is independently alkyl, alkoxy, haloalkyl, aryl, cyano, halogen, N(R^{A1})(R^{A1}), S(R^{B}), or thiophenyl;
   R^{B} at each occurrence is independently hydrogen, alkyl, an optionally substituted aryl, or C≡CSi(R^{B1})₃;
R^{A1} at each occurrence is independently hydrogen, alkyl, or aryl, or two R^{A1} together with the nitrogen atom to which they are attached form a ring;
R^{B1} at each occurrence is independently alkyl;
a at each occurrence is independently 0-20;
m1 is 0-10;
m2 is 0-10; and
Z is a counterion.

The present disclosure also provides a method of preparing the compound of formula (I-a), (I-b), or (I-c) as described herein. The method can include reacting a compound of formula (II-a), (II-b), or (II-c), respectively, with L and M⁺Z⁻, thereby producing the compound of formula (I-a), (I-b), or (I-c), respectively,

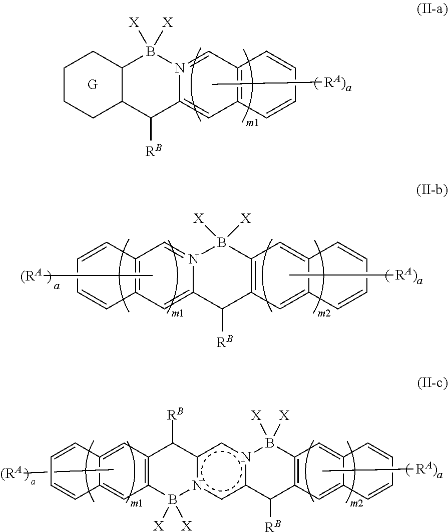

wherein X is halogen. M is a metal ion.

The present compounds can be air- and photo-stable and can be used in light-emitting materials, organic semiconductors, and photovoltaics. In another aspect, the present disclosure provides devices which incorporate the present compounds. For example, the device can be an organic field-effect transistor, a photoluminescence emitter device, a single molecule electrical device, a ratiometric biosensor, or a singlet fission device.

In another aspect, present disclosure also provides methods of using the compounds and devices as described herein, including a method for controlling the flow of an electric current, a method of producing electroluminescence, a method of transporting electrons, a method of detecting a target analyte, and a method of producing an electrical current using a singlet fission device.

### BRIEF DESCRIPTION OF THE DRAWINGS

Non-limiting embodiments of the present invention will be described by way of example with reference to the accompanying figures, which are schematic and are not intended to be drawn to scale. In the figures, each identical or nearly identical component illustrated is typically represented by a single numeral. For purposes of clarity, not every component is labeled in every figure, nor is every component of each embodiment of the invention shown where illustration is not necessary to allow those of ordinary skill in the art to understand the invention.

FIGS. 1A-1C show carbonaceous acenes, cationic BN-doped PAHs and azaboraacenium ions. FIG. 1A shows structures of common acenes with carbon atoms numbered and the correlation between energy gap and stability denoted. FIG. 1B shows examples of cationic BN-doped PAHs. The stated aromaticity refers to the BN-containing rings. FIG. 1C shows CDC azaboraacenium ions 1 and 2, and NHC azaboraacenium ions 3. i-Pr, isopropyl group; Cy, cyclohexyl group.

FIGS. 2A-2E show a synthetic scheme and single-crystal structures of azaboraacenium ions. FIG. 2A shows a synthetic route to 1-3 and 6. DCM, dichloromethane; MesMgBr, 2,4,6-trimethylphenylmagnesium bromide. FIGS. 2B-2E show molecular structure of 1b (FIG. 2B), 2a (FIG. 2C), 2b (FIG. 2D) and 3b (FIG. 2E) (with thermal ellipsoids at 30% probability for 1b and 2a and 50% for 2b and 3b; H atoms, counter-anions BPh₄⁻ and co-crystallized solvents are omitted for clarity). For the disordered atoms, only the component with the highest occupancy is shown. Selected bond lengths (Å) and angles (°): 2b: B1-C17 1.5600 (19), B1-N1 1.4568 (18), B1-C1 1.542 (2), C1-C6 1.4399 (18), C6-C7 1.4253 (19), C7-C8 1.362 (2), C8-C9 1.4404 (19), N1-C8 1.4216 (17), N1-C12 1.4013 (18), C11-C12 1.3384 (19), C10-C11 1.432 (2), C9-C10 1.344 (2), C17-C18 1.4100 (19), C17-C32 1.4268 (18), C18-C17-C32 116.29 (11); 3b: B1-C17 1.599 (4), B1-N1 1.439 (4), B1-C1 1.511 (4), C1-C6 1.449 (3), C6-C7 1.429 (4), C7-C8 1.363 (4), C8-C9 1.431 (4), C9-C10 1.346 (4), C10-C11 1.439 (4), C11-C12 1.342 (4), N1-C12 1.399 (3).

FIGS. 3A-3D show electronic structures. FIG. 3A shows FMOs of 1a. FIG. 3B shows molecular orbital diagram of 1b (calculated at the B3LYP-D3(BJ)/def2-TZVP level of theory, isovalue at 0.04 a.u.). FIG. 3C shows NICS (1)_{zz} values (calculated at the GIAO-B3LYP/pcSseg-2 level of theory and shown as the average value of NICS(+1)_{zz} and NICS(−1)_{zz}) and ACID plots (contribution from π electrons only) of 1a (left), 1b (middle) and 3a (right). The isovalue is 0.03, and the diamagnetic (clockwise) ring currents under the magnetic field parallel to the z axis are highlighted by arrows, the direction of the magnetic field is orthogonal to the BN-doped molecular plane and points upwards. FIG. 3D shows the localized orbital locator for π electrons (LOL-π) (calculated at the B3LYP-D3(BJ)/def2-TZVP level of theory) for the BN-doped molecular plane of 1a (left), 3a (center) and 6a (right). The colour bar ranges from 0 to 0.830 a.u., the about 0.500 a.u. band shows that π electrons within the bonds are effectively delocalized and about 0.800 a.u. colour indicates partial localization.

FIGS. 4A-4D show optoelectronic properties. FIG. 4A shows UV-vis absorption (solid line) and fluorescence (dashed line) spectra of 1, 2 and 3a under argon at 298 K. FIG. 4B shows images of toluene solutions of 1, 2 and 3a under 365 nm UV light irradiation (left), with images of the corresponding solids under ambient light (center) and 365 nm UV light irradiation (right). FIG. 4C shows emission spectra of 1a in 2-MeTHF (c=5×10−6 M) acquired at various temperatures. FIG. 4D shows energy level diagrams for 1b with SOC matrix elements between the pure spin states Sm (m=0, 1, 2, . . . ) and Tn (n=1, 2, . . . ) (Sₘ|Ĥ_{SO}|Tₙ). ĤSO denotes the spin-orbit Hamiltonian. ΔEST is the adiabatic energy gap between the S1 and T1 states.

FIGS. 5A-5D show stability evaluation. FIG. 5A shows solids of 3a, 1a, 2a, 2b and 1b (left to right) in vials submerged in water and exposed to air and UV light (365 nm). FIG. 5B shows absorbance-time profiles for cations 1a, 2a and 6a in air-equilibrated THF (0.04 mM) under ambient light conditions. A₀, initial absorbance; A, absorbance at different time intervals. FIG. 5C shows photographs of 6a (left) and 1a (right) in THE solutions at different time intervals (0.04 mM, sitting on top of a handheld 365 nm UV lamp with exposure to air). FIG. 5D shows the atomic orbital coefficients of carbon and boron of HOMOs (orbital energies in parentheses) in anthracene and 9,9a-BN anthracene 6a, 3a and 1a (left to right), calculated at the PCM(THF)-B3LYP-D3(BJ)/def2-TZVP level of theory. The blue and yellow circles refer to the reactive boron and carbon centers, respectively.

FIG. 6 shows variable temperature ¹H NMR (600 MHz, o-DCB-d₄) spectra for 1a. Peaks representing N—CH₃ and N—CH(CH₃)₂ protons split into several distinct signals at room temperature resulting from slowed rotation about the Ccarbone-Ccarbene bond with increased rotation of the C_{carbone}-C_{carbene} bonds and all of the respective peaks begin to coalesce at higher temperature and exist as one species. Note that compound 1a gradually decomposed above 100° C. (>10 min).

FIG. 7 shows UV-vis absorption (solid line) and fluorescence (dash line) spectra of anthracene, tetracene, 1a and 1b in toluene under argon at 298 K.

FIG. 8 shows a comparison of UV-vis absorption (top) and fluorescence (bottom) spectra of 1a, 2a and 6a in toluene at 298 K.

FIG. 9 shows solid fluorescence spectra of 1, 2 and 3a (in crystalline states, at 298 K).

FIG. 10 shows a CIE diagram of 1 and 3a in toluene [coordinates for 1a: (0.24, 0.54), 1b: (0.55, 0.44), 3a: (0.15, 0.17)] and solid states [coordinates for 1a: (0.28, 0.61), 1b: (0.63, 0.33), 3a: (0.14, 0.23)].

FIG. 11 shows a CIE diagram of 2 in toluene [coordinates for 2a: (0.22, 0.49), 2b: (0.54, 0.45)] and solid states [coordinates for 2a: (0.28, 0.61), 2b: (0.61, 0.39)].

FIGS. 12A-12B show atomic orbital coefficients of “C” and “B” in FIG. 12A (LUMOs) and FIG. 12B (HOMOs) and their orbital energies (in eV, calculated at the B3LYP-D3(BJ)/def2-TZVP level of theory in gas phase) for anthracene, 6a, 3a and 1a (from left to right). The coefficients of carbon and boron atoms are marked with light grey and dark grey circles, respectively. The higher stability of 1a vs 6a towards 02/light may be due to the significantly decreased energy levels of HOMOs and their atomic coefficients and on the reactive sites of acenes. The B atoms in 1a/2a have the most abundant atomic coefficients, which reflect their borenium characters.

FIGS. 13A-13B show atomic orbital coefficients of “C” and “B” in FIG. 13A (LUMOs) and FIG. 13B (HOMOs) and their orbital energies (in eV, calculated at the B3LYP-D3(BJ)/def2-TZVP level of theory in gas phase) for tetracene, 6b, 3b, 1b and 2b (from left to right). The coefficients of carbon and boron atoms are marked with light grey and dark grey circles, respectively. The higher stability of 1b/2b vs tetracene towards O₂/light may be due to the significantly decreased energy levels of FMOs and their atomic coefficients and on the reactive sites of acenes. The B atoms in 1b/2b have the most abundant atomic coefficients, which reflect their borenium characters.

FIGS. 14A-14B show TD-DFT calculations. FIG. 14A shows a comparison of the TD-DFT performance of B3LYP-D3(BJ), TPPSh-D3(BJ), PBE0-D3(BJ) and CAM-B3LYP-D3(BJ) using toluene as an implicit solvent. All the spectra have been normalized to compare with the experimental spectrum of 1b. All the spectra were obtained at the ma-def2-TZVP level of theory and were plotted using a full width at half maximum (FWHM) of 0.35 eV. It found that the CAM-B3LYP-D3(BJ) yield a very large error (>0.3 eV) on excitation energy and the relative intensity of experimental spectrum. FIG. 14B shows FOD plots (at σ=0.005 e Bohr⁻³, TPSS/def2-TZVP, Tel=5000 K) of 1a, 1b, anthracene, tetracene and pentacene.

FIGS. 15A-15B show air and moisture stability tests for azaboraacenium ions 1, 2 and 3a in solid states. FIG. 15A shows solids of 1, 2 and 3a in vials submerging/shaking with pure water and exposure to ambient atmosphere and light. FIG. 15B shows vials under UV light (365 nm) irradiation to monitor the solid decomposition. Based on their solid fluorescence change, these compounds are able to survive for at least one week under test conditions.

FIG. 16 shows plausible zwitterionic intermediate of the photooxygenation of 6a leading to compound 7. The base and B(OH)₃ could be generated from decomposing of BN-acene skeleton in varying degrees.

FIGS. 17A-17B show cyclic voltammograms of 1a (FIG. 17A) and 1b (FIG. 17B) (0.1 M Bu₄NPF₆ in THE, potential vs Fc/Fc⁺, scanning rate v=100 mV s⁻¹).

FIGS. 18A-18B show cyclic voltammograms of 2a (FIG. 18A) and 2b (FIG. 18B) (0.1 M Bu₄NPF₆ in THF, potential vs Fc/Fc⁺, scanning rate v=100 mV s⁻¹).

FIG. 19 shows a cyclic voltammogram of 6a (0.1 M Bu₄NPF₆ in CH₂Cl₂, potential vs Fc/Fc⁺, scanning rate v=100 mV s⁻¹).

### DETAILED DESCRIPTION OF THE INVENTION

Before the present invention is described in further detail, it is to be understood that the invention is not limited to the particular embodiments described. It is also understood that the terminology used herein is for the purpose of describing particular embodiments only and is not intended to be limiting. The scope of the present invention will be limited only by the claims. As used herein, the singular forms “a,” “an,” and “the: include plural embodiments unless the context clearly dictates otherwise.

It should be apparent to those skilled in the art that many additional modifications beside those already described are possible without departing from the inventive concepts. In interpreting this disclosure, all terms should be interpreted in the broadest possible manner consistent with the context. Variations of the term “comprising,” “including,” or “having” should be interpreted as referring to elements, components, or steps in a non-exclusive manner, so the referenced elements, components, or steps may be combined with other elements, components, or steps that are not expressly referenced. Embodiments referenced as “comprising” certain elements are also contemplated as “consisting essentially of” and “consisting of” those elements. When two or more ranges for a particular value are recited, this disclosure contemplates all combinations of the upper and lower bounds of those ranges that are not explicitly recited. For example, recitation of a value of between 1 and 10 or between 2 and 9 also contemplates a value of between 1 and 9 or between 2 and 10.

Definitions of specific functional groups and chemical terms are described in more detail below. For purposes of this disclosure, the chemical elements are identified in accordance with the Periodic Table of the Elements, CAS version, Handbook of Chemistry and Physics, 75th Ed., inside cover, and specific functional groups are generally defined as described therein. Additionally, general principles of organic chemistry, as well as specific functional moieties and reactivity, are described in Organic Chemistry, Thomas Sorrell, University Science Books, Sausalito, 1999; Smith and March March's Advanced Organic Chemistry, 5^{th} Edition, John Wiley & Sons, Inc., New York, 2001; Larock, Comprehensive Organic Transformations, VCH Publishers, Inc., New York, 1989; Carruthers, Some Modern Methods of Organic Synthesis, 3^{rd} Edition, Cambridge University Press, Cambridge, 1987; the entire contents of each of which are incorporated herein by reference.

The term “alkyl” as used herein refers to a saturated straight or branched hydrocarbon, such as a straight or branched group of 1-12, 1-10, or 1-6 carbon atoms, referred to herein as C₁-C₁₂ alkyl, C₁-C₁₀-alkyl, and C₁-C₆-alkyl, respectively.

The term “alkoxy” as used herein means an alkyl group, as defined herein, appended to the parent molecular moiety through an oxygen atom. Representative examples of alkoxy include, but are not limited to, C₁₋₆ alkoxy such as methoxy, ethoxy, propoxy, 2-propoxy, butoxy, tert-butoxy, pentyloxy, and hexyloxy.

The term “halogen” refers to halogen atoms F, Cl, Br, and I, or halogen substituents fluoro (—F), chloro (—Cl), bromo (—Br), and iodo-(—I).

The term “haloalkyl” refers to an alkyl group, as defined above, having halogen atoms, as defined above, replacing one or more hydrogen atoms. Representative haloalkyl groups include trifluoromethyl, dibromoethyl, monochloropropyl, and the like.

The term “aryl” refers to a carbocyclic aromatic group. Representative aryl groups include phenyl, naphthyl, and the like. The term “aryl” includes polycyclic ring systems having two or more carbocyclic rings in which two or more carbons are common to two adjoining rings (the rings are “fused rings”) wherein at least one of the rings is aromatic and, e.g., the other ring(s) may be cycloalkyls, cycloalkenyls, cycloalkynyls, and/or aryls.

The term “phenyl” refers to a monovalent benzene ring and has a formula of —C₆H₅.

The term “cycloalkyl” as used herein, means a monovalent group derived from an all-carbon ring system containing zero heteroatoms as ring atoms, and zero double bonds. The all-carbon ring system can be a monocyclic, bicylic, or tricyclic ring system, and can be a fused ring system, a bridged ring system, or a spiro ring system, or combinations thereof. Examples of cycloalkyls include, but are not limited to, cyclopropyl, cyclobutyl, cyclopentyl, cyclohexyl, cycloheptyl, cyclooctyl, and

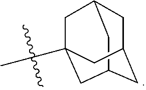 [SMILES: *C12CC3CC(CC(C3)C1)C2]

The cycloalkyl groups described herein can be appended to the parent molecular moiety through any substitutable carbon atom. The cycloalkyl can have 3-12, 3-8, 4-8, or 4-6 carbons (e.g., a “C₄₋₈ cycloalkyl” derived from a cycloalkane).

The term “heteroaryl” as used herein, means an aromatic heterocycle, i.e., an aromatic ring that contains at least one heteroatom selected from O, N, or S. A heteroaryl may contain from 5 to 12 ring atoms. The heteroaryl can include polycyclic ring systems having two or more rings in which two or more carbon or heteroatom are common to two adjoining rings (the rings are “fused rings”). For example, at least one of the rings is a heteroaryl and the other ring(s) are cycloalkyls or aryls. A heteroaryl may be a 5- to 6-membered monocyclic heteroaryl or an 8- to 12-membered bicyclic heteroaryl. A 5-membered monocyclic heteroaryl ring can contain two double bonds, and one, two, three, or four heteroatoms as ring atoms. Representative examples of 5-membered monocyclic heteroaryls include, but are not limited to, furanyl, imidazolyl, isoxazolyl, isothiazolyl, oxadiazolyl, oxazolyl, pyrazolyl, pyrrolyl, tetrazolyl, thiadiazolyl, thiazolyl, thienyl, and triazolyl. A 6-membered heteroaryl ring can contain three double bonds, and one, two, three or four heteroatoms as ring atoms. Representative examples of 6-membered monocyclic heteroaryls include, but are not limited to, pyridinyl, pyridazinyl, pyrimidinyl, pyrazinyl, and triazinyl. A bicyclic heteroaryl can be an 8- to 12-membered ring system having a monocyclic heteroaryl fused to an aromatic, saturated, or partially saturated carbocyclic ring, or fused to a second monocyclic heteroaryl ring. Representative examples of bicyclic heteroaryl include, but are not limited to, benzofuranyl, benzoxadiazolyl, 1,3-benzothiazolyl, benzimidazolyl, benzothienyl, indolyl, indazolyl, isoquinolinyl, naphthyridinyl, oxazolopyridine, quinolinyl, thienopyridinyl, 5,6,7,8-tetrahydroquinolinyl, and 6,7-dihydro-5H-cyclopenta[b]pyridinyl. The heteroaryl groups are connected to the parent molecular moiety through any substitutable carbon atom or any substitutable nitrogen atom contained within the groups.

The term “heterocycle,” “heterocyclyl,” or “heterocyclic” refers generally to ring systems containing at least one heteroatom as a ring atom where the heteroatom is selected from oxygen, nitrogen, and sulfur. In some embodiments, a nitrogen or sulfur atom of the heterocycle is optionally substituted with oxo. Heterocycles may be a monocyclic heterocycle, a fused bicyclic heterocycle, or a spiro heterocycle. The monocyclic heterocycle is generally a 4, 5, 6, 7, or 8-membered non-aromatic ring containing at least one heteroatom selected from O, N, or S. The 4-membered ring contains one heteroatom and optionally one double bond. The 5-membered ring contains zero or one double bond and one, two or three heteroatoms. The 6, 7, or 8-membered ring contains zero, one, or two double bonds, and one, two, or three heteroatoms. Representative examples of monocyclic heterocycle include, but are not limited to, azetidinyl, azepanyl, diazepanyl, 1,3-dioxanyl, 1,4-dioxanyl, 1,3-dioxolanyl, 4,5-dihydroisoxazol-5-yl, 3,4-dihydropyranyl, 1,3-dithiolanyl, 1,3-dithianyl, imidazolinyl, imidazolidinyl, isothiazolinyl, isothiazolidinyl, isoxazolinyl, isoxazolidinyl, morpholinyl, oxadiazolinyl, oxadiazolidinyl, oxazolinyl, oxazolidinyl, oxetanyl, piperazinyl, piperidinyl, pyranyl, pyrazolinyl, pyrazolidinyl, pyrrolinyl, pyrrolidinyl, tetrahydrofuranyl, tetrahydropyranyl, tetrahydrothienyl, thiadiazolinyl, thiadiazolidinyl, thiazolinyl, thiazolidinyl, thiomorpholinyl, 1,1-dioxidothiomorpholinyl, thiopyranyl, and trithianyl. The fused bicyclic heterocycle is a 7-12-membered ring system having a monocyclic heterocycle fused to a phenyl, to a saturated or partially saturated carbocyclic ring, or to another monocyclic heterocyclic ring, or to a monocyclic heteroaryl ring. Representative examples of fused bicyclic heterocycle include, but are not limited to, 1,3-benzodioxol-4-yl, 1,3-benzodithiolyl, 3-azabicyclo[3.1.0]hexanyl, hexahydro-1H-furo[3,4-c]pyrrolyl, 2,3-dihydro-1,4-benzodioxinyl, 2,3-dihydro-1-benzofuranyl, 2,3-dihydro-1-benzothienyl, 2,3-dihydro-1H-indolyl, 5,6,7,8-tetrahydroimidazo[1,2-a]pyrazinyl, and 1,2,3,4-tetrahydroquinolinyl. Spiro heterocycle means a 4-, 5-, 6-, 7-, or 8-membered monocyclic heterocycle ring wherein two of the substituents on the same carbon atom form a second ring having 3, 4, 5, 6, 7, or 8 members. Examples of a spiro heterocycle include, but are not limited to, 1,4-dioxa-8-azaspiro[4.5]decanyl, 2-oxa-7-azaspiro[3.5]nonanyl, 2-oxa-6-azaspiro[3.3]heptanyl, and 8-azaspiro[4.5]decane. The monocyclic heterocycle groups of the present invention may contain an alkylene bridge of 1, 2, or 3 carbon atoms, linking two nonadjacent atoms of the group. Examples of such a bridged heterocycle include, but are not limited to, 2,5-diazabicyclo[2.2.1]heptanyl, 2-azabicyclo[2.2.1]heptanyl, 2-azabicyclo[2.2.2]octanyl, and oxabicyclo[2.2.1]heptanyl. The monocyclic, fused bicyclic, and spiro heterocycle groups are connected to the parent molecular moiety through any substitutable carbon atom or any substitutable nitrogen atom contained within the group. The number of ring atoms in the heterocyclyl group can be specified using “x- to y-membered” nomenclature where x and y are integers specifying the number of ring atoms. For example, a 3- to 7-membered heterocyclyl group refers to a saturated or partially unsaturated 3- to 7-membered ring structure containing one to four heteroatoms, such as nitrogen, oxygen, and sulfur. The designation “3- to 7-membered” indicates that the heterocyclic ring contains a total of from 3 to 7 ring atoms, inclusive of any heteroatoms that occupy a ring atom position.

The term “thiophenyl” refers to a group of the formula

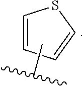

The term “cyano” refers to a group of the formula-CN.

The term “carbene” refers to a neutral divalent carbon species containing two electrons that are not shared with other atoms. In some embodiments, a carbene can have a form

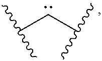

wherein 0, 1, or 2 hydrogen atoms can be replaced with an alkyl, cycloalkyl, aryl, heterocycloalkyl, or heteroaryl group as described herein.

The term “N-heterocyclic carbene” or “NHC” refers to a carbene that is a ring atom in a heterocycle comprising 1 to 5 nitrogen atoms. Examples of N-heterocyclic carbenes include, but are not limited to,

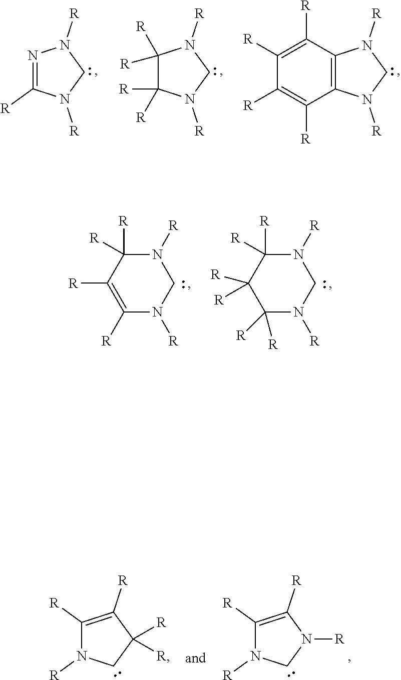

wherein, each R group is independently selected from H, alkyl, cycloalkyl, alkenyl, aryl, alkoxy, aryloxy, heterocycloalkyl, and heteroaryl.

The term “carbone” refers to a chemical species of a form

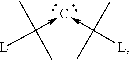

wherein the two-coordinated central carbon atom possesses only four electrons and the Lewis bases L bound to the central carbon provide the other four remaining electron to achieve octet stabilization in the system.

The term “Lewis base” refers to any species that can donate a pair of electrons. Examples of Lewis bases include, but are not limited to, (1)N-heterocyclic carbenes as described herein, (2) PR₃ wherein R is selected from alkyl, cycloalkyl, alkenyl, aryl, alkoxy, aryloxy, heterocycloalkyl, and heteroaryl, and (3) cyclic (alkyl) (amino) carbenes (CAACs). The term “cyclic (alkyl) (amino) carbene” refers to a cyclic carbene wherein one of the amino substituents of a diaminocarbene is replaced by at least one alkyl group. Examples of CAACs include, but are not limited to,

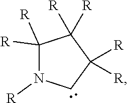

wherein each R group is independently selected from H, alkyl, cycloalkyl, alkenyl, aryl, alkoxy, aryloxy, heterocycloalkyl, and heteroaryl.

As used herein, the dashed circle in a six-membered ring in the formulae

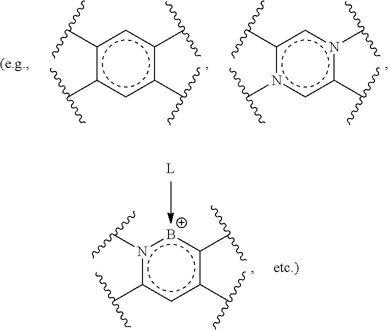

refers to an aromatic system.

As used herein, the term “counterion” refers to an ion or complex associated with a negative charge. Non-limiting examples of negatively charged counterions include fluoride, chloride, bromide, iodide, sulfate, phosphate, trifluoromethanesulfonate, acetate, nitrate; perchlorate, acetylacetonate, hexafluorophosphate, hexafluoroacetylacetonate, tetrafluoroborate, tetraphenylborate, hexafluoroantimonate, B[3,5-(CF₃)₂C₆H₃]₄^{⊖}, and B(C₆F₅)₄^{⊖}.

The compounds as described herein may be a resonance hybrid and can be represented by any contributing resonance structure thereof. For example, the following compound can be represented by any contributing resonance structure shown below:

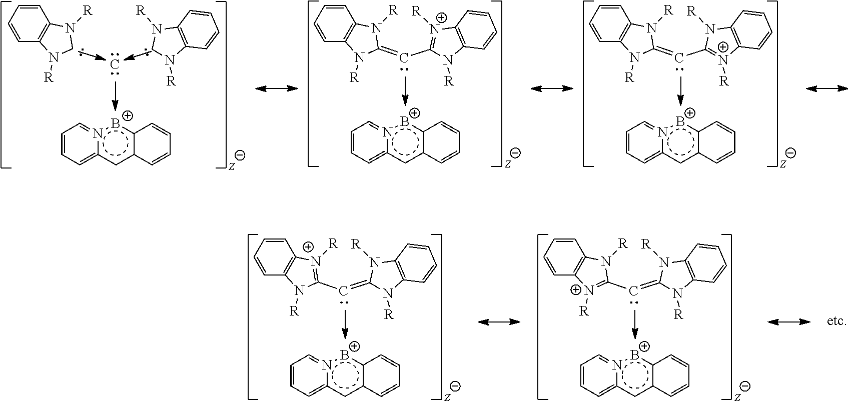

Terms such as “alkyl,” “alkoxy,” “haloalkyl,” “cycloalkyl,” and alike may be preceded by a designation indicating the number of atoms present in the group in a particular instance (e.g., “C₁-C₄alkyl,” “C₁₋₄alkyl,” or “C₃₋₆cycloalkyl”). These designations are used as generally understood by those skilled in the art. For example, the representation “C” followed by a subscripted number indicates the number of carbon atoms present in the group that follows. Thus, “C₃alkyl” is an alkyl group with three carbon atoms (i.e., n-propyl, isopropyl). Where a range is given, as in “C₁-C₄” or “C₁₋₄,” the members of the group that follows may have any number of carbon atoms falling within the recited range. A “C₁-C₄alkyl” or “C₁₋₄alkyl,” for example, is an alkyl group having from 1 to 4 carbon atoms, however arranged (i.e., straight chain or branched).

If a group is described as being “substituted”, a non-hydrogen substituent group is in the place of hydrogen radical on a carbon or nitrogen of that group. Thus, for example, a substituted alkyl is an alkyl in which at least one non-hydrogen radical is in the place of a hydrogen radical on the alkyl. To illustrate, monofluoroalkyl is alkyl substituted with a fluoro radical, and difluoroalkyl is alkyl substituted with two fluoro radicals. It should be recognized that if there is more than one substitution on a substituent, each non-hydrogen radical may be identical or different (unless otherwise stated). Substituent groups include, but are not limited to, halogen, ═O, ═S, cyano, nitro, fluoroalkyl, alkoxyfluoroalkyl, fluoroalkoxy, alkyl, alkenyl, alkynyl, haloalkyl, haloalkoxy, heteroalkyl, cycloalkyl, cycloalkenyl, aryl, heteroaryl, heterocycle, cycloalkylalkyl, heteroarylalkyl, arylalkyl, hydroxy, hydroxyalkyl, alkoxy, alkoxyalkyl, alkylene, aryloxy, phenoxy, benzyloxy, amino, alkylamino, acylamino, aminoalkyl, arylamino, sulfonylamino, sulfinylamino, sulfonyl, alkylsulfonyl, arylsulfonyl, aminosulfonyl, sulfinyl, —COOH, ketone, amide, carbamate, and acyl.

When a group is referred to as “unsubstituted” or not referred to as “substituted” or “optionally substituted”, it means that the group does not have any substituents. If a group is described as being “optionally substituted”, the group may be either (1) not substituted or (2) substituted. If a group is described as being optionally substituted with up to a particular number of non-hydrogen radicals, that group may be either (1) not substituted; or (2) substituted by up to that particular number of substituent groups or by up to the maximum number of substitutable positions on that group, whichever is less.

If substituents are described as being independently selected from a group, each substituent is selected independent of the other. Each substituent, therefore, may be identical to or different from the other substituent(s). A person of ordinary skill in the art would be able to choose the substituents that fulfill the valency rules. For example, in a non-solvated or non-salt form of a compound, nitrogen typically has three bonds attached to it and oxygen typically has two bonds attached to it.

The compounds of the present disclosure may contain one or more chiral centers and/or double bonds and, therefore, exist as stereoisomers, such as geometric isomers, enantiomers or diastereomers. The term “stereoisomers” when used herein consist of all geometric isomers, enantiomers or diastereomers. These compounds may be designated by the symbols “R” or “S,” depending on the configuration of substituents around the stereogenic carbon atom. The present invention encompasses various stereo isomers of these compounds and mixtures thereof. Stereoisomers include enantiomers and diastereomers. Mixtures of enantiomers or diastereomers may be designated “(±)” in nomenclature, but the skilled artisan will recognize that a structure may denote a chiral center implicitly. It is understood that graphical depictions of chemical structures, e.g., generic chemical structures, encompass all stereoisomeric forms of the specified compounds, unless indicated otherwise.

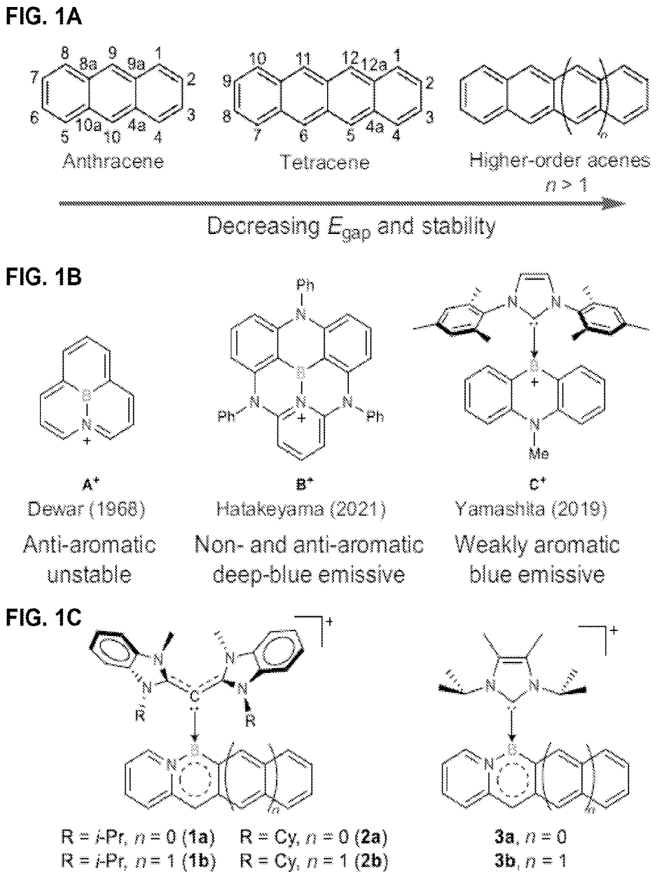

The present disclosure relates to the design, synthesis and molecular structures of fully π-conjugated cationic BN-doped acenes stabilized by electron donating ligands (e.g., carbodicarbene). Substitution of a C═C bond by an isoelectronic B—N bond may be to alter the electronic structure and stability of acenes. BN-substituted acenes that possess narrow energy gaps may have attractive optoelectronic properties (FIGS. 1A and 1B). However, they are susceptible to air and/or light. In contrast, the present compounds are luminescent in the solution and solid states and show high air and moisture stability (nonlimiting examples shown in FIG. 1C). Compared with their neutral BN-substituted counterparts as well as the parent all-carbon acenes, the present compounds display improved quantum yields and small optical gaps. In various embodiments, the electronic structures of the azabora-anthracene and azabora-tetracene cations resemble higher-order acenes while possessing high photo-oxidative resistance. The stability and photo-physics of these conjugated systems may be ascribed to their cationic nature and the electronic properties of the electron donating ligands.

### Compounds

In one aspect, the present disclosure provides a compound of formula (I-a), (I-b), or (I-c),

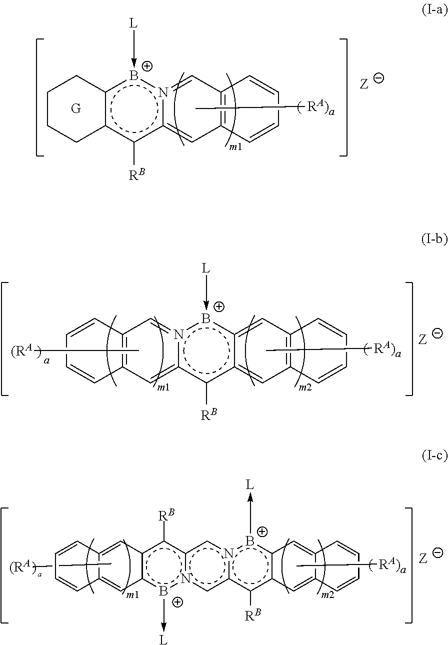

wherein
L is N-heterocyclic carbene (NHC) or a carbone having a structure of

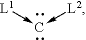

wherein each of L¹ and L² is independently a Lewis base;
G is a heteroaryl or heterocycle, which is optionally substituted;
R^{A} at each occurrence is independently alkyl, alkoxy, haloalkyl, aryl, cyano, halogen, N(R^{A1})(R^{A1}), S(R^{B}), or thiophenyl;
R^{B} at each occurrence is independently hydrogen, alkyl, an optionally substituted aryl, or C═CSi(R^{B1})₃;
R^{A1} at each occurrence is independently hydrogen, alkyl, or aryl, or two R^{A1} together with the nitrogen atom to which they are attached form a ring;
R^{B1} at each occurrence is independently alkyl;
a at each occurrence is independently 0-20;
m1 is 0-10;
m2 is 0-10; and
Z is a counterion.

As used herein, Z [symbol] includes both Z²⁻, in which Z is a doubly charged anion, and [Z⁻]₂, in which Z is a singly charged anion.

As used herein, —(R^{A}) a refers to a substituent on any fused aromatic ring indicated by “m1” and “m2” or a substituent on a terminal aromatic ring of the aromatic ring system in formula (I-a), (I-b), and (I-c).

G can be a heteroaryl or heterocycle, which is optionally substituted by one or more R^{G}, wherein R^{G} at each occurrence is independently alkyl, aryl, cycloalkyl, haloalkyl, halogen, or two adjacent R^{G} form a ring. In some embodiments, G is not substituted. In some embodiments, G is substituted with one, two, three, or four R^{G}, and R^{G} at each occurrence is independently alkyl, aryl, haloalkyl, or halogen. In some embodiments, G is substituted with two, three, or four R^{G} and two adjacent R^{G} form a ring.

In some embodiments, the compound is a compound of formula (I-a-i) or (I-c-i)

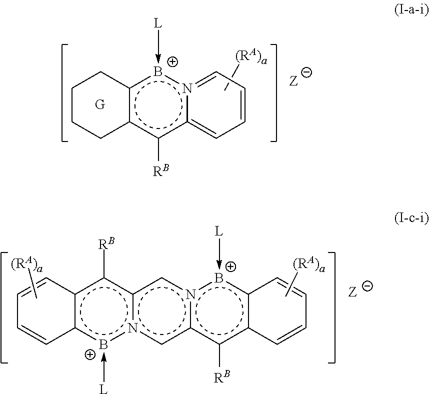

wherein a at each occurrence is independently 0, 1, 2, 3, or 4.

For example, in compounds of formula (I-a-i), a can be 0 or 1. For example, in compounds of formula (I-c-i), a can be 0 or 1.

In some embodiments, the compound is a compound of formula (I-b), wherein m2 is 0 or 1.

In some embodiments, the compound is a compound of formula (I-b), wherein m1 is 0 or 1 and m2 is 0 or 1. In some embodiments, m1 is 0 and m2 is 0 and the compound has a formula:

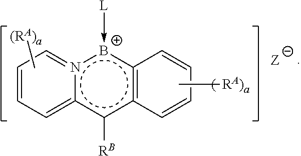

In some embodiments, m1 is 0 and m2 is 1 and the compound has a formula:

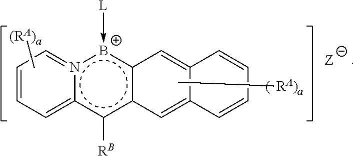

In some embodiments, the compound is a compound of formula (I-b-i)

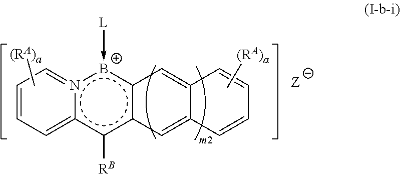

wherein
   a at each occurrence is independently 0, 1, 2, 3, or 4; and
   m2 is 0 or 1.

In some embodiments, the compound is a compound of formula (I-b-i), wherein a at each occurrence is 0. In some embodiments, the compound of formula (I-b-i) has a formula

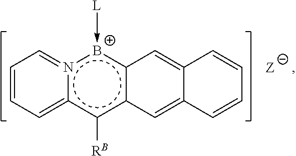

wherein a is 0 and m2 is 1. In some embodiments, the compound of formula (I-b-i) has a formula

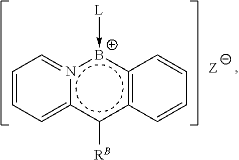

wherein a is 0 and m2 is 0.

In some embodiments, R^{A} at each occurrence in the compounds as described herein is independently OMe, CN, CF₃, NMe₂, SMe, NPh₂, halogen, or Ph.

In some embodiments, R^{B} is hydrogen,

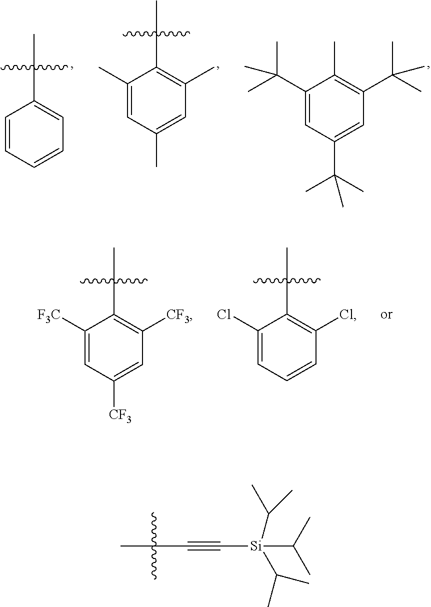

in the compounds as described herein.

In some embodiments, L in the compounds as described herein is an N-heterocyclic carbene (NHC) of

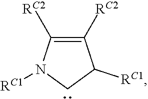

wherein
R^{C1} at each occurrence is independently alkyl, cycloalkyl, optionally substituted aryl, or optionally substituted heteroaryl;
R^{C2} at each occurrence is independently alkyl, cycloalkyl, optionally substituted aryl, or optionally substituted heteroaryl; or
R^{C1} and adjacent R^{C2}, together with the nitrogen and carbon atoms to which they are attached, respectively, form a ring; or
two adjacent R^{C2}, together with the carbon atoms to which they are attached form a ring.

In some embodiments, R^{C1} at each occurrence is independently alkyl, such as C₁₋₄ alkyl. In some embodiments, R^{C1} at each occurrence is independently an optionally substituted aryl or an optionally substituted heteroaryl. In some embodiments, R^{C1} at each occurrence is independently methyl, isopropyl, cyclohexyl, or 2-pyridinyl. In some such embodiments, R^{C1} is isopropyl.

In some embodiments, R^{C2} at each occurrence is independently alkyl, such as C₁₋₄ alkyl. In some embodiments, R^{C2} at each occurrence is independently an optionally substituted aryl or an optionally substituted heteroaryl. In some embodiments, R^{C2} at each occurrence is independently methyl, isopropyl, cyclohexyl, or 2-pyridinyl. In some such embodiments, R^{C2} is methyl.

In some embodiments, two adjacent R^{C2}, together with the carbon atoms to which they are attached form a ring, such as an aromatic ring or a heteroaromatic ring. In some embodiments, L is

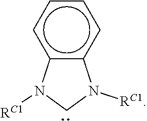

In some embodiments, L is

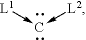

wherein
each of L¹ and L² is independently

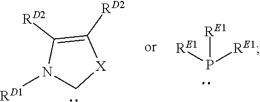

X is NR^{D1} or C(R^{D1}) (R^{D1});
R^{D1} at each occurrence is independently alkyl, cycloalkyl, optionally substituted aryl, or optionally substituted heteroaryl;
R^{D2} at each occurrence is independently alkyl, cycloalkyl, optionally substituted aryl, or optionally substituted heteroaryl; or
R^{D1} and adjacent R^{D2}, together with the nitrogen and carbon atoms to which they are attached, respectively, form a ring; or
two adjacent R^{D2}, together with the carbon atoms to which they are attached form a ring;
R^{E1} at each occurrence is independently alkyl, cycloalkyl, optionally substituted aryl, or optionally substituted heteroaryl; or
two or three R^{E1} together with the phosphorus atom to which they are attached form a ring.

In some embodiments, each of L¹ and L² is independently

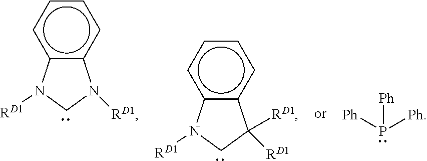

In some embodiments, L is

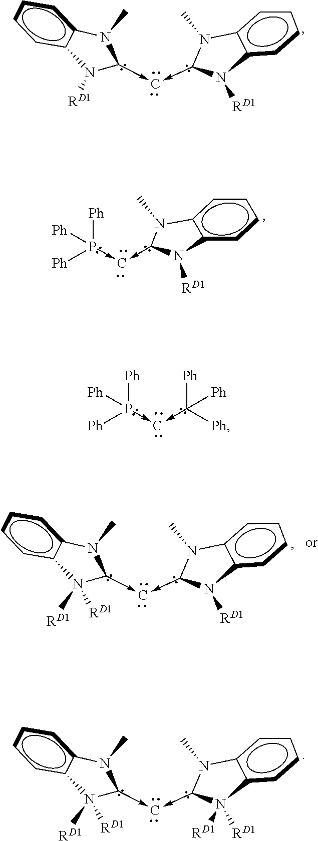

In some embodiments, R^{D1} in L at each occurrence is independently methyl, isopropyl, cyclohexyl, or 2-pyridinyl.

In some embodiments, L is

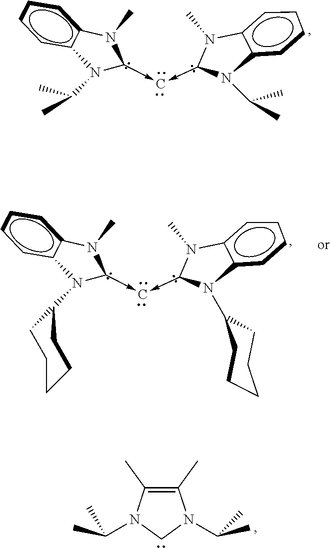

In some embodiments, the compound is

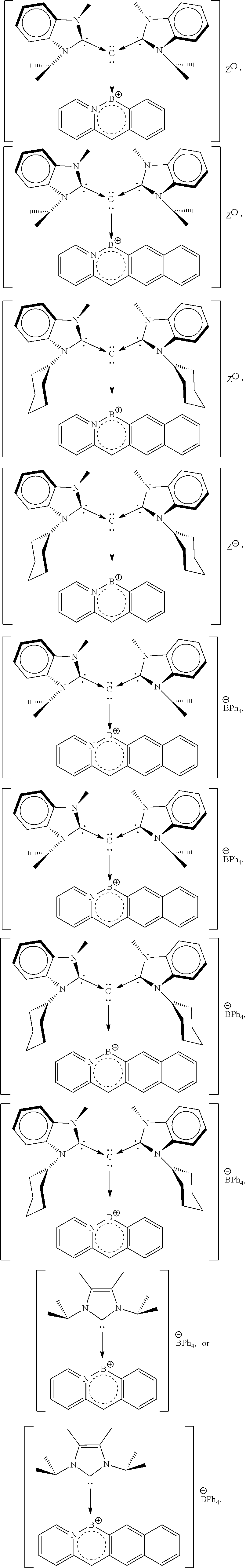

In some embodiments, Z is Cl, Br, BF₄, BPh₄, PF₆, SbF₆, B[3,5-(CF₃)₂C₆H₃]₄, or B(C₆F₅)₄.

In some embodiments, Z is BPh₄.

In some embodiments, the compound is

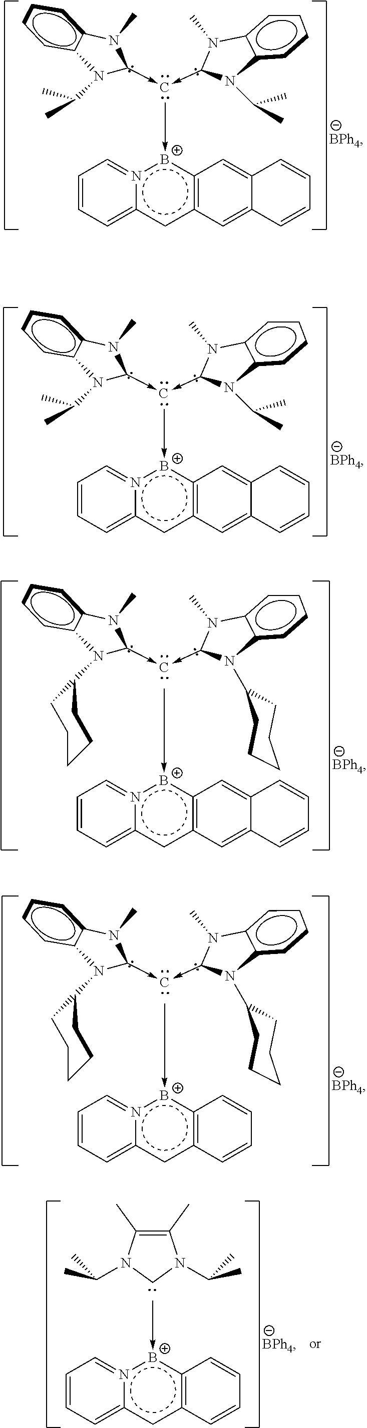

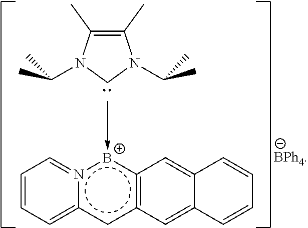

### Methods of Preparing the Compounds

Another aspect of the disclosure provides a method of preparing the compound of formula (I-a), (I-b), or (I-c). The method comprises reacting a compound of formula (II-a), (II-b), or (II-c), respectively, with L and M⁺Z⁻, thereby producing the compound of formula (I-a), (I-b), or (I-c), respectively

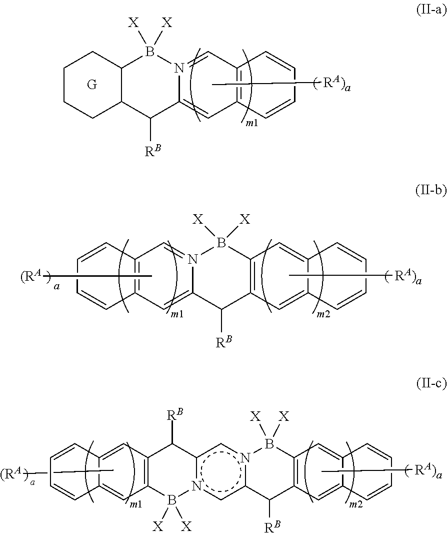

wherein
   X is halogen; and
   M is a metal ion.

In some embodiments, L is mixed with the compound of formula (II-a), (II-b), or (II-c) first to form an intermediate of formula (V-a), (V-b), or (V-c), respectively

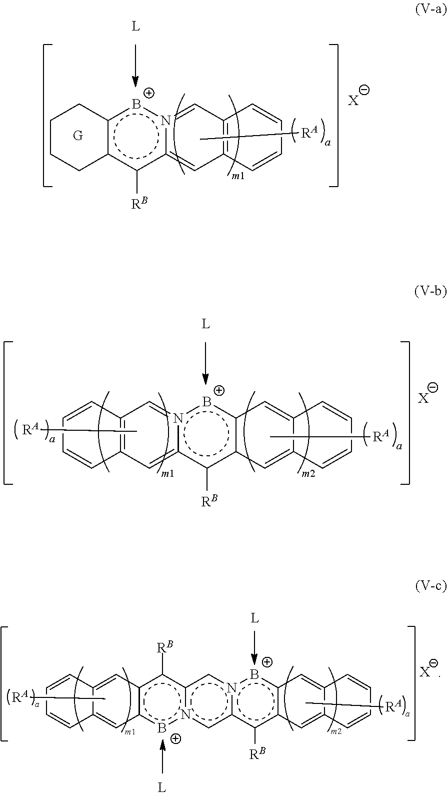

In some embodiments, M⁺Z is added to the intermediate of formula (V-a), (V-b), or (V-c), respectively, to form the compound of formula (I-a), (I-b), or I (c), respectively.

In some embodiments, the intermediate of formula (V-a), (V-b), or (V-c) is not isolated from the reaction mixture before the addition of M⁺Z⁻.

In some embodiments, the reaction of the compound of formula (II-a), (II-b), or (II-c) with L and M⁺Z⁻ is carried out under a light-free condition.

In some embodiments, the reaction of the compound of formula (II-a), (II-b), or (II-c) with L and M⁺Z⁻ is carried out at a temperature of 0-30° C. In some embodiments, the reaction of the compound of formula (II-a), (II-b), or (II-c) with L and M⁺Z⁻ is carried out at room temperature (e.g., 23° C.).

In some embodiments, the method further comprises converting a compound of formula (III-a), (III-b), or (III-c) to the compound of formula (II-a), (II-b), or (II-c), respectively

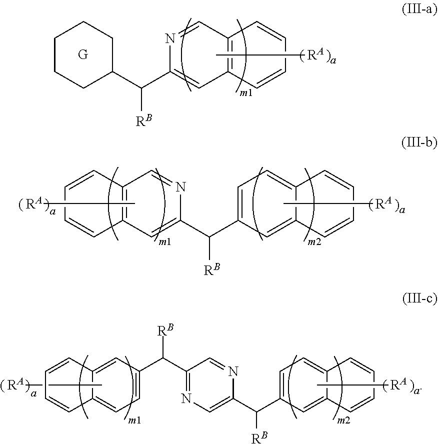

In some embodiments, the method comprises converting the compound of formula (III-a), (III-b), or (III-c) to the compound of formula (II-a), (II-b), or (II-c), respectively, then reacting the compound of formula (II-a), (II-b), or (II-c) with L and M⁺Z⁻, thereby producing the compound of formula (I-a), (I-b), or (I-c), respectively.

In some embodiments, the method comprises mixing the compound of (III-a), (III-b), or (III-c) with BX₃ to produce the compound of formula (II-a), (II-b), or (II-c), respectively. In some embodiments, the method comprises mixing the compound of formula (III-a), (III-b), or (III-c) with pinacolborane (HBPin) in the presence of a transition metal catalyst. In some embodiments, the transition metal catalyst comprises Iridium. In some embodiments, the transition metal catalyst comprises [Ir(OMe)(COD)]₂. In some embodiments, the mixing is carried out at a temperature from 0 to 30° C. In some embodiments, the mixing is carried out at room temperature. In some embodiments, the mixing is carried out in a non-polar solvent. In some embodiments, the non-polar solvent comprises hexane.

In some embodiments, the method comprises converting the compound of (III-b) to the compound of formula (II-b), then reacting the compound of formula (II-b) with L and M⁺Z⁻, thereby producing the compound of formula (I-b).

In some embodiments, the method comprises converting the compound of formula (III-b) to a compound of formula (IV-b), then converting the compound of formula (IV-b) to the compound of formula (II-b)

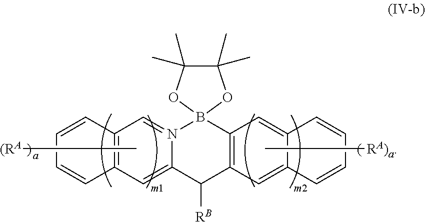

In some embodiments, the compound of formula (I-a), (I-b), or (I-c) can be synthesized by following the synthetic route below:

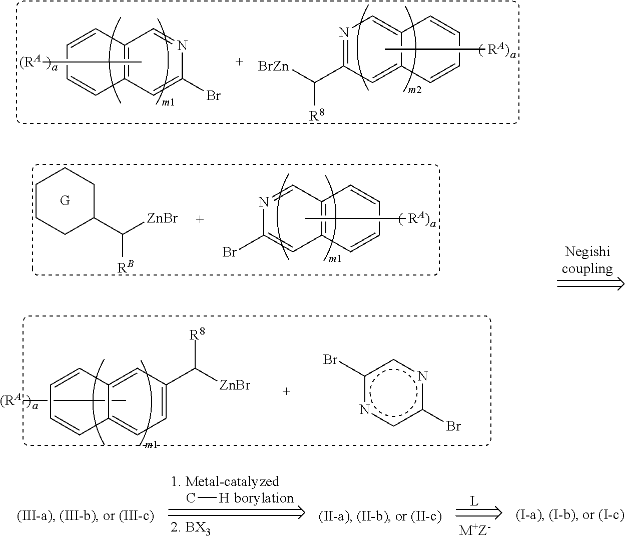

In some embodiments, the compound of formula (I-b) can be synthesized by following the synthetic route below:

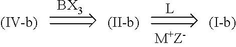

In some embodiments, m1 is 0 in the compounds of the preparation methods as described herein.

In some embodiments, a is 0 in the compounds of the preparation methods as described herein.

In some embodiments, m2 is 0 or 1 in the compounds of the preparation methods as described herein.

In some embodiments, R^{B} is hydrogen in the compounds of the preparation methods as described herein.

In some embodiments, L is

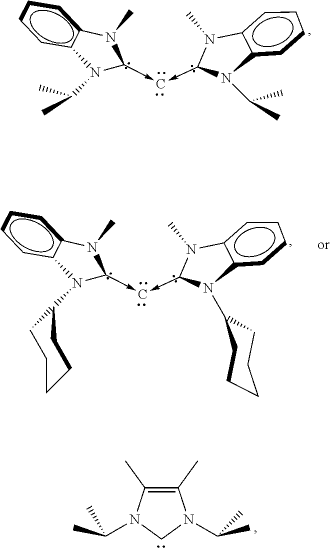

in the compounds of the preparation methods as described herein.

In some embodiments, the compound of formula (I-b) is

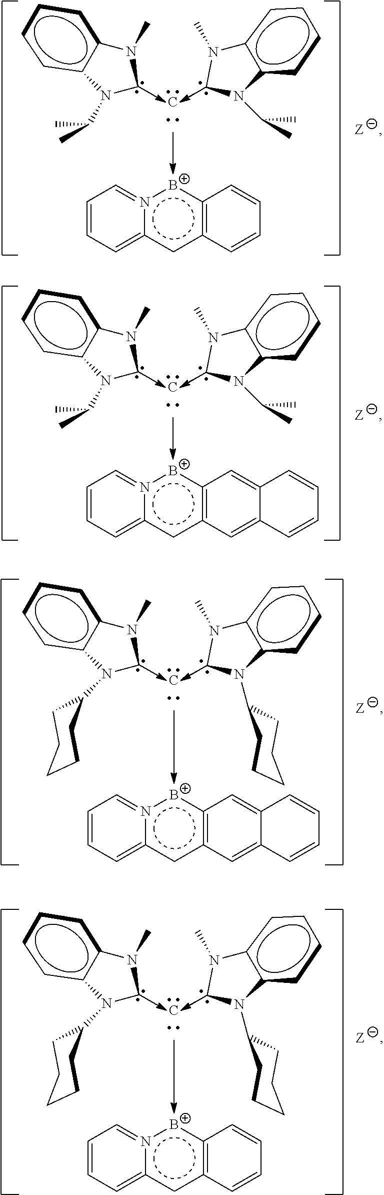

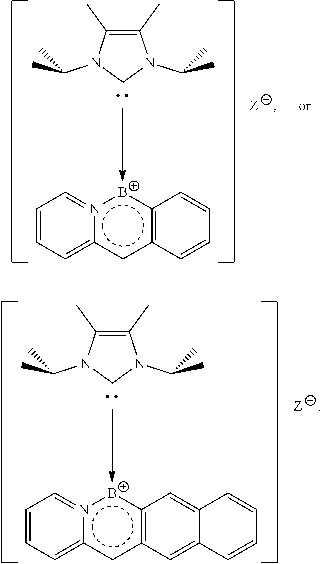

In some embodiments, Z is BPh₄ in the compounds produced from the preparation methods as described herein.

In some embodiments, X is Br or Cl. In some embodiments, X is Cl.

### Devices and Uses

Acenes are a classic type of polycyclic aromatic hydrocarbon (PAH) made up of linearly n annulated benzene rings (FIG. 1A). Among them, anthracene (n=3) and its derivatives are useful building blocks for light-emitting materials and organic semiconductors. However, they emit exclusively in the near-ultraviolet to blue wavelength regime and suffer drawbacks such as quenched fluorescence in the crystalline state and photo-induced dimerization and/or oxidation. The extended acenes such as tetracene (n=4) and pentacene (n=5) possess narrow band gaps and energetically low-lying triplet states. They are found in practical applications related to various optoelectronic devices, including organic field-effect transistors, organic light-emitting diodes, and singlet exciton fission-based solar cells. Despite these positive attributes, they are substantially less stable than anthracene owing to their high-lying highest occupied molecular orbital (HOMO) energy levels and increased open-shell character, resulting in an enhanced propensity to undergo photo-oxidation and/or photo-cyclization. In the solution state, tetracene has a half-life of 1 h and pentacene photodegrades within minutes when exposed to light and/or air. These shortcomings engender operational restrictions in the fabrication, usage and performance parameters of high-order acenes in electronic devices.

The isoelectronic replacement of a C═C bond in all-carbon acenes with a B—N unit has emerged as a powerful tool to develop novel acenes with tunable electronic features. The position and orientation of BN doping in PAH systems greatly affect their stability and can elicit desirable properties such as small band gaps and/or reduced molecular orbital energy levels. In particular, it has been reported that BN doping of anthracene at the 9,9a position induced a substantial bathochromic shift in its electronic absorption spectra, which provides a simple yet crucial way to access the low-energy band gap properties of extended acenes. Unfortunately, this modification also resulted in a HOMO level energetically comparable to that of tetracene, leading to BN acenes that are highly unstable towards air and/or light (vide infra). Moreover, stable π-extended tetracenes (for example, 12,12a-BN-tetracene) are even more arduous to realize experimentally as they possess elevated HOMO energy levels resembling pentacene. A 2,1-BN-tetracene isostere was disclosed that proved to be less light sensitive in the absence of oxygen compared with the parent tetracene. However, this type of BN doping resulted in a loss of the attractive narrow energy gap characteristics of extended acenes, inducing blue-shifted electronic spectra as a result of the reduced global π delocalization. In fact, it is difficult to tune the emission wavelengths of air-stable BN-doped acenes into the red region, even for high-order BN-acene systems. Thus, achieving the narrow band gap and/or red emissive properties of BN-doped acenes while simultaneously maintaining their ambient stability remains challenging, and this dilemma is often encountered in carbonaceous acenes as well.

Although a large number of neutral BN-doped acenes and other PAHs have been reported, investigations of cationic BN-PAHs are rare. The latter is particularly intriguing since the cationic boron atom would possess enhanced Lewis acidity and electron accepting ability (leading to n-type materials) while the isoelectronic B—N moiety would maintain global π delocalization on the PAH backbone. However, despite the fact that cationic boron species such as borenium ions have been widely employed as main group (pre-) catalysts, historically, they have been too unstable for optoelectronic materials-related applications. In 1958, Dewar unveiled the pioneering synthesis of the cationic BN-doped PAH A⁺, albeit with incomplete characterization owing to its high instability. To stabilize these species, two main molecular design approaches have been reported. Hatakeyama et al. developed a method for the synthesis of sufficiently air-stable cationic BN-embedded PAH B⁺ by incorporation of a boron cation into the center of an electron-rich framework, which attenuates the electrophilicity of B⁺ by dispersing the positive charge over the entire molecule (FIG. 1B). Yamashita and coworkers recently disclosed an N-methylated 9-aza-10-boraanthracene cation C⁺ stabilized by an N-heterocyclic carbene (NHC). The ligand coordination approach has advantages such as less synthetic demand and facile modulations of the electronic structures owing to the widespread availability of neutral coordinating ligands. Nevertheless, NHC-stabilized borenium complexes are often extremely air and moisture sensitive and thermally unstable in solution. It is worth noting that the 1,4-azaborine-embedded moieties in B⁺ and C⁺ lead to less effective delocalization of π electrons, acting as push-pull π electron systems rather than polycyclic aromatic molecules (FIG. 1B). Hence, the absorption and fluorescence maxima of B⁺ were blue-shifted relative to its carbon analogues, while C⁺ only exhibited a modest red-shift in optical spectroscopic features compared with anthracene. In view of these limitations, new strategies for the preparation of stable and luminescent cationic BN-doped PAHs with narrow energy gaps remain in high demand.

Carbodicarbenes (CDCs) are a special class of divalent carbon (0) compounds possessing two NHC fragments32,33. The two lone pairs on C0 render robust σ donation compared with the broadly explored NHCs, making CDCs highly potent ligands in coordination chemistry and catalysis. However, exploitation of their superior electron donating and stabilizing properties for optoelectronic applications is still in its infancy. The preparation and optical characterization of CDC-borafluorenium ions was recently described, which highlighted CDCs as effective supporting ligands for the development of temperature-responsive materials. Without being limited by any theory, it is hypothesized that CDCs would provide adequate thermodynamic (via its robust σ donation) and kinetic (via its steric profile) stabilization, necessary to synthesize cationic BN-acenes. Based on computations, the present disclosure further hypothesized that cationic BN-acenes would have decreased HOMO and the lowest unoccupied molecular orbital (LUMO) levels, potentially increasing their stability towards air and light.

The present disclosure provides the efficient modular synthesis, molecular and electronic structures, photophysical studies and photochemical stability assessments of a series of azaboraanthracenium ions (1a, 2a and 3a; FIG. 1C) stabilized by CDCs and NHC, respectively. Employing a similar strategy, the extended azaboratetracenium ions (1b and 2b) were also successfully prepared. Remarkably, these compounds represent rare examples of air- and light-stable, water-tolerant, highly luminescent and fully π-conjugated group 13 cationic PAHs. Moreover, ligand/(BN)+-acene variation permits tunable blue to red emission in both the solution and solid states, with improved quantum yields (QYs) compared with their all-carbon analogues. Detailed stability tests indicate that the CDC-azaboraacenium ions are more stable to air and ambient light than their parent carbonaceous acenes and neutral BN congeners.

Advantageously, the air- and photo-stabilities of the present compounds enable their use in light-emitting materials and organic semiconductors. In various implementations, the present disclosure provides devices which incorporate the present compounds, including an organic field-effect transistor, a photoluminescence emitter device, a single molecule electrical device, a ratiometric biosensor, and a singlet fission device.

In one aspect, the present disclosure provides an organic field-effect transistor (OFET) device, which can include a source terminal, a drain terminal, and a semiconductor channel including the compounds described herein, and a gate terminal. The compounds are in electrical connection with the source terminal and the drain terminal. A gate terminal is proximal to the semiconductor channel and electrically isolated from each of the source terminal, drain terminal, and semiconductor channel. The architecture of the OFET devices disclosed herein may include OFET architectures already known and described elsewhere in the art, including metal-oxide-semiconductor field-effect transistor (MOSFET), insulated-gate field-effect transistor (IGFET), metal-insulator-semiconductor field-effect transistor (MISFET), metal-semiconductor field-effect transistor (MESFET), or thin-film transistor (TFT). The semiconductor channel, which includes a compound as described herein, may be a single crystalline or a polycrystalline material. In some cases, the semiconductor channel may be deposited on a substrate. In some cases, the substrate may serve as the gate terminal. In some cases, the substrate may be silicon or thermally oxidized silicon, in which case the silicon dioxide may serve to electrically isolate the gate terminal from each of the source terminal, the drain terminal, and the semiconductor channel. In other cases, the substrate may be insulating, such as glass. The semiconductor channel may be deposited on the substrate using any techniques known in the field of OFET manufacturing, including thermal evaporation, coating from a solution (i.e., dip-coating, spin-coating, inkjet printing, screen printing), or electrostatic lamination. The semiconductor channel may use either electrons (n-channel) or holes (p-channel) as charge carriers. The drain terminal and the source terminal may be constructed from electrically conductive materials known in the field of OFETs, including metals, and may form ohmic contacts with the semiconductor channel.

In another aspect, the present disclosure provides a photoluminescent emitter, which can include an anode, a cathode, and an emissive layer comprising the compounds as described herein. The photoluminescent emitter may be an organic light-emitting diode (OLED). The emissive layer electrically connects the anode and the cathode. In some cases, the anode, cathode, and emissive layer, containing one or more of the compounds disclosed herein, may be deposited on a substrate. The emissive layer, which includes a compound as described herein, may be a single crystalline or a polycrystalline material. In some cases, the of the photoluminescence emitters disclosed herein may include OLED structures already known and described elsewhere in the art, including a single-layer OLED (e.g., a single emissive layer positioned between a cathode and an anode), a bilayer OLED (e.g., two layers positioned between a cathode and an anode, at least one of which may be an emissive layer including at least one of the compounds disclosed herein), and a multilayer OLED (e.g., e.g., three or more layers positioned between a cathode and an anode, at least one of which may be an emissive layer including at least one of the compounds disclosed herein). The photoluminescence emitter disclosed herein may have other OLED architectures, including bottom-emission OLED (BE-OLED), top-emission OLED (TE-OLED), transparent OLED, semi-transparent OLED, graded heterojunction OLED, stacked OLEDs, or inverted OLED.

In another aspect, the present disclosure provides a single molecule electrical device, which can include a first electrode, a second electrode, and a molecular backbone which includes a compound as described herein. The compound is covalently attached to the first electrode and to the second electrode, forming an electrically conductive connection. The first electrode and second electrode may be constructed from electrically conductive materials, such as one or more metals. Various chemistries can be used to covalently functionalize the first electrode and/or the second electrode with the one or more compounds disclosed herein. For example, in some cases, the first electrode and/or the second electrode may be gold and the one or more compounds disclosed herein may be further functionalized with one or more thiols, such as an alkane thiol. In some cases the alkane thiol may include methanethiol. The favorable formation of at least one thiol-gold bond may be used to covalently bind the one or more compounds to the first electrode and/or the second electrode. As nonlimiting examples, the present compounds of formula (I-a), (I-b), or (I-c), or their precursors such as compounds of formula (V-a), (V-b), or (V-c), can be covalently attached to the first or second electrode via a thiol group, a thiol ether group, or an equivalent thereof (e.g., at the R^{A} substituent). For example, the compound can form a thiol ether linkage with the electrode.

In another aspect, the present disclosure provides a ratiometric biosensor, which can include a photoluminescent substrate including a compound as described herein. The photoluminescent substrate can have a first optical emission and a second optical emission emitted in the presence of a target analyte. In some cases, the first optical emission is identifiable in emission wavelength and/or intensity from the second optical emission. The ratiometric biosensor may include an excitation source capable of exciting the photoluminescent substrate, including at least one compound disclosed herein, to produce the first emission and/or the second emission. The ratiometric biosensor may further include a detector. The detector may be a single channel (a single wavelength) or multichannel (multiple wavelength) detector, a CCD array, a photomultiplying tube (PMT), or a similar detector capable of converting photons to electrical signals. In some cases, the excitation of the photoluminescence substrate to produce the first optical emission and/or second optical emission may include an optical excitation source (e.g., a laser, a light emitting diode, an incandescent lamp, an arc lamp, a flash lamp, a halogen lamp, or other illumination sources known in the field of photoluminescence).

In another aspect, the present disclosure provides a singlet fission device capable of converting a singlet excited state into a spin-correlated triplet-pair state to generate a quintet state in one or more of the compounds disclosed herein. These devices may be capable of converting high-energy, above bandgap incident photons—which would otherwise lose energy by thermalization—into multiple lower energy photons (i.e., forming triplet excitons) within or closer to the band edge of the semiconductor. In some cases, the singlet fission device may be a photovoltaic device, such as an organic photovoltaic device (e.g, an organic solar cell), including a singlet fission layer including at least one of the compounds disclosed herein, a solar cell layer comprising a semiconductor and electrical contacts, a transition layer positioned between the singlet fission layer and the solar cell layer. The solar cell layer may include one or more semiconductors, such as silicon. In some cases, the solar cell layer may include a silicon heterojunction solar cell. In some cases, the singlet fission layer may produce photons (i.e., singlet fission photons) which are energetically matched (e.g. substantially equal to) to the bandgap of the semiconductor of the solar cell layer, thereby increasing the solar cell layer's efficiency by reducing energy loss to thermalization. The transition layer may facilitate the transfer of photons from the singlet fission layer to the solar cell layer. In some cases, the transition layer includes hafnium oxynitride. In some cases, the transition layer may be as thin as about 8 angstroms. In some cases, the singlet fission device may include further layers. In some cases, the further layers may include a layer to facilitate hole extraction (e.g., ‘a hole extraction layer’). The hole extraction layer may include an organic polymer, such as poly(3,4-ethylenedioxythiophene) polystyrene sulfonate (PEDOT:PSS). The hole extraction layer may be positioned between incident photons and the singlet fission layer.

The present disclosure also provides methods of using the compounds and devices as described herein, including a method for controlling the flow of an electric current, a method of producing electroluminescence, a method of transporting electrons, a method of detecting a target analyte, and a method of producing an electrical current using a singlet fission device.

In one aspect, the present disclosure provides a method for controlling the flow of an electric current, which can include providing an organic field-effect transistor device, providing an electric current to the source terminal, and applying an electric voltage to the gate terminal. The organic field-effect transistor device can include those as described herein. For example, the organic field-effect transistor device can have having a source terminal, a drain terminal, a semiconductor channel which includes a compound disclosed herein and electrically connects the source terminal and the drain terminal, and a gate terminal proximal to the semiconductor channel and electrically isolated from the source terminal, the drain terminal, and the semiconductor channel. The voltage applied to the gate terminal may alter the conductivity of charge carriers (either electrons or holes) of the semiconductor channel, thereby controlling the flow of electric current between the source terminal and the drain terminal.

In another aspect, the present disclosure provides a method of producing electroluminescence. The method can include providing a photoluminescent emitter, which has an anode, a cathode, and an emissive layer comprising a compound as described herein, the emissive layer electrically connecting the anode and the cathode. The method can further include applying an electrical current to the cathode. The compounds disclosed herein may be electrically conductive as a result of delocalized pi electrons caused by conjugation over all or part of the compound. As a voltage is applied across the photoluminescent emitter device, the anode may be positive with respect to the cathode. A current of electrons may flow through the device from cathode to anode, as electrons may be injected into the lowest unoccupied molecular orbitals (LUMO) of the emissive layer (containing at least one of the compounds disclosed herein) at the cathode and injection of electron holes into the highest occupied molecular orbital (HOMO) at the anode. Electrostatic forces may bring the electrons and the holes towards each other and they may recombine forming an exciton, a bound state of the electron and hole. The decay of this excited state may result in a relaxation of the energy levels of the electron, accompanied by emission of radiation. The frequency of this radiation may depend on the band gap (e.g., the difference in energy between the HOMO and LUMO) of the emissive layer containing at least one of the compounds disclosed above. In some cases, the radiation may be in ultraviolet, visible, or infrared wavelengths or a combination of ultraviolet, visible, or infrared wavelengths. In some embodiments, the method can be carried out using a photoluminescent emitter as described herein.

In another aspect, the present disclosure provides a method of transporting electrons, which can include providing a single molecule electrical device having a first electrode, a second electrode, and a molecular backbone. The molecular backbone can include a compound as described herein, which is covalently attached to the first electrode and the second electrode, forming an electrically conductive connection. The method may include applying an electrical current to one of the first electrode or second electrode. The method can further include applying a stimulus to the molecular backbone. In some cases, the stimulus applied to the molecular backbone may include changing (e.g., increasing or decreasing) temperature, applying an electrical bias to the first or second electrodes, mechanically pulling the molecular backbone, mechanically compressing the molecular backbone, irradiating the molecular backbone, and any combinations thereof. The application of one or more of the aforementioned stimuli may produce, enable, or disable the passage of electrons from the first electrode, through or along the molecular backbone, and to the second electrode. In some embodiments, the method can be carried out using a single molecule electrical device as described herein.

In another aspect, the present disclosure provides a method of detecting a target analyte, which can include providing a photoluminescent substrate comprising a compound as described herein. The photoluminescent substrate can include a first optical emission having a first wavelength and a first intensity, and a second optical emission, having a second wavelength and a second intensity, emitted in the presence of a target analyte. The method can further include detecting the first optical emission, exposing the photoluminescent substrate to a target analyte, and detecting the second optical emission. The method can further include comparing the first optical emission to the second optical emission, thereby detecting the presence or absence of the target analyte. The presence of a target analyte may cause a chemical reaction with the photoluminescent substrate, leading to an effective color change in emission wavelength or intensity. In some cases, the indication of the presence or absence of the target analyte may include the ratio of the first optical emission and the second optical emission. The emission ratio may include the optical emission intensity at the wavelength of the first optical emission and the optical emission intensity at the wavelength of the second optical emission. In some cases, the target analyte may include reactive oxygen species. In some cases, the target analyte may include hydrogen peroxide. In some cases, the target analyte may be produced by or be present in a biological setting and under physiological conditions. In some embodiments, the method can be carried out using a ratiometric biosensor as described herein. For example, the ratiometric biosensor may be used to determine the amount of endogenous hydrogen peroxide in living cells. In some cases, the excitation and detection of the first optical emission and the second optical emission may be accomplished with a fluorescence microscope, including a confocal fluorescence microscope.

In another aspect, the present disclosure provides a method for generating electrical current with a singlet fission device. The method includes illuminating a singlet fission device including a singlet fission layer including at least one of the compounds disclosed herein, a solar cell layer comprising a semiconductor comprising a semiconductor bandgap and electrical contacts, and a transition layer positioned between the singlet fission layer and the solar cell layer. The method further includes illuminating the singlet fission layer with incident photons to produce singlet fission photons comprising an energy substantially equal to the semiconductor bandgap, absorbing the singlet fission photons with the solar cell layer, thereby producing an electrical current in the solar cell layer, and collecting the electrical current from the electrical contacts. In some cases, the illumination of the singlet fission layer may be accomplished with ultraviolet, visible, or infrared wavelength of light. In some cases, the illumination is accomplished with sunlight., some cases, the singlet fission layer may produce photons which are energetically matched to the bandgap of the semiconductor of the solar cell layer, thereby increasing the solar cell layer's efficiency in converting photons to electrical current.

### EXAMPLES

### Example 1

### Synthesis and Structural Characterizations

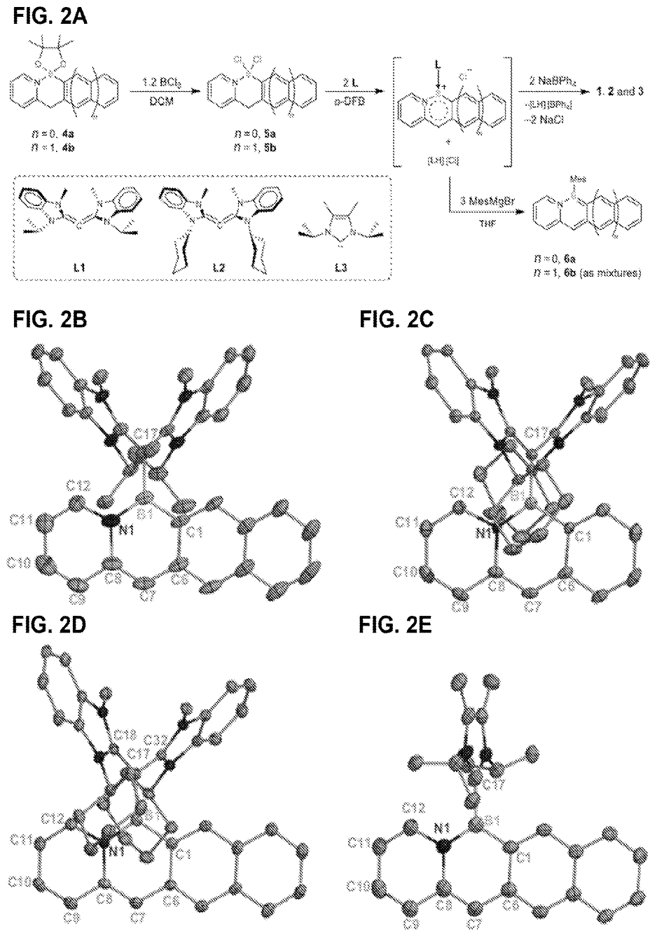

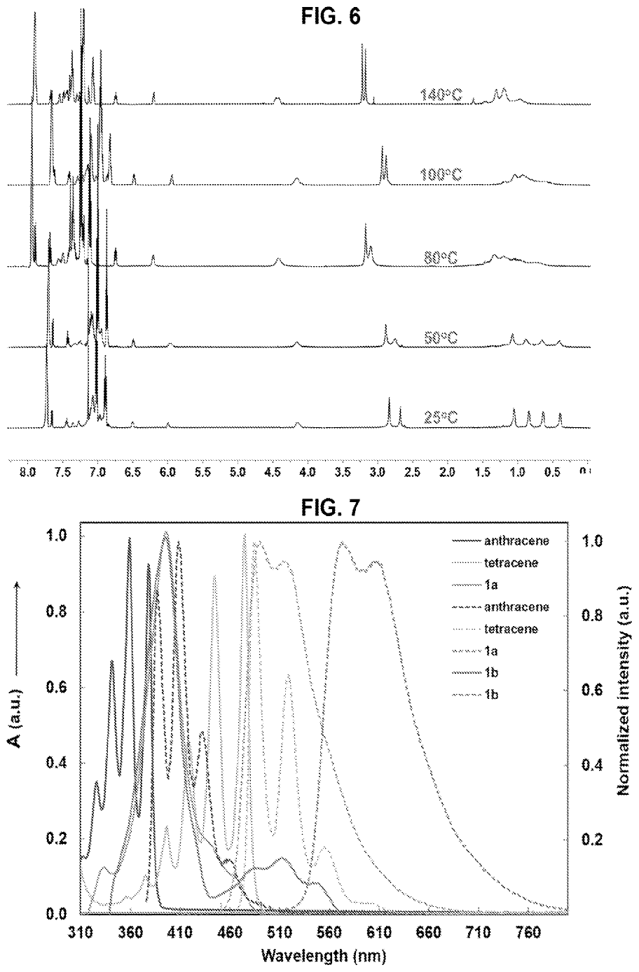

Synthesis strategy as illustrated in FIG. 2A was devised to prepare CDC-azaboraacenium ions. It is envisaged that the reported B—N-chelate ortho-borylated compound 4 could be transformed into the respective dichloroborate derivatives by treatment with BCl₃ in DCM. The desired compound 5a was exclusively obtained in 70% yield. Reacting CDC L¹ and 5a in ortho-difluorobenzene (o-DFB) resulted in concomitant coordination and dehydrochlorination, furnishing a mixture of the CDC-stabilized azaboraacenium ions and the CDC·HCl byproduct. To facilitate the removal of protonated ligand and increase the solubility of the title compound, the resulting mixtures were subjected to an anion exchange reaction with sodium tetraphenylborate (NaBPh₄), followed by recrystallization in hexanes/o-DFB to provide the azaboraanthracenium ion 1a as a yellow solid in an overall yield of 83%. The ¹¹B{¹H} NMR signal of 1a was observed at 36.4 ppm (azaboraanthracenium ion) and −6.6 ppm (BPh₄ anion). The ¹H NMR spectrum of compound 1a showed ill-defined peaks at room temperature, resulting from conformational changes due to the free rotation of the C_{carbone}-C_{carbene} single bonds. Multiple groups of ligand peaks likely result from strong intramolecular agostic-type interactions between the methine C—H group and B⁺, generating a mixture of diastereomers. Variable temperature (VT) ¹H NMR studies showed coalescence of all the peaks in the aromatic region at high temperatures, which supports an increased rotation of the C_{carbone}-C_{carbene} bonds and the presence of one species in solution (FIG. 6). Based on this method, the extended fused ring analogue 1b, which has a cationic BN-doped tetracene framework, was also obtained in an excellent yield of 90% (¹¹B{1H} NMR: 37.8 ppm).

To evaluate the effect of ligand sterics, CDC ligand L² with cyclohexyl pendant arms was used to prepare 2a and 2b in 85% and 76% yield, respectively. This efficient and highly modular synthetic pathway enabled the use of pure starting materials to generate the desired cationic species without involving unstable intermediates. The NHC ligand 1,3-diisopropyl-4,5-dimethylimidizol-2-ylidine L³ was chosen for comparative investigations as it has moderately strong o-donating abilities and less steric demand. NHC coordination to the BN anthracene framework proceeded smoothly to afford 3a, albeit in lower yield (65%). However, the NHC—(BN)+tetracene adduct 3b is surprisingly labile in solution at room temperature, readily decomposing into protonated ligand and intractable mixtures within hours, which precluded rigorous solution-state investigations. Compounds 1, 2, and 3a are remarkably stable to air and moisture in the solid-state under ambient light. For comparison, Inventors attempted to synthesize the neutral BN acene analogues of 1 and 2 using the aforementioned procedures. Treatment of the mixture of cationic species generated from 5 with an excess of MesMgBr afforded air and/or light-sensitive 6a in 77% yield. However, the BN tetracene analogue 6b could not be isolated and decomposed instantly during purification in the glovebox, which may be attributed to the very high HOMO level comparable with pentacene.

Single crystals of azaboraacenium ions 1-3 suitable for X-ray crystallography were obtained by slow evaporation from hexanes/o-DFB or hexanes/THF, which unambiguously confirmed the structures (FIGS. 2B-2E). For 1 and 3a, there are considerable positional disorders among the crystal lattices, especially for the BN backbone, thus the geometrical parameters are not discussed in detail. In all cases, the cationic boron centers are well-separated from their counteranions. In 1 and 2, the azaboraacene framework adopts a quasi-planar structure as the pyridine rings are slightly distorted [the root-mean-square (RMS) deviation of the mean polycyclic azaboraacene plane fitting ranging from 0.207 to 0.252 Å]. Both the carbene-stabilized complexes 3a and 3b display a more coplanar π-conjugated framework (RMS deviation value: 0.102 Å, 0.153 Å for 3a, 3b, respectively). The C17-B1 bond in 2b [1.5600 (19) Å] is longer than the comparable CDCC-B bonds in CDC-borafluorenium ions [1.467 (14)-1.495 (3) Å], and more similar to the reported carbene-borafluorenium ions [1.567 (5) Å]. In contrast, the C17-B1 bond in 3b [1.598 (5) Å] is longer than the NHCC—B bonds carbene-borafluorenium ions, reflecting weak stabilization from the NHC ligand. The B1-N1 bond [1.4568 (18) Å] in 2b is markedly shorter than a typical B→N dative bond (>1.60 Å), but slightly longer than the B═N bond in azaborines [1.403(2)-1.417(3) Å]. The endocyclic boron-carbon (B1-C1) and C—C bond distances (C1-C6, C6-C7, C7-C8 and N1-C8) are within the typical lengths of the respective single and double bonds, reflecting that the π-electrons are effectively delocalized within the BN-embedded rings.

### Electronic Structures

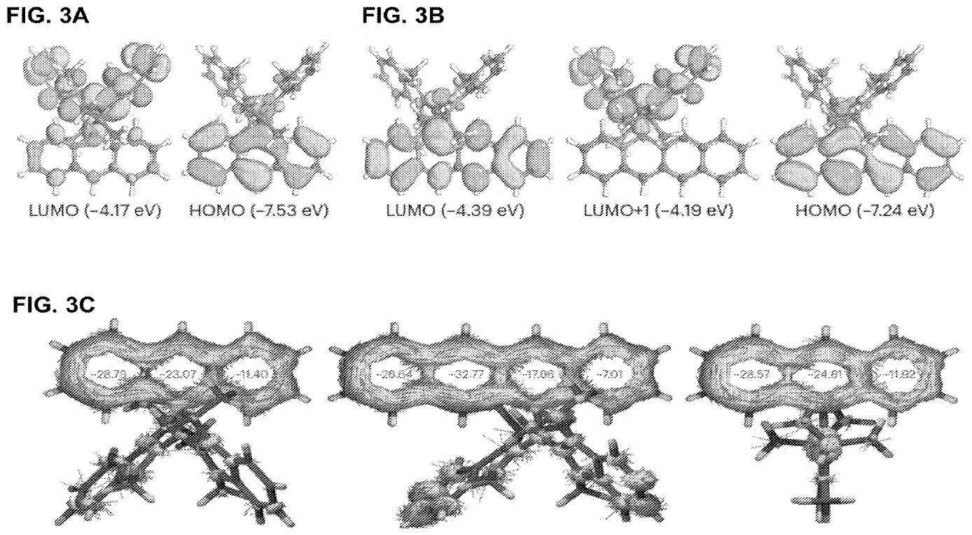

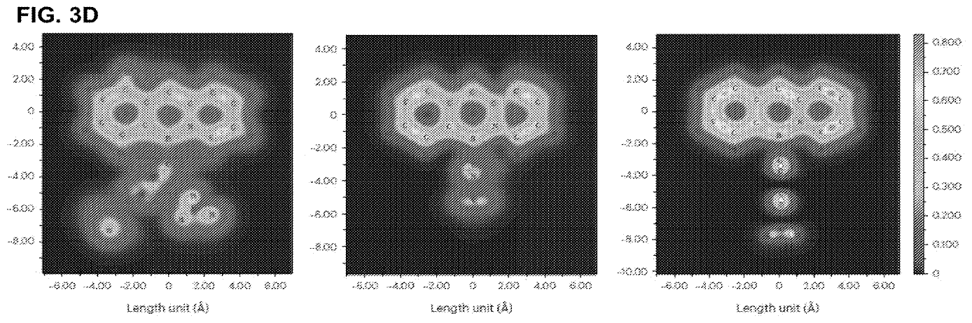

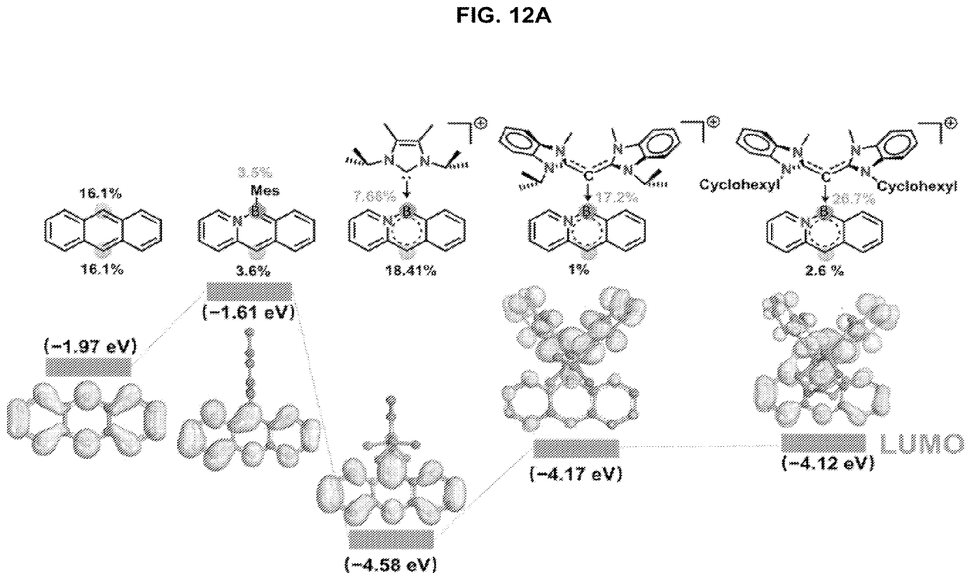

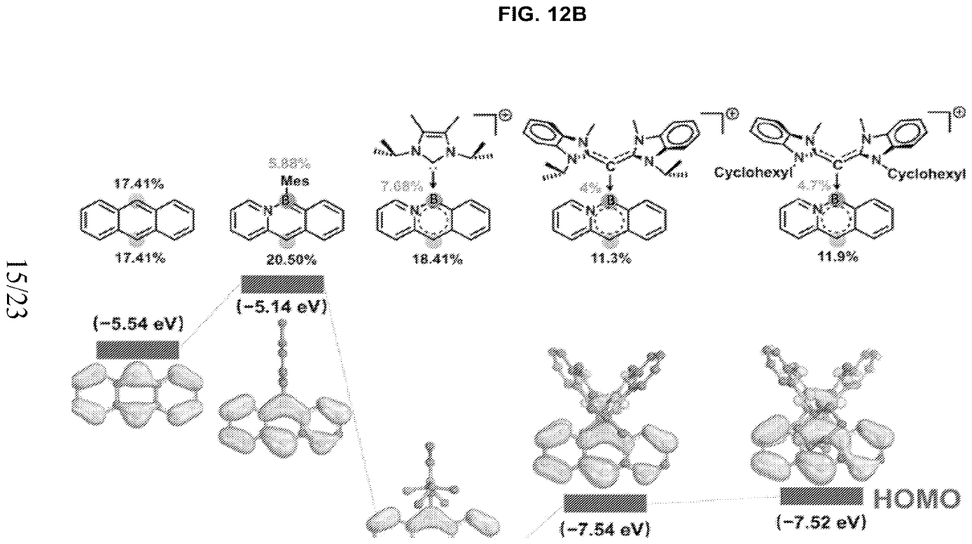

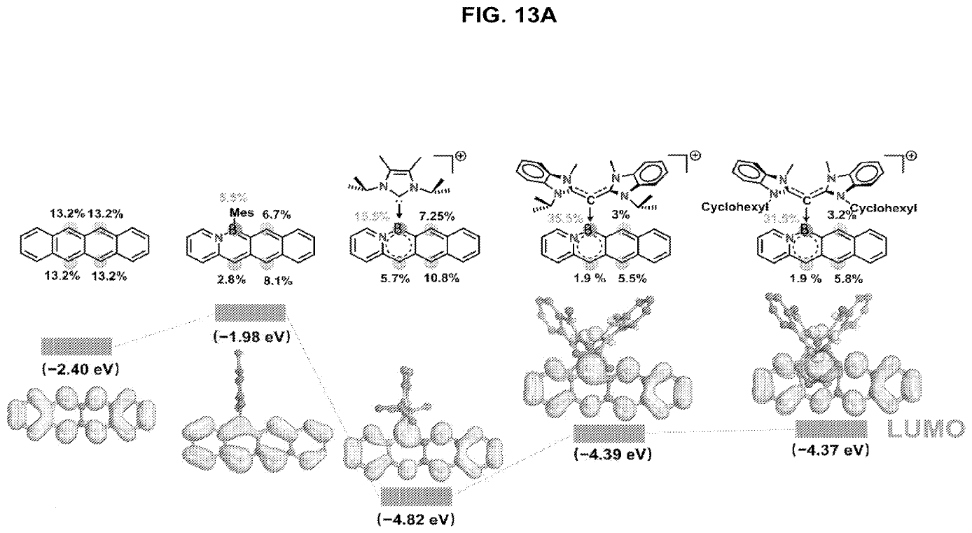

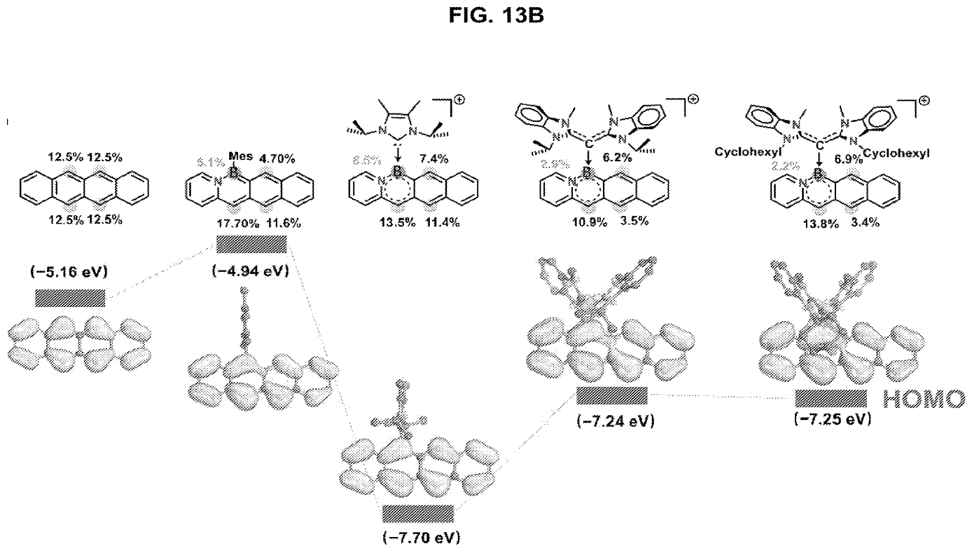

To gain deeper insight into the electronic structures of 1-3, DFT calculations were performed at the B3LYP-D3(BJ)/def2-TZVP level of theory. The calculated geometrical parameters agree well with the experiment-derived crystal structures. The HOMOs for 1a and 1b are located on the azaboraacenium core with 15.4% and 6.3% fragmental contribution from the CDC ligand, respectively. For 1a, the LUMO is spread over the whole molecular skeleton, but mainly lies on the CDC ligand (65.2% orbital coefficients) (FIG. 3A). The CDC moiety in azaboratetracenium ion 1b has a smaller contribution to the LUMO (13.2%), but possesses a major contribution to the energetically close-lying LUMO+1 (96.3%). Therefore, it is concluded that the reduced LUMO energy levels of 1a and 1b are adequately stabilized by the CDC ligand. This contrasts the observations for NHC-stabilized azaboraacenium ion derivatives 3, in which the frontier molecular orbitals (FMOs) coefficients are absent on the ligand in both cases (FIGS. 12A-12B and 13A-13B). The Wiberg bond indices (WBI) for the C17-B1 bond in 1a, 1b, and 3a are calculated to be 1.045, 0.978, and 0.897, respectively. The nature of the C17-B1 bond in 1, 2, and 3a was further interpreted using the extended transition state-natural orbitals for chemical valence (ETS-NOCV) and intrinsic bond orbitals (IBOs) analysis. The orbital stabilization in 1a dominantly arises from the CDC to B⁺ σ-donation (72.6%), with additional weak π-donation (6.5%). Based on the collective bonding analysis, the C17-B1 bonds are rationally depicted as a coordinate covalent bond. Similar results were obtained for the other azaboraacenium ions.

Natural population analysis (NPA) suggests the positive charge predominantly resides on the boron centers in 1a (+0.801) and 2b (+0.872), which is smaller than the charge on the boron atom in 3a (+0.758 a.u). The N atoms in the BN-embedded rings are negatively charged, suggesting highly polarized B1-N1 bonds (−0.579 a.u., −0.428 a.u. and −0.418 a.u. for 1a, 1b, and 3a, respectively). Of special interest was an evaluation of the aromatic character of these cationic BN π-conjugated ring systems. Thus, nucleus-independent chemical shift (NICS) values of the azaboraacenium ion rings were calculated at the GIAO-B3LYP/pcSseg-2 level of theory. As shown in FIG. 3C, all of the rings within 1a, 1b, and 3a exhibited negative NICS (1)_{zz} values, indicating their aromatic characters. The individual rings in 1a/1b show NICS (1)_{zz} values that are more negative than those in the neutral BN acene compounds 6a/6b, which suggest that the azaboraacenium ions have stronger aromaticity. Furthermore, the LOL-π(localized orbital indicator function) calculation shows that the π-electrons within the tricyclic and tetracyclic frameworks are mainly delocalized except in 3a (FIG. 3D). As compared to 6a, the stronger aromaticity in 1a is attributed to the presence of less partially localized C═C bonds in the tricyclic ring system, leading to effective π-delocalization (FIG. 3D). To further examine the overall aromaticity of the cations 1 and 2, analysis of the anisotropy of the induced current density (ACID) plots indicates a continuous clockwise diatropic ring currents around the fused molecular framework (FIG. 3C). Thus, these cationic BN-embedded systems display global aromaticity comparable to their parent all-carbon acenes.

### Optoelectronic Properties

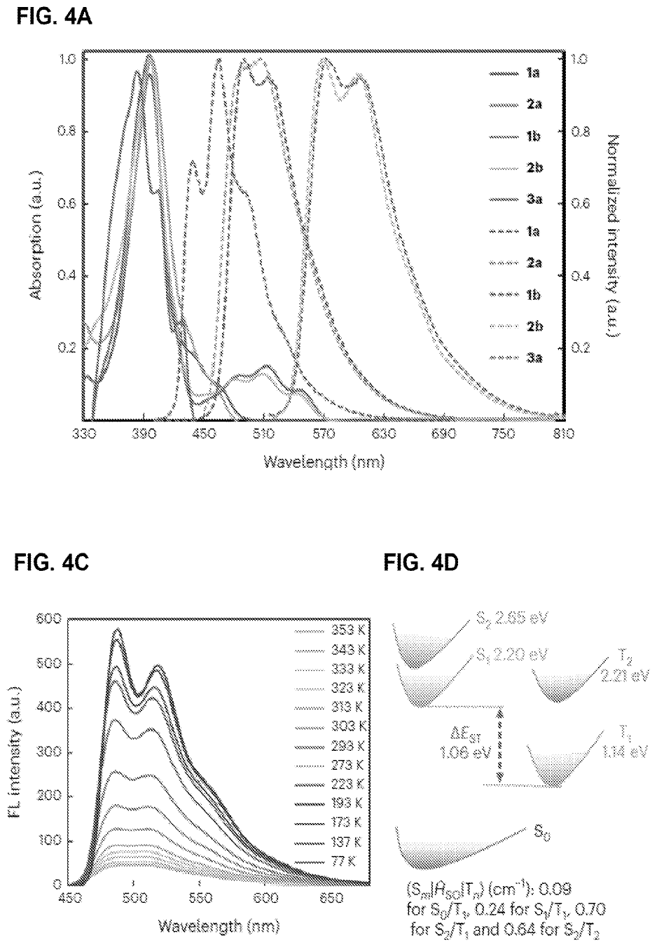

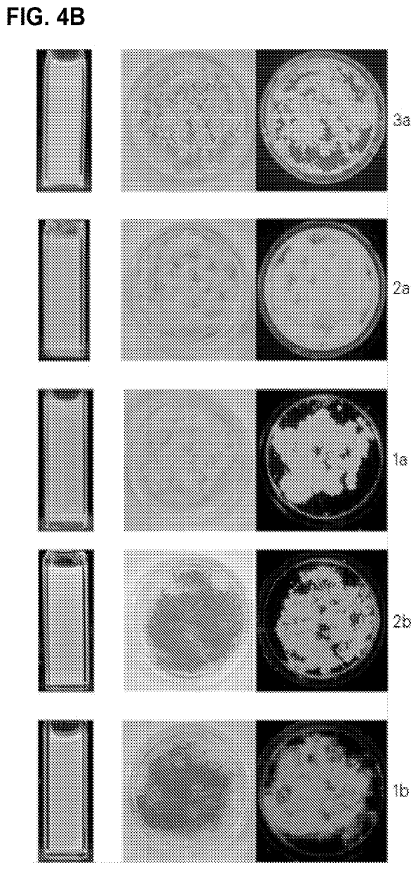

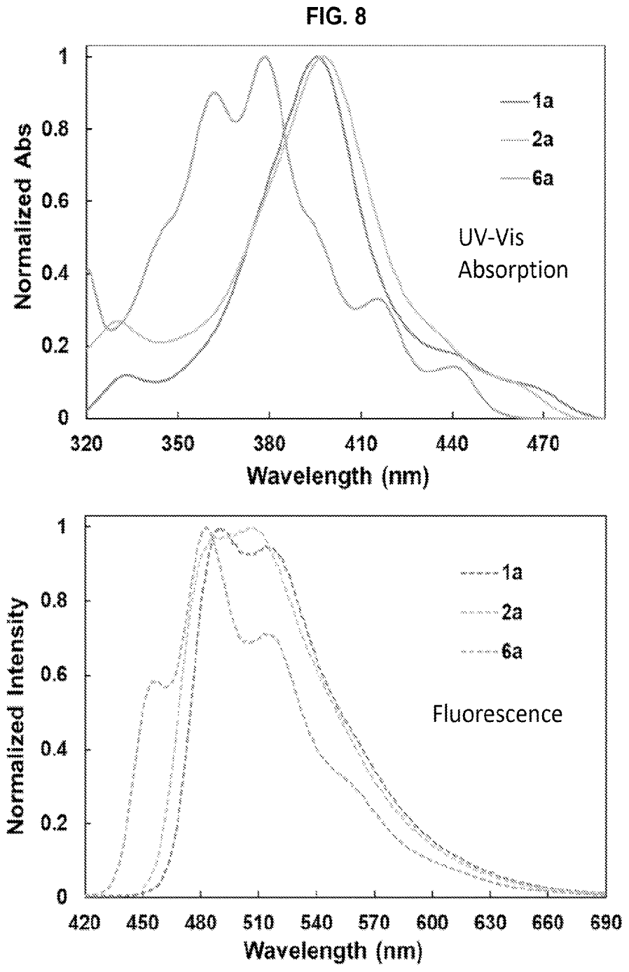

The ultraviolet-visible (UV-vis) absorption and fluorescence spectra of 1, 2, and 3a were recorded in anhydrous toluene under argon (FIG. 4A). Distinct from the characteristic optical features of the all-carbon anthracene, both azaboraanthracenium ions 1a and 2a display an exceptionally intense (log ε ~4.6) absorption peak around 400 nm and two weaker shoulder peaks in the 430-490 nm range. The higher absorption coefficients measured in 1a and 2a suggest the azaboraanthracenium ions are superior photon absorbers for potential optoelectronic usages compared to anthracene (log ε<4). In the case of azaboraanthracenium ion 3a, only a major wide band in the 330-440 nm region with a typical vibronic structure is observed. The lowest-energy absorption peaks among all the compounds are mainly ascribed to the S₀→S₁ (the first singlet excited state) (HOMO→LUMO) electronic transitions with oscillator strengths (f) in the range of 0.12-0.16, while the strong absorption peaks correspond to the S₀→S₅ (HOMO-1→LUMO+1) transition with a large f (>0.5) (Tables 4-8). Overall, the observed lowest-energy bands are red-shifted compared to anthracene (FIG. 7), which can be rationalized by their narrower HOMO-LUMO gaps. From the onsets of the lowest energy absorption band of their UV-vis absorption spectra, the optical energy gaps (Eₒₚₜ) were determined. The Eₒₚₜ for 1a (2.53 eV), 2a (2.57 eV), and 3a (2.81 eV) are remarkably smaller than the pristine anthracene (3.20 eV). Compared to the neutral BN-acene 6a (2.72 eV), the lowest-energy absorption bands of azaboraanthracenium ions 1a/2a are red shifted ca. 20-30 nm, which showcases the notable influence of cationization on the absorption properties of BN acenes (FIG. 8). The optical energy gap of 1a is even lower than that of tetracene (2.54 eV).

It is understood that 1a also represents the most red-shifted longest-wavelength absorption maximum of an anthracene derivative doped with a single BN unit and therefore may be regarded as an electronic mimic for tetracene. By contrast, the azaboratetracenium ions 1b and 2b show major absorption bands centered around 400 nm (log ε~4.5) but display a broadened absorption features with small vibronic progressions within the 430-580 nm spectral range. The considerable bathochromic shift of the longest absorption maxima with respect to 1a and 2a is due to the longitudinal extension effective conjugation within the central core. The lowest-energy bands 1b and 2b are significantly red-shifted (~70 nm) compared to the parent all-carbon tetracene (FIG. 7). Tetracyclic 1b and 2b thereby display small optical gaps of 2.15 eV and 2.17 eV, respectively, which are in accord with that of the more conjugated pentacene (2.07 eV, 2.15 eV), attesting their potential as stable electronic alternatives to pentacene for solution-processable optoelectronics. Unequivocally, the optical energy gaps of 1b and 2b are significantly smaller than those of highly fused neutral BN acene derivatives.

Compounds 1, 2, and 3a are luminescent in the solution and solid states (FIG. 4B and Table 1). In toluene, the fluorescence spectra of all compounds are drastically red-shifted with the absence of the characteristic vibrational fine structures of typical acenes (FIG. 7). It is noteworthy that the absolute fluorescence quantum yields of 1-3 surpass their parent hydrocarbon acenes (anthracene: 0.27; tetracene: 0.17). Azaboraanthracenium ions 1a and 2a showed the highest solution quantum yields (QYs) of 0.53 and 0.62, respectively, which are higher than their neutral counterpart 6a (0.32). Electron density difference (EDD) plots and the natural transition orbitals (NTOs) suggest that S₀→S₁ transitions are mainly characterized as π to π* transitions with no discernible charge transfer, which reveal that the emission has a dominant localized emission (LE) character, in accordance with the negligible fluorescence solvatochromism from toluene to acetonitrile. Among the azaboraanthracenium series, 1a and 2a exhibited higher fluorescence QYs with respect to 3a mainly due to the higher radiative constants, kᵣ (Table 2). Notably, the bulky cyclohexyl CDC ligand in 2a and 2b resulted in reduced nonradiative processes and showed higher QYs than 1a and 1b. The optimized geometries of S₁ states show no remarkable change and their HOMO-LUMO gaps are nearly the same as those of the ground states (Table 9), which is consistent with the small Stokes shift observed in the optical spectroscopic studies.

TABLE 1
Photophysical data at 298K.

| | | logε/ | λ_{em.solu}/ | | λ_{em.solid}/ | | | |
|---|---|---|---|---|---|---|---|---|
| Compound | λₘₐₓ/nm^{[a]} | M⁻¹ · cm^{-1[b]} | nm^{[d]} | Φ_{F, solu}^{[e]} | nm | Φ_{F, solid}^{[e]} | τ/ns^{[f]} | Eₒₚₜ/eV^{[g]} |
| 1a | 465 | 4.57 | 490, 513 | 0.53(0.88) | 521 | 0.40 | 2.9 | 2.53 |
| 1b | 544 | 4.55 | 572, 603 | 0.29(0.35) | 635 | 0.17 | 4.6 | 2.15 |
| 2a | 446 | 4.57 | 506 | 0.62(0.98) | 517 | 0.34 | 5.4 | 2.57 |
| 2b | 542 | 4.54^{[c]} | 568, 603 | 0.34(0.32) | 608 | 0.11 | 5.2 | 2.17 |
| 3a | 384 | 4.11 | 439, 466 | 0.31 | 466 | 0.27 | 6.2 | 2.81 |

^{[a]}The longest absorption (λₘₐₓ) maxima, measured in toluene.
^{[b]}The major absorption band.
^{[c]}Measured in PhCl solutions due to the limited solubility in toluene.
^{[d]}The most intense local maximum of each emission band, measured in toluene.
^{[e]}Absolute quantum efficiency determined in toluene using an integrating sphere, error ± 3%. Values in parentheses obtained in the 2-MeTHE glass matrix at 77K.
^{[f]}Fitted with the mono-exponential decay model.
^{[g]}The optical band gap Eₒₚₜ = 1240/λₒₙₛₑₜ.

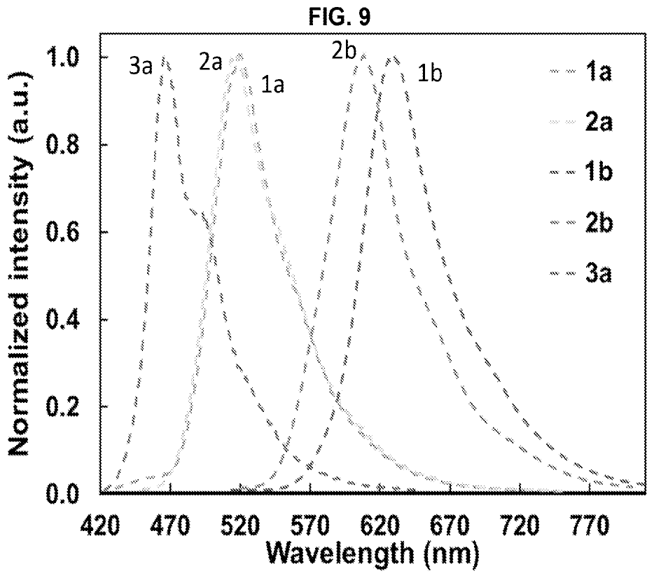

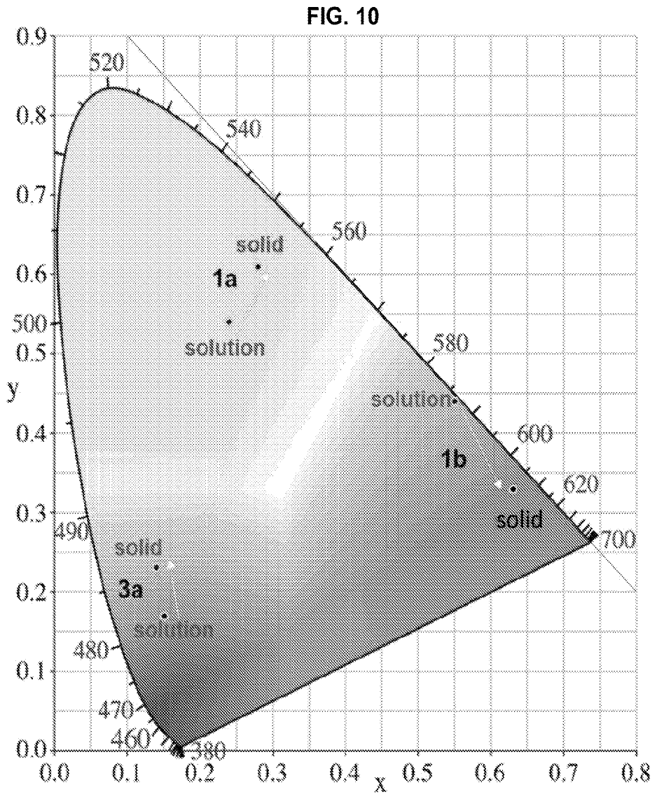

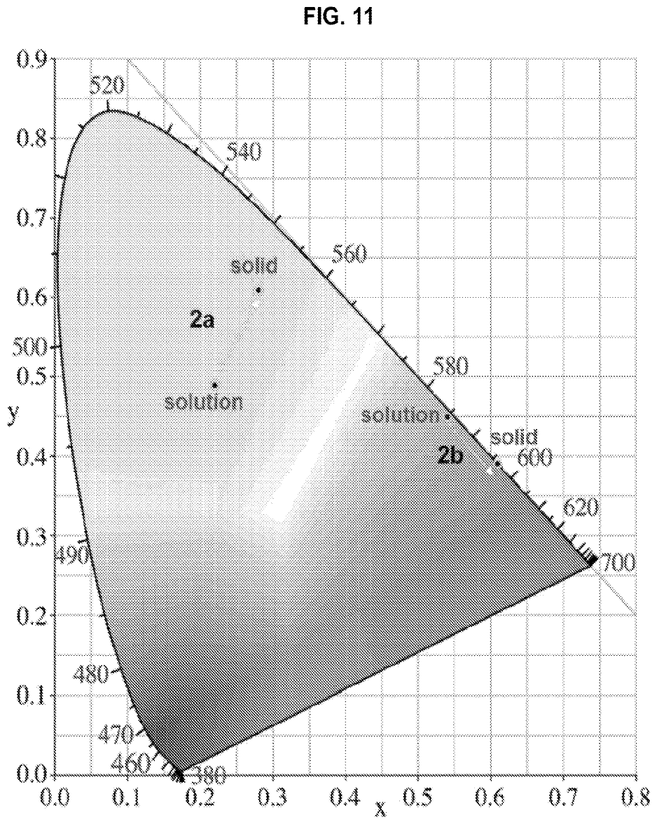

Compounds 1, 2, and 3a emit in the crystalline states and the emission maxima range from blue (466 nm) to red (635 nm) with photoluminescence quantum yields up to 0.40 (Table 1 and FIG. 9). The solid-state emission spectra of 1 and 2 are structureless with smaller full-width-half-maxima (FWHM) with respect to the solution-phase (FIGS. 10 and 11). The bathochromically-shifted emission profiles and decreased QYs in the solid-states manifest possible exciton interactions in the condensed phase. However, the bulky CDC ligands prevent aggregation-caused quenching (ACQ) to some extent. Notably, the azaboratetracenium ion solids 1b and 2b are emissive while the solid all-carbon tetracene is nearly non-fluorescent (0.004). The differences in emission behavior reflect the significant impact of ligand-based sterics and electronics, not only on emission color but also the fluorescence efficiency of these materials.

Upon cooling from 293 to 77 K, the intensities of lower absorption and emission bands for 1 and 2 in 2-methyl-THF (2-MeTHF) gradually increased while their wavelengths were slightly red-shifted (FIG. 4C). The photoluminescence QYs for 1a and 2a drastically increased to 0.88 and 0.98, respectively (Table 1 and Table 3). The enhanced emission behaviors for these cations at low temperatures are likely due to the enhanced S₀→S₁ transitions (increased kᵣ) and the prohibited structural relaxation via rotation of C_{carbone}-C_{carbene} bonds in the excited states (decreased kₙᵣ). In contrast, kₘᵣ increased while heating from 298 to 353 K and the emission intensity diminished. For azaboratetracenium ions 1b and 2b, the photoluminescence intensities only show a minor increase at 77 K, indicative of the presence of intersystem crossing (ISC) processes and/or internal conversion. Nevertheless, no photoluminescence spectra (<800 nm region) were attributed to phosphorescence even at 77 K, implying these compounds may possess low lying triplet energies. Accordingly, the S₁ and the first triplet excited state (T1) energy levels were investigated by TD-DFT and unrestricted DFT (UDFT) calculations to determine the singlet and triplet energy levels (FIG. 4D and Table 10). Both 1a and 1b possess very large ΔEST (>1 eV), retaining the intriguing wide energetic splitting characters of the S₁ and T₁ found in high-order all-carbon acenes. Notably, both the adiabatic energy levels of S₁ and the second triplet excited state (T₂) are nearly twice than that of T₁ [i.e., 2E(T₁)≈E(S₁) and 2E(T₁)≈E(T₂)], which suggest that the energy level distribution in 1b perfectly satisfies the energy matching criteria for isoergic SF-scaffolds. As shown in FIG. 4D, the spin-orbit coupling (SOC) calculations suggest that the Sₘ/Tₙ elements in 1b are considerably larger than those of hydrocarbon tetracene (nearly 0 cm⁻¹), thus Sₘ/Tₙ ISC is likely to efficiently occur and lead to high triplet yields for efficient SF processes. For 1a, the energetics of 2E(T₁)>E(S₁), large absorption coefficient, as well as high fluorescence QYs are desirable characteristics of emitters for triplet-triplet-annihilation (TTA) upconversion. In this regard, these main-group species may serve as a promising platform for expanding the scope of singlet fission and triplet fusion materials.

### Evaluation of the Photostability

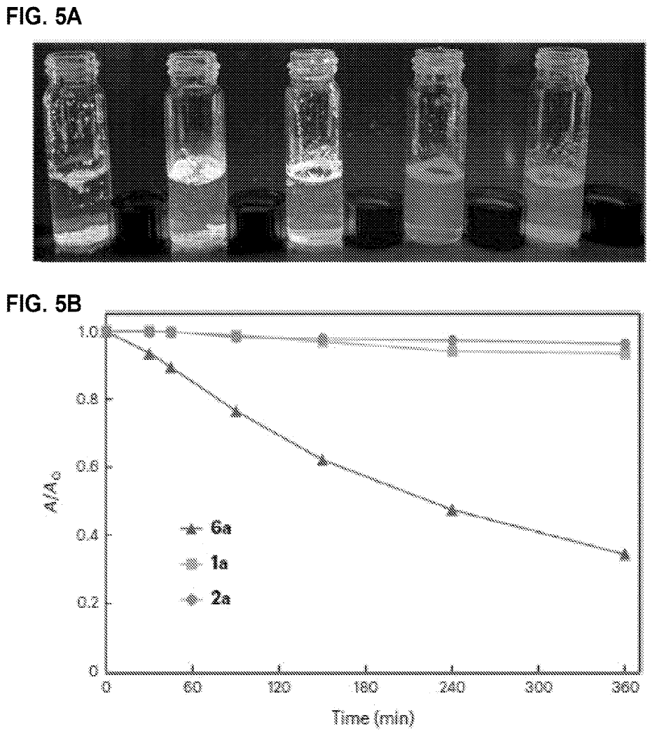

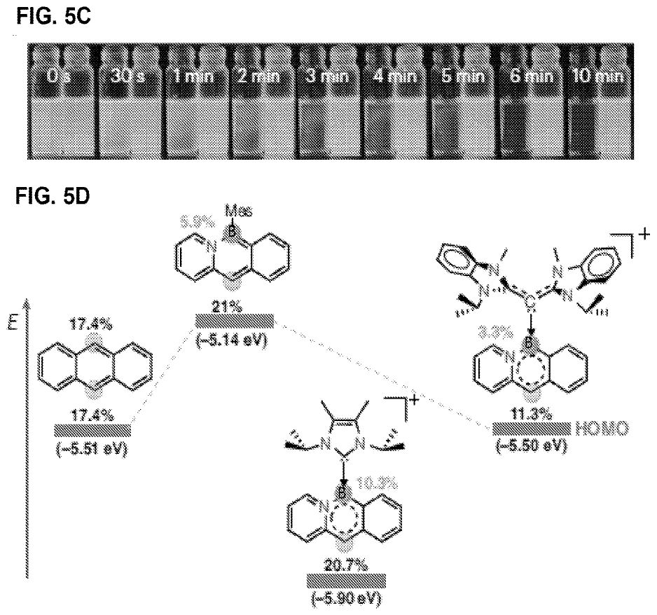

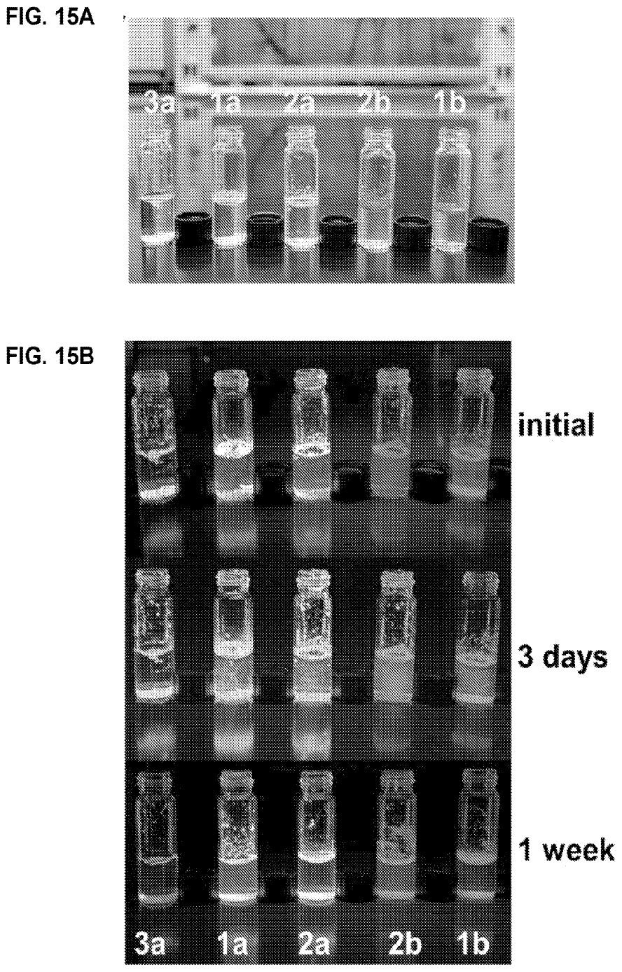

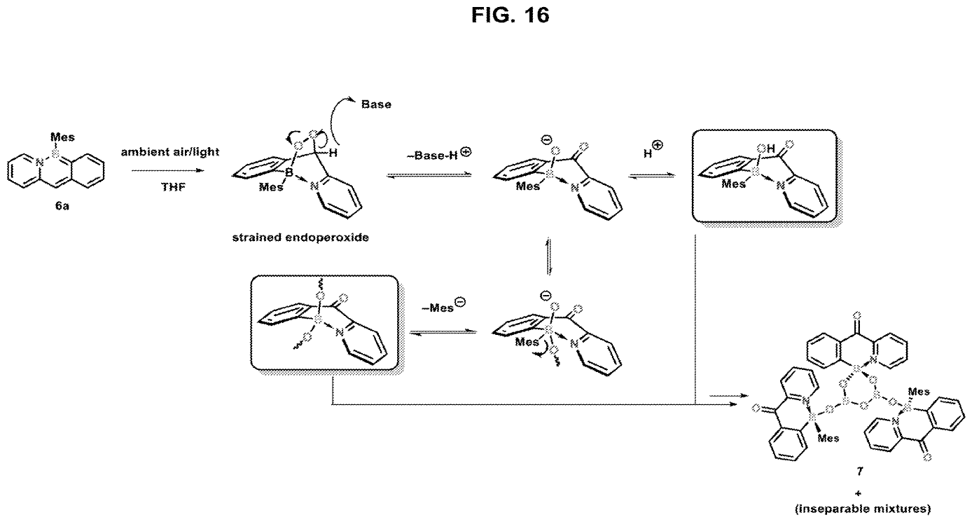

The isolated solids 1, 2, and 3a are stable for several weeks under ambient air- and light-environments. Strikingly, they even survive and emit for a week submerged and dispersed in water (FIG. 5A and FIGS. 15A-15B), making azaboraacenim ions exceptional compared to the majority of reported borenium ion systems, which are generally highly unstable when exposed to oxygen and/or water. To further assess the photostability of the azaboraacenium ions in solution, air-equilibrated dry THE solutions of 1a, 2a, and 6a were exposed to ambient light and the absorbance of low energy maxima in their UV-vis absorption spectra were monitored at different times to track degradation (FIG. 5A). The intensity of the low energy absorption band in the neutral BN counterpart 6a decreased by one-half within 3.4 hrs. In marked contrast, no absorbance change for the low energy absorption band was observed for 1a, maintaining over ca. 95% of the initial intensity after 6 hrs. When exposed to air and 365 nm UV light, the fluorescence color of 6a in THF solution completely bleached after 6 min. Bulk photooxidation of 6a afforded compound 7 with B—O/C═O bonds in the central ring, suggesting that the 9,10-positions of the central ring are the most reactive sites (FIG. 16). In contrast, the fluorescence of 1a remained after 10 min and, in this instance, took ~30 min to completely fade (FIG. 5C). DFT calculations revealed that the introduction of positive charge into the BN-acene framework reduced the HOMO energy levels compared to the neutral BN anthracene (FIG. 5D), which is beneficial in improving the photostability of acene or BN-acene related materials. Furthermore, the higher reactivity of 6a compared to anthracene may be ascribed to the highly unsymmetrical and increased HOMO atomic coefficients at the reactive B and C atoms. In contrast, the positively charged 1a showed significantly decreased atomic HOMO coefficients with respect to 6a (C: 11.3%, B: 3.3% in 1a vs. C: 21%, B: 5.9% in 6a). The NHC-stabilized anthracene 3a completely degraded under air and/or light conditions in THE after 10 minutes. The low photo-oxidative stability of 3a may be attributed to the insufficient NHC ligand stabilizing effect on the highly reduced energy levels, leading to significantly increased orbital coefficients in the central reactive ring (FIG. 5D).

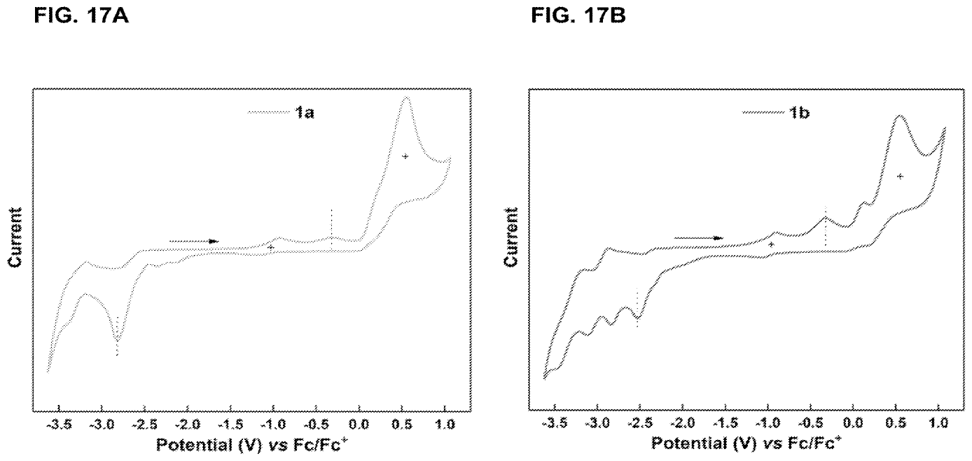

Therefore, the efficient CDC ligand stabilization on the reduced energy levels and the orbital coefficients of the FMOs in 1a contribute to its excellent stability. Unfortunately, the electrochemical behavior of 1a is complicated by the redox active non-bonding pair of π electrons on the CDC ligand, which prelude the rough estimation of its FMO energies by cyclic voltammetry (FIGS. 17A-17B). Azaboratetracenium ion 1b showed signs of slow photobleaching but retained 50% of its initial intensity after 8 hrs, which is remarkably more stable than the parent all-carbon tetracene (half-life: 1 hr). A comparison of the isopropyl-versus cyclohexyl-substituted CDC ligands (1a/1b vs. 2a/2b) revealed that the bulky azaboraacenium ions are more stable than those bearing less sterically hindered ligands, which is likely due to the additional kinetic protection of the cationic boron center from the perpendicularly-oriented cyclohexyl groups. Thus, the significantly enhanced photo-oxidative resistance in the solution states, compared to tetracene or pentacene, as well as even greater stabilities in the solid-states hold significant potential in the context of optoelectronic applications.

The above results have demonstrated that the CDC ligand provides efficient stabilization for the synthesis of π-conjugated azaboraacenium ions, which were isolated as remarkably air- and water-stable solids. This class of compounds display blue to red emission that is tunable based on the specific combination of CDC and cationic BN-doped acene. The cationization strategy among BN-acenes results in distinct optical profiles with red-shifted emission and higher quantum yields with respect to their neutral BN counterparts and all-carbon acene analogues. Importantly, the small-size azaboraacenium ions exhibit electronic structure characteristics that are consistent with their respective n+1 carbon-based congener (e.g., cationic BN-tetracenium ion mimics pentacene) with dramatically enhanced photo- and air-stability. The close resemblance of the electronic structures to high-order carbonaceous acenes coupled with the highly emissive properties hold promise for the use of these main-group element-containing cations in optoelectronic applications, such as light-emitting materials/devices and uncommon single fission-based photovoltaic cells. Future work will focus on the preparation of more extended cationic BN-acenes and substituted BN-acene frameworks via specific precursor synthesis. In addition, this approach also permits the utilization of related carbon (0) ligands for the development of a diverse library of cationic acene mimics.

### Example 2

### General Procedures

All air- and moisture-sensitive reactions were carried out under an inert atmosphere of argon using standard Schlenk techniques or in a MBRAUN LABmaster glovebox equipped with a −36° C. freezer. Reaction solvents including toluene, hexanes, diethyl ether and tetrahydrofuran (THF) were purified by distillation over Na/benzophenone. Dichloromethane (DCM) and chlorobenzene were purified via distillation over CaH₂. Dry acetonitrile (MeCN) was purchased from Millipore Sigma and used as received in a SureSeal. Deuterated solvents were purchased from Cambridge Isotope Laboratories and distilled over Na/benzophenone (C₆D₆) or CaH₂ (CD₃CN, o-DCB-d₄). All glassware used for reactions was oven-dried overnight at 190° C. The NMR spectra were collected on Bruker Advance III 600 MHz, Bruker Advance III 800 MHz, Varian Inova 500 MHz, and Varian 600 MHz spectrometers. Proton and carbon signals are reported in ppm and referenced to residual solvent peaks of the deuterated solvent (1H:CDCl₃ δ 7.26, CD₂Cl₂ δ 5.32; CD₃CN 8 1.94; o-DCB-d₄ δ 7.19, 6.93; 13C:CDCl₃ δ 77.16, CD₂Cl₂ δ 53.84; CD₃CN 8 118.7, 1.4). Abbreviations are as follows; s=singlet, d=doublet, t=triplet, hept=heptet, dt=doublet of triplets, m=multiplet, br=broad. All boron signals are reported in ppm and were referenced to an external standard, BF₃·Et₂O (¹¹B: 8=0.00). Due to a borosilicate NMR probe, there is a broad signal observed from −25 to 25 ppm. Elemental analyses were performed at the University of Virginia Department of Chemistry using a Perkin Elmer 2400 Series II Instrument. Single crystal X-ray diffraction data were collected on a Bruker Kappa APEXII Duo system or a Bruker D8Venture Photon III Duo diffractometer. The structures were solved and refined using the Bruker SHELXTL Software Package within OLEX2 1.3. The following compounds were prepared according to literature procedures: B—N-chelate ortho-borylated compound 4a and 4b, bis(1-isopropyl-3-methyl-benzimidazol-2-ylidene) methane [CDC L1] and bis(1-cyclohexyl-3-methyl-benzimidazol-2-ylidene) methane [CDC L2]. All other chemicals were purchased from Millipore Sigma or Ambeed and used as received.

### Synthetic Procedures

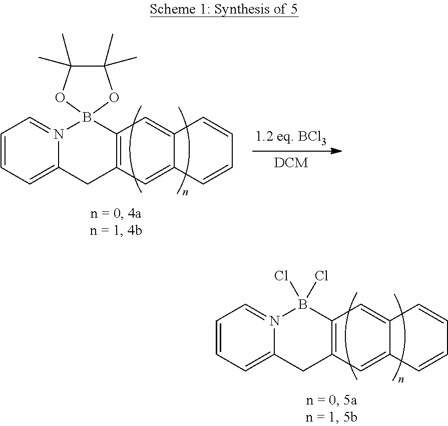

To a solution of 41 (2.95 g for 4a, 3.15 g for 4b, 10 mmol, 1 eq.) in dry DCM (2 mL), a solution of BCl₃ (1 M in DCM) (12 mL, 12 mmol, 1.2 eq.) was added dropwise at 0° C. under argon protection. The reaction was stirred at room temperature for 16 hrs before the resulting mixture was concentrated and washed with hexanes (50 mL). The final product was isolated by recyclization from a mixture of DCM and hexanes.

5a, light grey solid (1.74 g, 70% yield). ¹H NMR (600 MHz, CDCl₃, 20° C.) 8 9.56 (dd, J=6.2, 1.6 Hz, 1H, ArCH), 8.05 (td, J=7.7, 1.6 Hz, 1H, ArCH), 8.01 (dd, J=7.4, 1.4 Hz, 1H, ArCH), 7.70-7.64 (m, 1H, ArCH), 7.64-7.60 (m, 1H, ArCH), 7.41-7.33 (m, 1H, ArCH), 7.29 (td, J=7.4, 1.5 Hz, 1H, ArCH), 7.24 (d, J=7.1 Hz, 1H, ArCH), 4.45 (s, 2H, CH₂). ¹³C {¹H} NMR (201 MHz, CDCl₃, 20° C.) 8 156.9, 144.7, 142.4, 133.8, 132.0, 128.0, 127.2, 126.4, 125.9, 123.8, 38.8. 11B{¹H} NMR (192 MHz, CDCl₃, 20° C.) 8 6.2. Anal. Calcd. For C₁₂H₁₀BCl₂N:C, 57.67; H, 4.03; N, 5.60%. Found: C, 57.60; H, 4.19; N, 5.77%.

5b, white solid (2.49 g, 83% yield). ¹H NMR (600 MHz, CD₂Cl₂, 20° C.) δ 9.61 (dd, J=6.2, 1.6 Hz, 1H, ArCH), 8.41 (s, 1H, ArCH), 8.14 (td, J=7.7, 1.6 Hz, 1H, ArCH), 7.95-7.89 (m, 1H, ArCH), 7.85-7.79 (m, 1H, ArCH), 7.78-7.73 (m, 2H, ArCH), 7.70 (ddd, J=7.6, 6.0, 1.4 Hz, 1H, ArCH), 7.51-7.43 (m, 2H, ArCH), 4.65 (s, 2H, CH₂). ¹³C {¹H} NMR (201 MHz, CD₂Cl₂, 20° C.) δ 157.4, 144.8, 143.1, 133.5, 133.1, 132.7, 131.7, 128.7, 127.4, 127.0, 126.5, 125.9, 124.4, 124.4, 39.5. 11B{¹H} NMR (192 MHz, CDCl₃, 20° C.) δ 6.4. Anal. Calcd. For C₁₆H₁₂BCl₂N:C, 64.06; H, 4.03; N, 4.67%. Found: C, 63.70; H, 4.00; N, 4.53%.

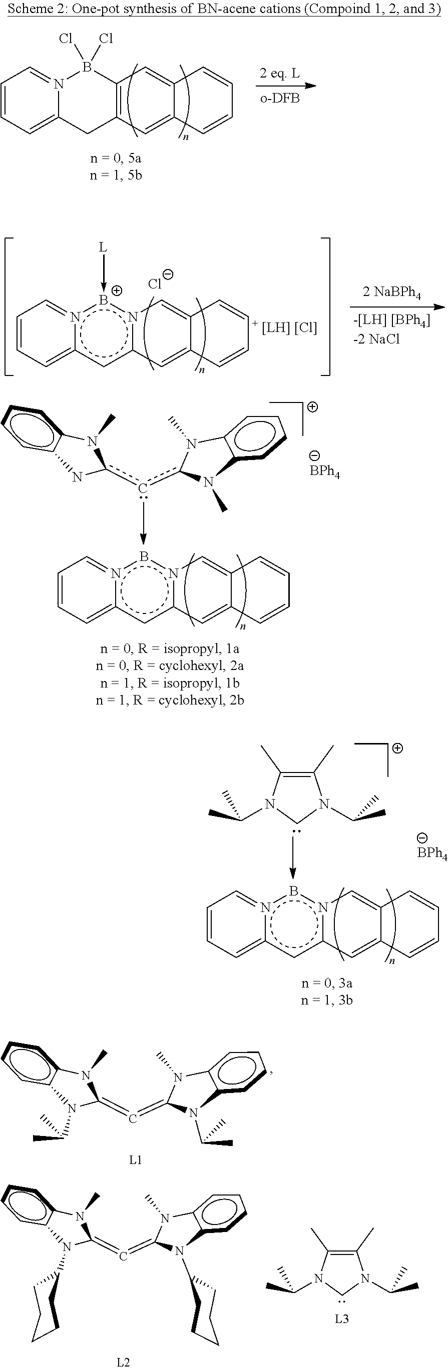

To a solution of CDC ligand (L1 or L2) or NHC ligand (L3) (0.2 mmol, 2 eq.) in o-DFB (3 mL), the corresponding dichloroboranes derivative 5a/5b (25 mg for 5a, 30 mg for 5b, 0.1 mmol, 1 eq.) was added. The reaction was protected from light and stirred at room temperature for 18 hrs. Then sodium tetraphenylborate (68 mg, 0.2 mmol, 2 eq.) was added into the resulting mixtures and continue to stir in the dark for 12 hrs. The solution was filtered through a 0.45 μm PTFE syringe filter and the solvent was removed under vacuum. The residue was re-dissolve in 60/40 o-DFB/hexanes (10 mL) was added and the mixture were allowed to stand still at r.t. for 12 hrs. During which time, a colorless precipitate formed, which was the protonated ligand [(LH)]⁺[BPh₄]⁻. After filtration and the solution was placed into the in the glovebox fridge (−36° C.) for overnight. The resulting precipitate was isolated by filtration and dried in vacuo to afford the product. Analytical pure product can be obtained from the second recrystallization from a 70/30 0-DFB/hexanes (for 1a and 2a, 3a) or 70/30 THF/hexanes (for 1b and 2b) at −36° C.

Azaboraanthracenium ion 1a (synthesized from 5a and CDC ligand L1), bright yellow solid (71 mg, 83% yield). ¹H NMR (600 MHz, o-DCB-d₄, 120° C.) δ 7.69-7.66 (m, 9H, ArH 1H/BPh₄-ArH 8H), 7.48-7.45 (ddd, J=8.2, 6.9, 1.2 Hz, 1H, ArH), 7.35 (d, J=7.4 Hz, 1H, ArH), 7.29-7.25 (m, 3H, ArH), 7.20-7.14 (m, 5H, ArH overlap with o-DCB-d₄), 7.12 (dd, J=7.5, 1.6 Hz, 1H, ArH), 7.08 (m, 1H, ArH), 7.02-6.97 (m, 10H, ArH 2H/BPh₄-ArH 8H), 6.85-6.82 (m, 4H, BPh₄-ArH), 6.56-6.53 (m, 1H, ArH), 6.00 (ddd, J=7.5, 6.2, 1.4 Hz, 1H, ArH), 4.32-4.20 (m, 2H, CH(CH₃)₂), 3.06 (s, 3H, CH₃), 3.03 (s, 3H, CH₃), 1.13-1.01 (m, 9H, CH(CH₃)₂), 0.83 (s, 3H, CH(CH₃)₂). Discernable ¹³C {¹H} NMR cannot be obtained due to the limited solubility in o-DCB-d₄ and/or gradual decomposition at the high collecting temperature. ¹¹B{¹H} NMR (192 MHz, CD₃CN, 20° C.) δ 36.4 (B⁺), −6.6 (BPh₄). Anal. Calcd. For C₅₉H₅₇B2N5:C, 82.62; H, 6.70; N, 8.16%. Found: C, 82.62; H, 6.69; N, 7.99%.

Azaboratetracenium ion 1b (synthesized from 5b and CDC ligand L2), red solid (82 mg, 90% yield). ¹H NMR (600 MHz, o-DCB-d₄, 120° C.) δ 8.15 (s, 1H, ArH), 7.81 (s, 1H, ArH), 7.79 (d, J=8.5 Hz, 1H), 7.75-7.72 (m, 8H, BPh₄-ArH), 7.35-7.29 (m, 3H, ArH), 7.22-7.15 (m, 8H, ArH), 7.08-7.02 (m, 11H, ArH 3H/BPh₄-ArH 8H), 6.93-6.88 (m, 4H, BPh₄-ArH), 6.42 (dd, J=9.3, 6.0 Hz, 1H, ArH), 5.85 (t, J=6.7 Hz, 1H, ArH), 4.30 (s, 2H, CH(CH₃)₂), 3.11 (s, 3H, CH₃), 3.00 (s, 3H, CH₃), 1.13 (brs, 12H, CH(CH₃)₂). Discernable ¹³C {¹H} NMR cannot be obtained due to the limited solubility in o-DCB-d₄ and/or gradual decomposition at the high collecting temperature. ¹¹B{¹H} NMR (192 MHz, CD₂Cl₂, 20° C.) δ 37.4 (B), −6.6 (BPh₄). Anal. Calcd. For C₆₃H₅₉B₂N₅:C, 83.35; H, 6.55; N, 7.71%. Found: C, 83.53; H, 6.56; N, 7.69%.

Azaboraanthracenium ion 2a (synthesized from 5a and CDC ligand L1), bright yellow solid (80 mg, 85% yield). ¹H NMR (600 MHz, o-DCB-d₄, 140° C.) δ 7.71-7.68 (m, 9H, ArH 1H/BPh₄-ArH 8H), 7.50-7.48 (m, 2H, ArH), 7.43 (d, J=8.0 Hz, 1H, ArH), 7.37-7.35 (m, 2H, ArH), 7.19-7.12 (m, 6H, ArH), 7.09-7.05 (m, 3H, ArH), 7.01 (t, J=7.4 Hz, 8H, BPh₄-ArH), 6.86 (t, J=7.2 Hz, 4H, BPh₄-ArH), 6.60 (dd, J=9.2, 6.1 Hz, 1H, ArH), 6.10 (m, 1H, ArH), 4.04 (s, 1H, CH(CH₃)₂), 3.91-3.89 (m, 1H, CH(CH₃)₂), 3.14 (s, 3H, CH₃), 3.07 (s, 3H, CH₃), 2.04-1.79 (m, 3H, cyclohexyl-H), 1.76-1.55 (m, 2H, cyclohexyl-H), 1.43-1.41 (m, 3H, cyclohexyl-H), 1.30-1.27 (m, 3H, cyclohexyl-H), 1.21-1.19 (m, 2H, cyclohexyl-H), 0.90-0.86 (m, 3H, cyclohexyl-H), 0.64 (s, 1H, cyclohexyl-H), 0.36-0.25 (m, 3H, cyclohexyl-H). Discernable ¹³C {¹H} NMR cannot be obtained due to the limited solubility in o-DCB-d₄ even at high temperature. ¹¹B{¹H} NMR (192 MHz, CD₃CN, 20° C.) δ 36.5 (B⁺), −6.7 (BPh₄). Anal. Calcd. For C₆₅H₆₅B₂N₅:C, 83.24; H, 6.99; N, 7.47%. Found: C, 83.50; H, 6.70; N, 7.50%.

Azaboratrtracenium ion 2b (synthesized from 5b and CDC ligand L2), orange-red solid (75 mg, 76% yield). ¹H NMR (600 MHz, o-DCB-d₄, 145° C.) § 8.18 (s, 1H, Ar—H), 7.98 (s, 1H), 7.79 (d, J=8.5 Hz, 1H, Ar—H), 7.69-7.67 (m, 8H, BPh₄-ArH 8H), 7.43-7.40 (m, 2H, Ar—H), 7.36-7.28 (m, 2H, Ar—H), 7.25-7.16 (m, 6H, Ar—H overlap with o-DCB-d₄), 7.11-7.06 (m, 4H, Ar—H), 6.99 (t, J=7.3 Hz, 8H, BPh₄-ArH 8H), 6.84 (t, J=7.2 Hz, 4H, BPh₄-ArH 4H), 6.46 (dd, J=9.3, 6.0 Hz, 1H, Ar—H), 5.93 (t, J=6.8 Hz, 1H, Ar—H), 4.11-4.01 (m, 2H, CH(CH₃)₂), 3.21 (s, 3H, CH₃), 3.08 (s, 3H, CH₃), 1.94-1.83 (m, 3H, cyclohexyl-H), 1.66-1.13 (m, 11H, cyclohexyl-H), 0.91-0.69 (m, 4H, cyclohexyl-H), 0.33-0.29 (m, 2H, cyclohexyl-H). Discernable ¹³C {¹H} NMR cannot be obtained due to the limited solubility in o-DCB-d₄ even at the high temperature. ¹¹B{¹H} NMR (192 MHz, CD₃CN, 20° C.) δ 37.8 (B⁺), −6.7 (BPh₄). Anal. Calcd. For C₆₉H₆₇B₂N₅:C, 83.89; H, 6.84; N, 7.09%. Found: C, 83.60; H, 6.69; N, 6.89%.

Azaboraanthracenium ion 3a (synthesized from 5a and NHC ligand L3), light yellow powder (44 mg, 65% yield). ¹H NMR (800 MHz, CD₃CN, 20° C.) δ 8.00 (dd, J=8.4, 1.1 Hz, 1H, ArCH), 7.83 (ddd, J=8.2, 6.8, 1.3 Hz, 1H, ArCH), 7.73 (dt, J=7.9, 1.1 Hz, 1H, ArCH), 7.65-7.62 (m, 2H, ArCH), 7.60 (s, 1H, ArCH), 7.44 (ddd, J=7.9, 6.8, 1.0 Hz, 1H, ArCH), 7.28-7.26 (m, 8H, BPh₄-ArCH), 7.10 (ddd, J=9.3, 6.7, 1.0 Hz, 1H, ArCH), 6.99 (t, J=7.5 Hz, 8H, BPh₄-ArCH), 6.85-6.83 (m, 4H, BPh₄-ArCH), 6.65 (ddd, J=7.3, 6.3, 1.2 Hz, 1H, ArCH), 4.31 (hept, J=6.9 Hz, 2H, CH(CH₃)₂), 2.45 (s, 6H, CH₃), 1.32 (d, J=6.9 Hz, 6H, CH(CH₃)₂), 1.25 (d, J=6.9 Hz, 6H, CH(CH₃)₂). ¹³C {¹H} NMR (800 MHz, CD₃CN, 20° C.) δ 164.9 (q, J=48.3 Hz), 142.4, 140.0, 136.8, 135.1, 134.2, 133.5, 130.5, 128.2, 128.1, 126.7 (q, J=3.3 Hz), 126.6, 125.1, 122.8, 114.7, 112.4, 54.6, 22.4, 21.6, 10.5. 11B{¹H} NMR (192 MHz, CD₃CN, 20° C.) δ 31.8 (B⁺), −6.6 (BPh₄). Anal. Calcd. For C₄₇H₄₉B₂N3:C, 83.32; H, 7.29; N, 6.20%. Found: C, 83.32; H, 7.39; N, 6.02%.

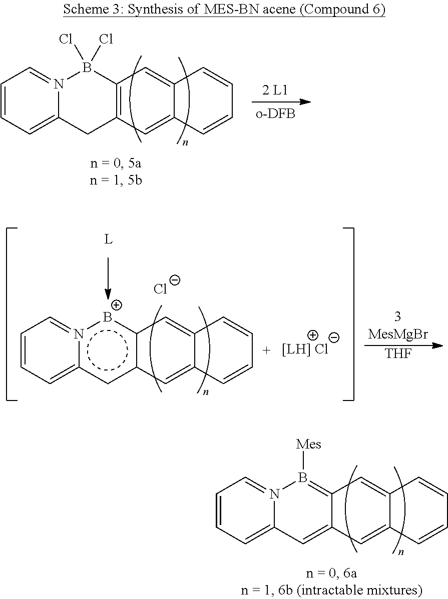

To a solution of CDC ligand L1 (140 mg, 0.4 mmol, 2 eq.) in o-DFB (3 mL), the corresponding dichloroborane derivative 5a/5b (50 mg for 5a, 60 mg for 5b, 0.2 mmol, 1 eq.) was added in the dark. The reaction was stirred at room temperature for 18 hrs. The solution was filtered through a 0.25 μm PTFE syringe filter and the solvent was removed under vacuum. The residue was redissloved in THF (5 mL) and cooled to 0° C., MesMgBr (1 M in THF) (0.6 mL, 3 eq.) was added dropwise and stirred at r.t. for 3 hrs. After filteration through a plug of silica gel (1 cm) in the glovebox and washed with THE, the volatiles were removed in vacuo to give the title compound (6a or 6b).

6a (synthesized from 5a), yellow powder (44 mg, 77% yield). ¹H NMR (600 MHz, CD₂Cl₂, 20° C.) δ 7.79 (m, 1H), 7.71 (ddd, J=7.8, 1.5, 0.8 Hz, 1H), 7.66 (ddd, J=8.2, 6.8, 1.4 Hz, 1H), 7.57 (dt, J=7.3, 1.1 Hz, 1H), 7.33 (dt, J=9.2, 1.3 Hz, 1H), 7.24 (ddd, J=7.8, 6.8, 1.1 Hz, 1H), 7.09 (s, 1H), 6.97 (m, 2H, Mes-ArCH), 6.84 (ddd, J=9.2, 6.0, 1.3 Hz, 1H), 6.23 (ddd, J=7.4, 6.1, 1.4 Hz, 1H), 2.38 (s, 3H, Mes-CH₃), 1.96 (s, 6H, Mes-CH₃). ¹¹B{¹H} NMR (192 MHz, CD₂Cl₂, 20° C.) δ 40.8. The 1H-NMR and ¹¹B—NMR data in agreement with the literature.

Compound 6b was obtained as an intractable mixture. The red crude solution is prone to rapid decomposition (with noticeable color fading) in solution even under dark during work up in the glove box.

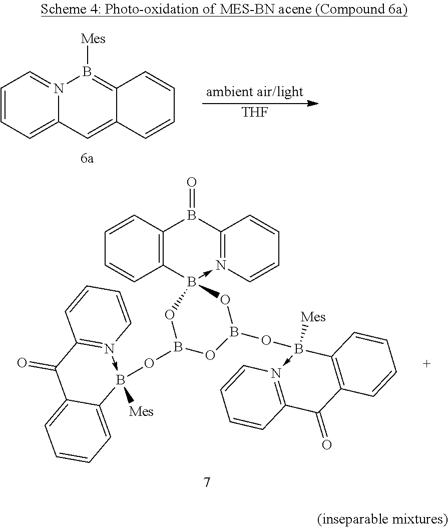

A solution of 6a (297 mg, 1 mmol) in THF (5 mL) was prepared and allowed to stir under ambient light while exposed to air. The solution color faded after ca. 8 hours and NMR analysis indicated the crude product contained inseparable mixtures. However, a single crystal from was grown from the mixtures, and the structure was identified to be 7. A proposed mechanism for the formation 7 via zwitterionic intermediates is shown in FIG. 16.

### Photophysical Data

All steady-state spectra were obtained using an Agilent Cary Eclipse Fluorescence spectrophotometer equipped with the photomultiplier tube (PMT) detector. Absolute fluorescence quantum yields were determined using a Hamamatsu C11347-11 Quantaurus-QY Absolute PL Quantum Yield Spectrometer. Samples were prepared inside the glovebox in quartz Petri dishes (solid sample) or 1 cm square quartz cuvettes (solutions). Solutions were prepared in toluene and data were collected with absorbance values below 0.05. Time-correlated single photon counting (TCSPC) was employed to obtain all fluorescence lifetime spectra, which was achieved with an Edinburgh Instruments FS5 spectrofluorometer equipped with pulsed LEDs at 340 nm. The signal level was kept below 5% of the light source repetition rate. Instrument response functions (IRF) were determined from the scatter signal solution of Ludox HS-40 colloidal silica (~1% particles in water w/w). The decay traces analysis was performed using the Fluoracle software (Edinburgh Instruments) and fitted with the mono-exponential function and/or multi-exponential decay function. The quality of fit was judged on the basis of the reduced chi-square statistic, χ², and the randomness of residuals.

TABLE 2
Summary of QYs, lifetimes, and decay rate constants
for 1, 2 and 3a in toluene at 298 K (under Argon).

| Compound | 1a | 1b | 2a | 2b | 3a |
|---|---|---|---|---|---|
| Φ_{F}^{[a]} | 0.53 | 0.29 | 0.62 | 0.34 | 0.31 |
| τ/ns^{[b]} | 2.9 | 4.6 | 5.4 | 5.2 | 6.2 |
| kᵣ/×10⁸ s^{-1[c]} | 1.83 | 0.63 | 1.15 | 0.65 | 0.50 |
| kₙᵣ/×10⁸ s^{-1[c]} | 1.62 | 1.54 | 0.68 | 1.26 | 1.11 |

^{[a]}Absolute QYs.
^{[b]}Lifetime values were collected at λex = 340 nm.
^{[c]}Radiative constant kr = ΦF/τ, non-radiative constant knr = (1 − ΦF)/τ.

TABLE 3
Summary of QYs, lifetimes, and decay rate constants
for 1 and 2 in 2-MeTHF at 77 K (data at 298
K in 2-MeTHF are given in parentheses).

| Compound | 1a | 2a | 1b | 2b |
|---|---|---|---|---|
| Φ_{F}^{[a]} | 0.88 (0.16) | 0.98 (0.30) | 0.35 (0.19) | 0.32 (0.23) |
| τ/ns^{[b]} | 11.7 (4.3) | 12.2 (6.5) | 5.1 (4.7) | 6.0 (5.4) |
| kᵣ/×10⁸ s^{-1[c]} | 0.75 (0.37) | 0.80 (0.46) | 0.69 (0.40) | 0.53 (0.42) |
| kₙᵣ/×10⁸ s^{-1[c]} | 0.18 (1.95) | 0.02 (1.08) | 1.27 (1.72) | 1.13 (1.43) |

^{[a]}Absolute QYs.
^{[b]}Lifetime values were collected at λex = 340 nm.
^{[c]}Radiative constant kr = ΦF/τ, non-radiative constant knr = (1 − ΦF)/τ.

### X-Ray Crystallography Details

Single crystals of 1a, 1b, 2a, 2b, 3a, 3b, or 7 were coated with Paratone oil and mounted on a MiTeGen MicroLoop. The X-ray intensity data were measured on a Bruker D8 Venture Kappa four-circle diffractometer system. An Incoatec IpS 3.0 micro-focus sealed X-ray tube (Mo Kα, λ=0.71073 Å) and a HELIOS double bounce multilayer mirror monochromator were used for 1a, 1b, 2b, and 3a. An Incoatec IpS 3.0 micro-focus sealed X-ray tube (Cu Kα, Δ=1.54178 Å) and a HELIOS EF double bounce multilayer mirror monochromator were used for 2a, 3b, and 7. The frames were integrated with the Bruker SAINT software package using a narrow-frame algorithm. Data were corrected for absorption effects using the Multi-Scan method (SADABS). Each structure was solved and refined using the Bruker SHELXTL Software Package within APEX4 and OLEX2. Non-hydrogen atoms were refined anisotropically. Hydrogen atoms were placed in geometrically calculated positions with Uᵢₛₒ=1.2U_{equiv} of the parent atom (1.5U_{equiv} for methyl).

The relative occupancies of the disordered atoms in 1a, 1b, 2a, 3b and 7 were freely refined. In 3a, the occupancy of the disordered atoms was set to 50% because of the symmetry of the atoms. Constraints and restraints were used on the anisotropic displacement parameters and/or bond lengths of most of the disordered atoms in these structures. In 1a, 1b and 7, disordered solvent located in the crystal lattice was severely disordered and could not be adequately modeled with or without restraints. Thus, the structure factors were modified using the PLATON SQUEEZE⁸ technique, in order to produce a “solvate-free” structure factor set. PLATON reported a total electron density of 639 e⁻ and total solvent accessible volume of 2344 Å³ for 1a (a mixture of CH₂Cl₂, hexanes, diethyl ether), 206 e and total solvent accessible volume of 571 Å³ for 1b (CH₂Cl₂), and 98 e; and total solvent accessible volume of 428 Å³ for 7 (a mixture of CH₂Cl₂, hexanes, benzene).

### Theoretical Calculations

General. All geometries were optimized with Orca 5.2.1., using the B₃LYP functional in conjunction with a triple-¿ quality basis set (def2-TZVP). The dispersion corrections were introduced using the Grimme D3-parametrized correction and the Becke Johnson damping to the DFT energy. The RIJCOSX approximation was used to reduce the computational cost of calculations. The initial structures were generated from the above X-ray crystallography data while the counter anions (BPh₄) were not included. The bond lengths errors for all optimized structures are within 0.02 Å when compared to the crystal structure. In addition, characterization of stationary points as minima were verified by analytical vibrational mode analysis.

Natural bond order (NBO) and natural population analysis (NPA) were performed using NBO 6.0 program at the B₃LYP-D3(BJ)/def2-TZVP level of theory. The out-of-plane nucleus-independent chemical shift [NICS (1)] and [NICS (1)_{zz}] were calculated at the GIAO-B₃LYP-D3(BJ)/pcSseg-2 level of theory at the geometrical center of the ring. Due to the nonplanarity of the BN-acene backbone, the NICS (1) and NICS (1)_{zz} values are the average of NICS (1)/NICS(−1) and NICS (1)_{zz}/NICS(−1)_{zz}, respectively. In that analysis the aromatic rings have negative values and nonaromatic rings have positive values. The anisotropy of the current (induced) density (ACID) and localized orbital indicator function (LOL-π) calculations were carried out at B₃LYP-D3(BJ)/def2-TZVP level of theory. Except for the NBO analysis, all the calculations were performed with Gaussian 16, the wavefunction analysis were conducted using Multiwfn program. Coordination of the azaboraacenes and ligands were investigated using the extended transition state method for energy decomposition analysis combined with the natural orbitals for chemical valence theory (ETS-NOCV) as implemented in the ORCA 5.2.1. For the intrinsic bond orbitals (IBOs) calculations, wave functions were obtained in the ORCA 5.2.1 and structural depictions were made using the IboView. The spin-orbit coupling (SOC) matrix elements between Sₘ/Tₙ states were calculated with PySOC interfaced to the Gaussian 16 program. The detailed electronic structures of 1a and 1b were investigated using the fractional occupation weighted density (FOD) analyses were performed at the TPSS/def2-TZVPP level of theory. The T₁ diagnostics value were extracted from the domain-based local pair natural orbital coupled cluster singles and doubles with perturbative triple excitations [DLPNO-CCSD (T)] calculations at cc-pVTZ levels of theory. Both wavefunction theory calculations are performed by using the Orca 5.2.1 package.

QTAIM Analysis and Non-Covalent Interactions (NCI) Plot. The QTAIM analyses were conducted based on the optimized geometries. A bonding critical point (BCP) in accordance with the AIM theory locates between two atoms containing the considered bond. The most important parameters for description of the interaction are the electron density ρ(r) and the Laplacian of the electron density [∇²ρ(r)]. In general, large values of the electron density ρ(r) indicate a strong bonding interaction (for the same type of chemical bond). A negative ∇²ρ(r) shows the excess potential energy at the BCP which means that the electronic charge is contracted between two nuclei (covalent interaction), while a positive ∇²ρ(r) reveals that the kinetic energy contribution is greater than the potential energy (closed-shell interaction). QTAIM topological parameter G(r) is the Lagrangian kinetic energy and V(r) is the local potential electron energy density. The sign of electronic energy H(r) on the Hamiltonian at BCP determines whether the accumulation of charge at a given point is stabilizing [H(r)<0] or destabilizing [H(r)>0]. The nature of bond can be evaluated by means of the |V(r)|/G(r). If |V(r)|/G(r)>2, then the bond has covalent character while for the 1<|V(r)|/G(r)<2, the bond has partially covalent character. If |V(r)|/G(r)<1, suggesting the bonding is closed-shell interaction.

To visualize the position and different types of non-covalent interactions in 3D space, the gradient isosurfaces (cutoff=0.5 a.u.) of the reduced density gradient (RDG) at low densities, colored on a blue-green-red scale according to values of sign (λ₂)ρ(r) (ranging from −0.025 to 0.03 a.u.) were obtained. The blue isosurface represents strong attractive interactions, green indicates van der Waals interactions and red indicates repulsive/steric interactions.

TD-DFT Calculations. The TD-DFT vertical excitation calculations were performed at the B₃LYP-D3(BJ)/ma-def2-TZVP//B₃LYP-D3(BJ)/def2-TZVP level of theory using Gaussian 16 Rev B.01. It is well-known that the reliability of the TDDFT results strongly depends on the choice of the exchange-correlation functional, additional hybrid functions such as TPPSh-D3(BJ) (10% HF exchange), PBE0-D3(BJ) (25% HF exchange) theory and long-range-corrected CAM-B₃LYP-D3(BJ) (composed of 19% HF exchange at short-range and 65% HF exchange at long-range, ideally for charge-transfer (CT) excitations) with the unified ma-def2-TZVP basis set were also evaluated on 1b. The results suggest that TPPSh-D3(BJ) and PBE0-D3(BJ) theory reproduced the trend in the experimental spectra of all the cations, and B₃LYP-D3(BJ) (20% HF exchange) yielded the most reliable energy ordering and the excitation energies in the excited states for all the compounds. The CAM-B₃LYP-D3(BJ) method led to significantly blue-shifted electronic transition energies (>0.3 eV) with respect to the experimental values and failed to reproduce the experimentally obtained absorption characteristics, which further validated the local excitation (LE) transition characters for these types of compounds. The optimizations and single-point TD-DFT calculations were performed in solvent using the conductor-like polarisable continuum model (CPCM) with parameters for toluene. Both the state-specific (SS) and corrected-linear response (cLR) approaches were assessed, and the difference are minimal (within 2 nm) due to the small change of the electron density for vertical excitation/de-excitations. Thus, the cLR scheme is sufficient for describing the environment response in solution. Due to the fact that possible vibrational progression on the rigid azaboraacene frameworks may couple with the absorption band, vibrationally-resolved UV-Vis absorption spectra (only for S₁→S₀ transitions in 1b and 3a due to the significantly large computational costs found in analogues 2) were predicted based on the Franck-Condon analysis, as it is implemented in Gaussian 16. The ground and excited state optimizations and frequency calculations were obtained at the B₃LYP-D3(BJ)/TZVP level of theory in implicit solvent (toluene) via PCM.

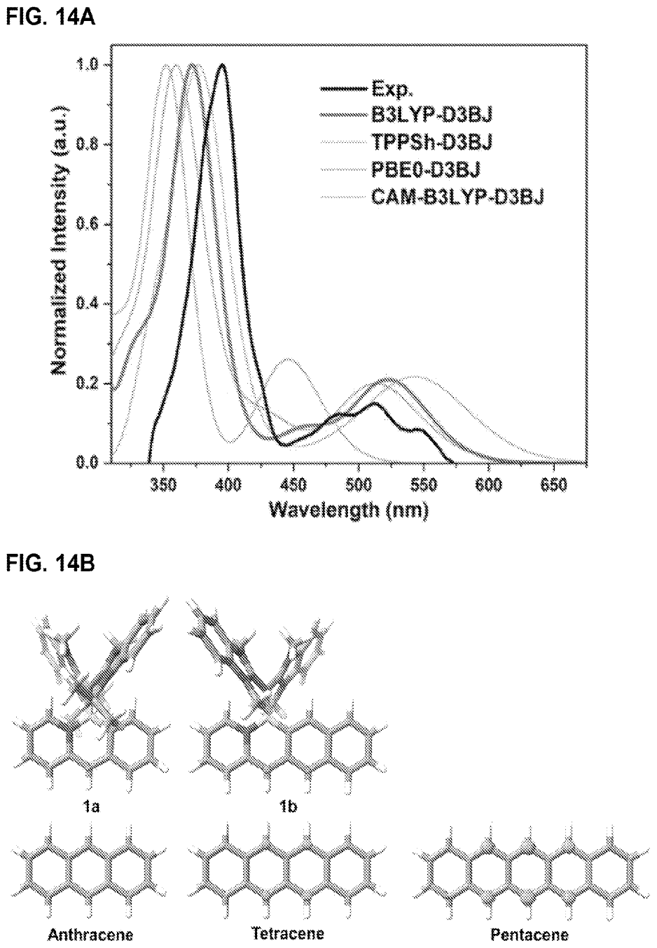

Separately, since the longer linear fused acenes may exhibit potential multireference characters, the electronic structures of chromophores 1a and 1b in their ground states were further evaluated using the T1 diagnostics, which were calculated at the DLPNO-CCSD (T)/cc-pVTZ levels of theory base on their stable KS-DFT wavefunctions. The T₁ diagnostics values for 1a and 1b are calculated to be 0.0111 and 0.0114, respectively, which are significantly smaller than 0.02 threshold. Furthermore, we performed fractional occupation number weighted density (FOD) calculations as a static electron correlation diagnostic to analyze the ground sate electronic structures of 1a and 1b as well as the all-carbon acenes. The FOD plot provide reliable information on the localization of “hot” (strongly correlated and chemically active) electrons in a molecule. As shown in FIGS. 14A-14B, the ‘hot’ electrons spatial distribution at the atoms of 1a and 1b are highly localized and less visible than their parent all-carbon acenes, which suggest even weaker multireference cases among BN-anthracenium and -tetracenium ions than the short-length acenes. Therefore, we believe the single-reference results presented in this study are reliable predictions.

TABLE 4
Selected wavelength, oscillator strength (f) and
major configuration from the TD-DFT calculation
(at the B3LYP-D3(BJ)/ma-def2-TZVP//B3LYP-D3(BJ)/def2-
TZVP (PCM, toluene) level of theory) for 1a.

| | | electronic | | |
|---|---|---|---|---|
| | λ_{cal} (nm) | transitions | f | Major configurations |
| 1a | 437 | S₁ ← S₀ | 0.1698 | HOMO→LUMO (97%) |
| | 420 | S₂ ← S₀ | 0.1860 | HOMO→LUMO + 1 (98%) |
| | 374 | S₃ ← S₀ | 0.2072 | HOMO − 1→ LUMO + 2 (82%) |
| | | | | HOMO→LUMO + 2 (8%) |
| | 365 | S₄ ← S₀ | 0.0930 | HOMO − 1→LUMO (86%) |
| | 358 | S₅ ← S₀ | 0.5486 | HOMO − 1→LUMO + 1(93%) |
| | 325 | S₆ ← S₀ | 0.0360 | HOMO − 1→LUMO + 2 (78%) |
| | | | | HOMO→LUMO + 3 (17%) |
| | 321 | S₇ ← S₀ | 0.2162 | HOMO→LUMO + 3 (72%) |
| | | | | HOMO − 1→LUMO + 2 (18%) |
| | 303 | S₈ ← S₀ | 0.0349 | HOMO→LUMO + 4 (82%) |

. . .

TABLE 5
Selected wavelength, oscillator strength (f) and
major configuration from the TD-DFT calculation
(at the B3LYP-D3(BJ)/ma-def2-TZVP//B3LYP-D3(BJ)/def2-
TZVP (PCM, toluene) level of theory) for 1b.

| | | electronic | | |
|---|---|---|---|---|
| | λ_{cal} (nm) | transitions | f | Major configurations |
| 1b | 524 | S₁ ← S₀ | 0.1667 | HOMO→LUMO (98%) |
| | 459 | S₂ ← S₀ | 0.0675 | HOMO→LUMO + 1 (99%) |
| | 414 | S₃ ← S₀ | 0.0215 | HOMO − 1→LUMO (96%) |
| | 389 | S₄ ← S₀ | 0.1718 | HOMO→LUMO + 2 (88%) |
| | 371 | S₅ ← S₀ | 0.6811 | HOMO − 1→LUMO + 1(95%) |
| | 349 | S₆ ← S₀ | 0.099 | HOMO→LUMO + 3 (73%), |
| | | | | HOMO→LUMO + 4 (18%) |
| | 341 | S₆ ← S₀ | 0.1258 | HOMO→LUMO + 3 (18%), |
| | | | | HOMO→LUMO + 4 (62%) |
| | 324 | S₇ ← S₀ | 0.0793 | HOMO − 1→LUMO + 2 (93%) |

. . .

TABLE 6
Selected wavelength, oscillator strength (f) and
major configuration from the TD-DFT calculation
(at the B3LYP-D3(BJ)/ma-def2-TZVP//B3LYP-D3(BJ)/def2-
TZVP (PCM, toluene) level of theory) for 2a.

| | | electronic | | |
|---|---|---|---|---|
| | λ_{cal} (nm) | transitions | f | Major configurations |
| 2a | 437 | S₁ ← S₀ | 0.1523 | HOMO→LUMO (97%) |
| | 417 | S₂ ← S₀ | 0.1906 | HOMO→LUMO + 1 (98%) |
| | 374 | S₃ ← S₀ | 0.1821 | HOMO − 1→LUMO (31%) |
| | | | | HOMO→LUMO + 2 (60%) |
| | 369 | S₄ ← S₀ | 0.0893 | HOMO − 1→LUMO + 2 (64%) |
| | | | | HOMO→LUMO + 2 (30%) |
| | 360 | S₅ ← S₀ | 0.5464 | HOMO − 1→LUMO + 1(94%) |
| | 327 | S₆ ← S₀ | 0.0871 | HOMO − 1→LUMO + 2 (91%) |
| | 320 | S₇ ← S₀ | 0.1551 | HOMO→LUMO + 3 (85%) |
| | 303 | S₈ ← S₀ | 0.0320 | HOMO→LUMO + 4 (84%) |

. . .

TABLE 7
Selected wavelength, oscillator strength (f) and
major configuration from the TD-DFT calculation
(at the B3LYP-D3(BJ)/ma-def2-TZVP//B3LYP-D3(BJ)/def2-
TZVP (PCM, toluene) level of theory) for 2b.

| | | electronic | | |
|---|---|---|---|---|
| | λ_{cal} (nm) | transitions | f | Major configurations |
| 2b | 519 | S₁ ← S₀ | 0.1446 | HOMO→LUMO (98%) |
| | 445 | S₂ ← S₀ | 0.0626 | HOMO→LUMO + 1 (99%) |
| | 422 | S₃ ← S₀ | 0.0134 | HOMO − 1→LUMO (97%) |
| | 387 | S₄ ← S₀ | 0.1744 | HOMO→LUMO + 2 (89%) |
| | 370 | S₅ ← S₀ | 0.7471 | HOMO − 1→LUMO + 1(96%) |
| | 347 | S₆ ← S₀ | 0.1538 | HOMO→LUMO + 3 (68%), |
| | | | | HOMO→LUMO + 4 (22%) |
| | 337 | S₇ ← S₀ | 0.0561 | HOMO − 2→LUMO (10%), |
| | | | | HOMO→LUMO + 3 (18%), |
| | | | | HOMO→LUMO + 4 (62%) |
| | 329 | S₈ ← S₀ | 0.0659 | HOMO − 1→LUMO + 2 (92%) |

. . .

TABLE 8
Selected wavelength, oscillator strength (f) and
major configuration from the TD-DFT calculation
(at the B3LYP-D3(BJ)/ma-def2-TZVP//B3LYP-D3(BJ)/def2-
TZVP (PCM, toluene) level of theory) for 3a.

| | | electronic | | |
|---|---|---|---|---|
| | λ_{cal} (nm) | transitions | f | Major configurations |
| 3a | 404 | S₁ ← S₀ | 0.1168 | HOMO→LUMO (97%) |
| | 351 | S₂ ← S₀ | 0.3006 | HOMO→LUMO + 1 (91%) |
| | 335 | S₃ ← S₀ | 0.0128 | HOMO→LUMO + 2 (98%) |
| | . . . | | | |
| | 258 | S₆ ← S₀ | 0.2335 | HOMO − 3→LUMO (30%), |
| | | | | HOMO − 2→LUMO (48%), |
| | | | | HOMO→LUMO + 5 (10%) |
| | 250 | S₇ ← S₀ | 0.5362 | HOMO − 3→LUMO (53%), |
| | | | | HOMO − 2→LUMO + 1 (23%), |

. . .

TABLE 9
The calculated vertical emission energies (E^{vert-fluo}) for 1, 2
and 3a at PCM(toluene)-B3LYP-D3(BJ)/TZVP level of theory.
E^{vert-flo}: vertical emission energy of the first excited singlet at ground
state geometry. λₑₘ^{cal}: calculated emission wavelength, in nm. ΔE_{S0}:
HOMO-LUMO gap for the ground state. ΔE_{S1}: HOMO-LUMO gap
for the first excited singlet state. Energies given in eV.

| | 1a | 1b | 2a | 2b | 3a |
|---|---|---|---|---|---|
| E^{vert-fluo} | 2.36 | 1.98 | 2.37 | 2.00 | 2.56 |
| λₑₘ^{cal} | 524 | 624 | 522 | 621 | 485 |
| ΔE_{S0} | 3.38 | 2.85 | 3.25 | 2.88 | 3.55 |
| ΔE_{S1} | 3.40 | 2.45 | 3.41 | 2.46 | 3.00 |

TZVP level of theoThe emission spectra are independent of the excitation wavelength and the obtained excitation spectra are similar to the absorption spectra, thus S₁→S₀ fluorescence emission are observed and obey Kasha's rule. E^{vert-fluo} are consistent with the observed emission peaks in the spectroscopic studies.

Calculated Values for the Energy-matching Conditions for Singlet Fission (SF). Using the S₀ geometries of 1a, 1b and 2b (obtained at B₃LYP-D3(BJ)/def2-TZVP level of theory) as starting point, the S₁ and T₂ energies were computed using TD-DFT at B₃LYP-D3(BJ)/def2-TZVP level of theory, while T₁ were optimized by the unrestricted density functional theory (UDFT) method at B₃LYP-D3(BJ)/def2-TZVP level of theory. Their energies (S₁, T₁ and T₂) are estimated based on adiabatic processes in gas phase. The values of <S**2> are calculated to check the spin contamination effect on triplet excitation states, and reveal that the spin operators are extremely close to two (the exact value for triplet), indicating no spin contamination effect found for T₁ and T₂. The reliability of our calculations was verified by comparing the experimental values of E(S₁), E(T₁), and ΔE_{SF} of tetracene with the respective calculated values (Table 10), which showed the experimental and computed values for E(S₁) and E(T₁) agreed very well. It should be noted that complicated contribution of MOs are found for the T₂ state of 1b [HOMO-2→LUMO (19%), HOMO-1→LUMO (12%), HOMO→LUMO+2 (52%), and HOMO→LUMO+3 (10%)] and tetracene [HOMO-1→LUMO (57%), HOMO-LUMO+1 (38%)] as well as the mixed transition characters (LE³+CT³) for T₂ states of 1b/2b, thus the current single-reference DFT-based theory might be not well suited to estimate E(T₂). Multireference configuration interaction methods like the complete active space self-consistent field (CASSCF) or complete active space second-order perturbation theory (CASPT2) calculations are necessary to precisely determine the E(T₂), which is beyond the scope of this paper due to too high computational cost.

TABLE 10
Summary of the calculated energies (in eV, at the B3LYP-
D3(BJ)/def2-TZVP level) of the S₁, T₁ and T₂ states relatives
to the energy of their S₀ state of 1, 2b and tetracene.
E(S₁)_{adiab}: adiabatic excitation energy of the first excited singlet.
E(T₁)_{adiab}: adiabatic excitation energy of the first excited triplet.
E(T₂)_{adib}: adiabatic excitation energy of the second excited triplet.
ΔE_{SF}: energies related to singlet fission efficiency calculated as
2E(T₁)_{adiab} − E(S₁)_{adiab}. ΔE_{T}: energies related to 2E(T₁)_{adiab} − E(T₂)_{adiab}.

| | E(S₁)_{adiab} | E(T₁)_{adiab} | E(T₂)_{adiab} | ΔE_{SF} | ΔE_{T} |
|---|---|---|---|---|---|
| 1a | 2.61 | 1.51 | 2.50 | 0.41 | 0.52 |
| 1b | 2.20 | 1.14 | 2.22 | 0.08 | 0.06 |
| 2b | 2.19 | 1.15 | 2.21 | 0.11 | 0.11 |
| Tetracene^{a} | 2.25 | 1.24 | 2.34 | 0.23 | 0.14 |
| | (2.31) | (1.25) | (2.54) | (~0.2) | |

^{a}the experimental values for tetracene are given in parentheses.

The best SF materials for a solar cell should have a very small negative ΔE_{SF} or slightly endothermic (around 0 eV), which could ensure a thermodynamically favorable SF and minimize energy loss. Organic compounds such as tetracene or pentacene have been proven as efficient SF sensitizers. Pentacene undergoes the exoergic SF process ((ΔE_{SF}=−0.11 eV) with very high SF efficiencies, however, it is not a suitable candidate for the development of single-junction S₁-based SF solar cells because its E(T₁) (0.86 eV) is significantly below E_{g} of S₁ (1.11 eV). For tetracene, it has a matching E(T₁) (1.25 eV) and undergoes larger endoergic SF (ΔE_{SF}≈0.2 eV) with lower SF efficiency. Nevertheless, the main drawback of tetracene and pentacene is their low photostability.

Spin-orbit Coupling (SOC) Calculations. The spin-orbit coupling (SOC) matrix elements (<Sₘ|Ĥ_{SO}|Tₙ>) between Sₘ (m=0, 1, 2, . . . ) and In (n=1, 2, . . . ) states were calculated to investigate the tendency of spin-forbidden Sₘ/Tₙ state processes such as intersystem crossing (ISC) and phosphorescence. All SOCs were computed at TDDFT-B₃LYP-D3(BJ)/TZVP level based on the equilibrium S₁ geometries of 1b and 2b and the three Tₘ sublevels (ms=+1, 0, −1) are considered to be degenerate. The SOCs for Sₘ/T₁ in 1b/2b are non-zero (S₁/T₁; S₂/T₁; S₂/T₂) compared to the hydrocarbon tetracene (nearly 0 cm⁻¹ between the low-lying Sₘ and In), which indicates stronger couplings and would promote the Sₘ/Tₙ ISC (via thermal and/or vibrational coupling), leading to high triplet yields for the SF process. Inventors' note that the E(S₁) and E(T₂) are very close in energy (similar to tetracene), a feature that can lead to an S₁/T₂ reverse intersystem crossing (RISC). However, one still cannot discard the possibility for singlet exciton fission because the calculated SOC for S₁/T₂ is around 0.1 cm⁻¹, suggesting weak coupling. For an effective SF chromophore, the long-lived T₁ excitons are desirable. The results showed that the SOC elements for T₁/S₀ channel in 1b and 2b were less than 0.1 cm⁻¹, which is comparable to the pure hydrocarbon tetracene (all the SOCs for tetracene were nearly ~0 cm⁻¹), suggesting T₁ excitons should be long-lived and the phosphorescence would be weak. Spin-orbit coupling matrix elements for 1b and 2b are shown in Tables 11-12.

TABLE 11
Spin-orbit coupling (SOC) matrix elements (in cm⁻¹) between
the low-lying singlet Sₘ and triplet excited states Tₙ of 1b.

| Sₘ | Tₙ | <Sₘ\|Ĥ_{SO}\|Tₙ> |
|---|---|---|
| 0 | 1 | 0.09 |
| 1 | 1 | 0.24 |
| 2 | 1 | 0.70 |
| 0 | 2 | 0.46 |
| 1 | 2 | 0.09 |
| 2 | 2 | 0.64 |

TABLE 12
Spin-orbit coupling (SOC) matrix elements (in cm⁻¹) between
the low-lying singlet Sₘ and triplet excited states Tₙ of 2b.

| Sₘ | Tₙ | <Sₘ\|Ĥ_{SO}\|Tₙ> |
|---|---|---|
| 0 | 1 | 0.11 |
| 1 | 1 | 0.29 |
| 2 | 1 | 0.58 |
| 0 | 2 | 0.40 |
| 1 | 2 | 0.10 |
| 2 | 2 | 0.51 |

### UV-Vis Spectroscopy and Kinetic Studies

To experimentally assess the stability in the solution state, UV-visible spectra were obtained using a Cary 60 UV-vis spectrometer. Dilute solutions of compounds (4.0× 10-5 M) were prepared using degassed spectroscopic grade dry THF. The cells were protected from light until each experiment began, at which point an initial spectrum was recorded. Each cell was then exposed to ambient air by loosening the cuvette cap to allow for free exchange of air, while minimizing solvent evaporation. The cells were placed on a laboratory bench under ambient light. Their UV-vis absorption spectra were taken at different time intervals to monitor the degradation process.

### Photooxidation of BN-Acene

Tetracene and its higher homologues are highly photoreactive. They undergo photochemical [4π+4π] dimerization and/or form endoperoxide with atmospheric oxygen at the most central carbon rings. The latter also known as photooxidation, which could happen in two pathways: (a) The electron transfer from PAHs to the triplet oxygen (³O₂) leads to the formation of cationic acenes and highly reactive anionic oxygen, then they interact with each other causing a degradation of acenes. Then, the singlet oxygen interacts with the PAHs leading to degradation. (b) The photoexcited PAHs could change into triplet state through intersystem crossing (ISC) and result in highly reactive singlet oxygen (¹O₂) by means of oxygen sensitization. Even so, the degradation mechanism for acenes is very complicated and still controversial.

It is suggested that the lowering of the LUMO is proposed as the source of photostabilization by reducing the rate of electron transfer to ³O₂ (pathway a), while the lowering energy of the HOMO could reduce ¹O₂ sensitization (pathway b). Generally, lower lying HOMO and LUMO energies and small triplet excitation energies are expected to be beneficial to increase the photostability of acenes. Based on the FMOs analysis (FIGS. 12A-12B and 13A-13B) and the X-ray structure of photooxidation product 7, the degradation mechanism for the aromatized BN-acene should follow similar pathways i.e., the central ring would be the more reactive sites (FIG. 16).

### Electrochemistry

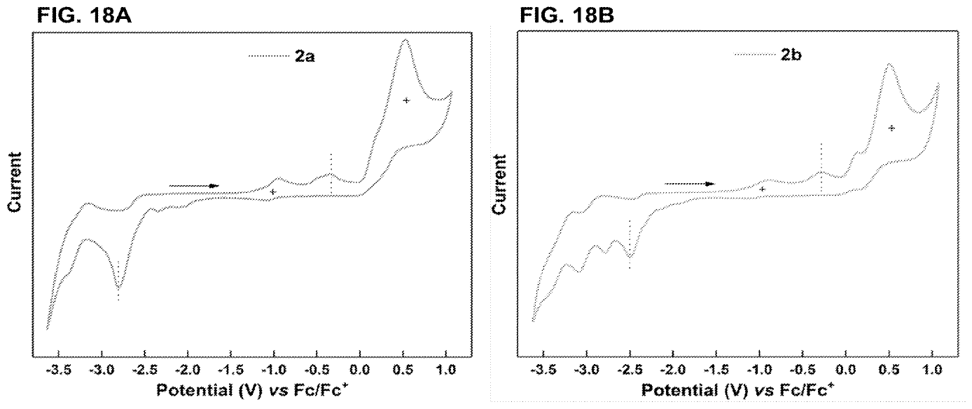

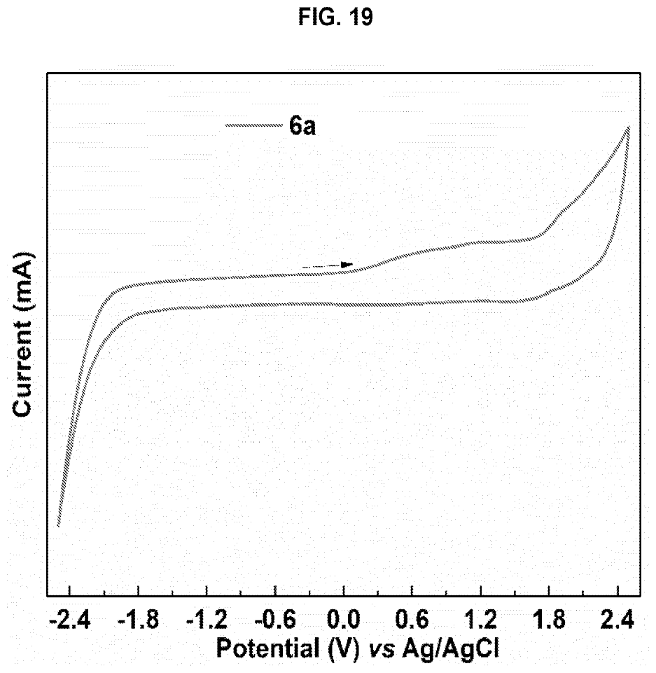

All cyclic voltammetry (CV) experiments for 1-2 and 6a were conducted using a 3-electrode geometry using a WavePico Wireless potentiostat (FIGS. 17A-17B, 18A-18B, and 19). Electrolyte solutions (0.1 M) were prepared from anhydrous, deoxygenated solvent (1-2 in THF, 6a in CH₂Cl₂) and anhydrous Bu₄NPF₆. The working electrode was a glassy carbon electrode (3-mm diameter), with a Pt-coil counter electrode and an Ag/AgCl reference. Sample concentrations were ca. 1 mM. The ferrocene/ferrocenium (Fc/Fc⁺) couple was used as an internal standard following each experiment. Compound 3a decomposed under the electrochemical experiments.

The CV test with extending scanning range (50, 100, 200, 300 mV) for 1-2 and 3a were carried out. The redox potential signals of −1.05 V, −0.38 V and 0.5 V (vs Fc/Fc⁺) in 1-2 were intrinsic feature of the CDC ligand rather instead of impurity effect. Inventors guess it may be due to the high energy of the π lone pair on the CDC ligand and strong intermolecular interactions, leading to these active oxidation potentials or solvent effect in THF.

For reasons of completeness, various aspects of the invention are set out in the following numbered clauses:

Clause 1. A compound of formula (I-a), (I-b), or (I-c),

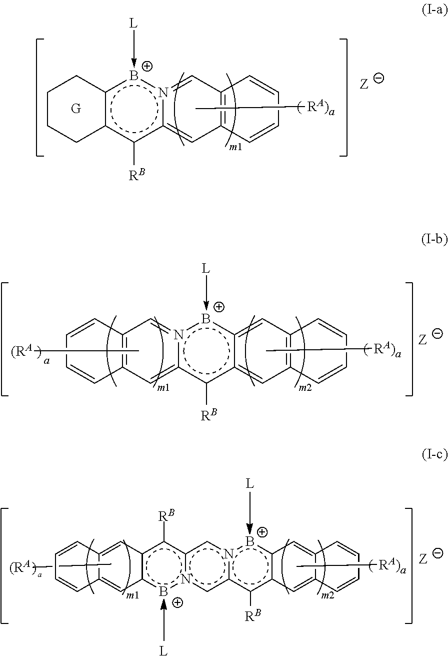

wherein
L is N-heterocyclic carbene (NHC) or a carbone having a structure of

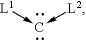

wherein each of L1 and L2 is independently a Lewis base;
G is a heteroaryl or heterocyclyl, which is optionally substituted; R^{A} at each occurrence is independently alkyl, alkoxy, haloalkyl, aryl, cyano, halogen, N(R^{A1})(R^{A1}), S(R^{B}), or thiophenyl;
R^{B} at each occurrence is independently hydrogen, alkyl, an optionally substituted aryl, or C≡CSi(R^{B1})₃;
R^{A1} at each occurrence is independently hydrogen, alkyl, or aryl, or two R^{A1} together with the nitrogen atom to which they are attached form a ring;
R^{B1} at each occurrence is independently alkyl;
a at each occurrence is independently 0-20;
m1 is 0-10;
m2 is 0-10; and
Z is a counterion.

Clause 2. The compound of clause 1, which is a compound of formula (I-a-i) or (I-c-i)

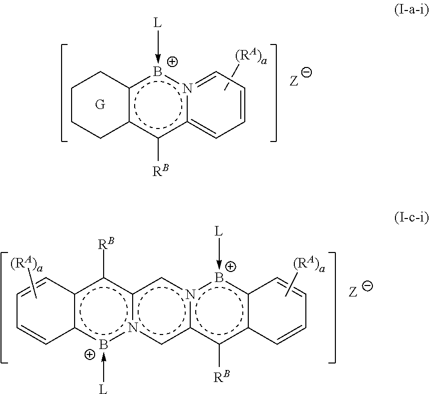

wherein a at each occurrence is independently 0, 1, 2, 3, or 4.

Clause 3. The compound of clause 1, which is a compound of formula (I-b), wherein m2 is 0 or 1.

Clause 4. The compound of clause 3, wherein m1 is 0 or 1.

Clause 5. The compound of clause 1, which is a compound of formula (I-b-i)

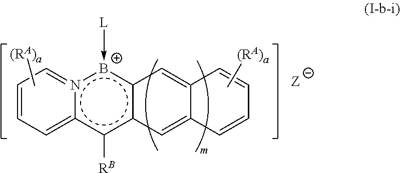

wherein
a at each occurrence is independently 0, 1, 2, 3, or 4; and
m2 is 0 or 1.

Clause 6. The compound of clause 5, wherein a at each occurrence is 0.

Clause 7. The compound of any one of clauses 1-6, wherein R^{A} at each occurrence is independently OMe, CN, CF₃, NMe₂, SMe, NPh₂, halogen, or Ph.

Clause 8. The compound of any one of clauses 1-7, wherein R^{B} is hydrogen,

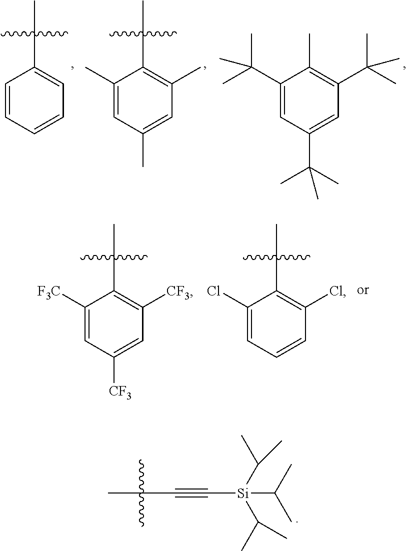

Clause 9. The compound of any one of clauses 1-8, wherein L is an N-heterocyclic carbene (NHC) of

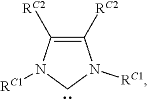

wherein
R^{C1} at each occurrence is independently alkyl, cycloalkyl, optionally substituted aryl, or optionally substituted heteroaryl;
R^{C2} at each occurrence is independently alkyl, cycloalkyl, optionally substituted aryl, or optionally substituted heteroaryl; or
R^{C1} and adjacent R^{C2}, together with the nitrogen and carbon atoms to which they are attached, respectively, form a ring; or
two adjacent R^{C2}, together with the carbon atoms to which they are attached form a ring.

Clause 10. The compound of clause 9, wherein L is

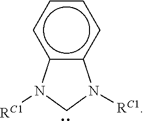

Clause 11. The compound of clause 10, wherein R^{C1} at each occurrence is independently methyl, isopropyl, cyclohexyl, or 2-pyridinyl.

Clause 12. The compound of any one of clauses 1-8, wherein
L is

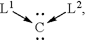

each of L1 and L2 is independently

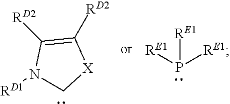

X is NR^{D1} or C(R^{D1}) (R^{D1});
R^{D1} at each occurrence is independently alkyl, cycloalkyl, optionally substituted aryl, or optionally substituted heteroaryl;
R^{D2} at each occurrence is independently alkyl, cycloalkyl, optionally substituted aryl, or optionally substituted heteroaryl; or
R^{D1} and adjacent R^{D2}, together with the nitrogen and carbon atoms to which they are attached, respectively, form a ring; or
two adjacent R^{D2}, together with the carbon atoms to which they are attached form a ring;
R^{E1} at each occurrence is independently alkyl, cycloalkyl, optionally substituted aryl, or optionally substituted heteroaryl; or
two or three R^{E1} together with the phosphorus atom to which they are attached form a ring.

Clause 13. The compound of clause 12, wherein
each of L1 and L2 is independently

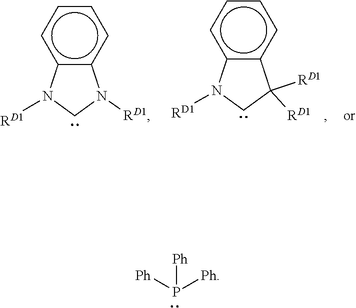

Clause 14. The compound of clause 13, wherein L is

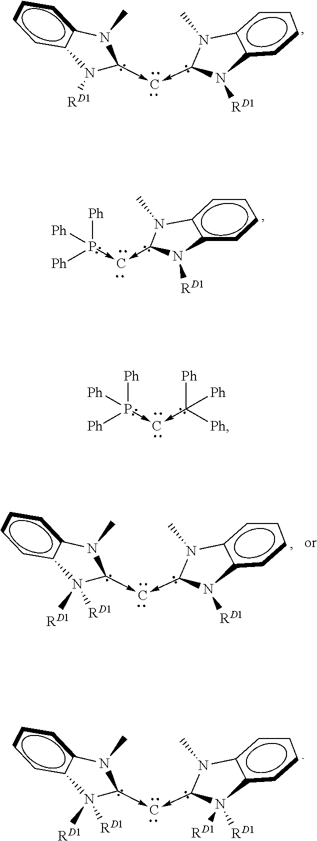

Clause 15. The compound of clause 14, wherein R^{D1} at each occurrence is independently methyl, isopropyl, cyclohexyl, or 2-pyridinyl.

Clause 16. The compound of clause 1, wherein L is

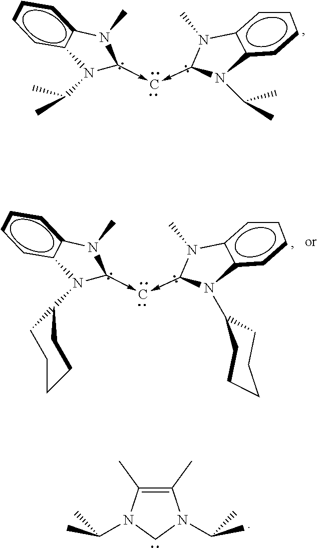

Clause 17. The compound of clause 1, which is

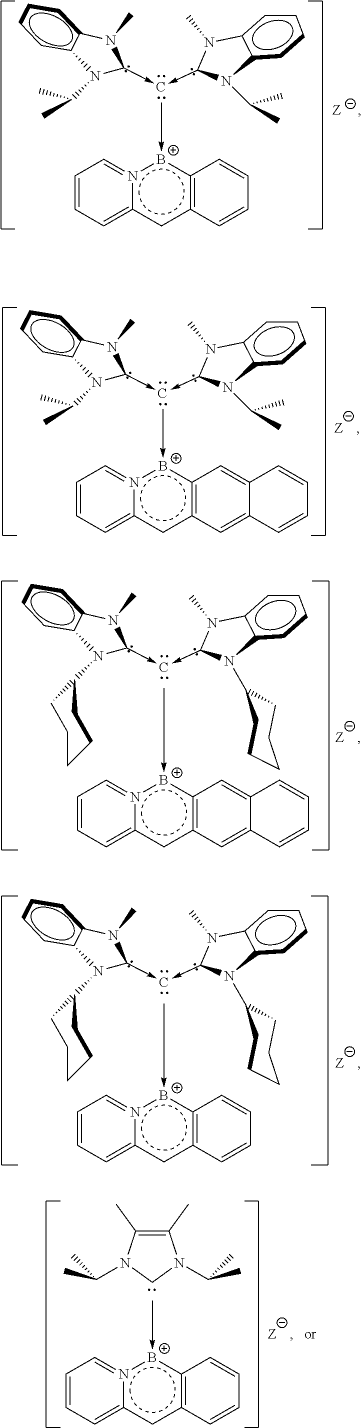

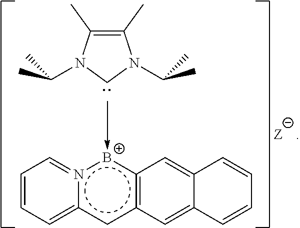

Clause 18. The compound of any one of clauses 1-17, wherein Z is Cl, Br, BF₄, BPh₄, PF₆, SbF₆, B[3,5-(CF₃)₂C₆H₃]₄, or B(C₆F₅)₄.

Clause 19. The compound of clause 17, wherein Z is BPh₄.

Clause 20. A method of preparing the compound of formula (I-a), (I-b), or (I-c) of clause 1, the method comprising reacting a compound of formula (II-a), (II-b), or (II-c), respectively, with L and M⁺Z′, thereby producing the compound of formula (I-a), (I-b), or (I-c), respectively

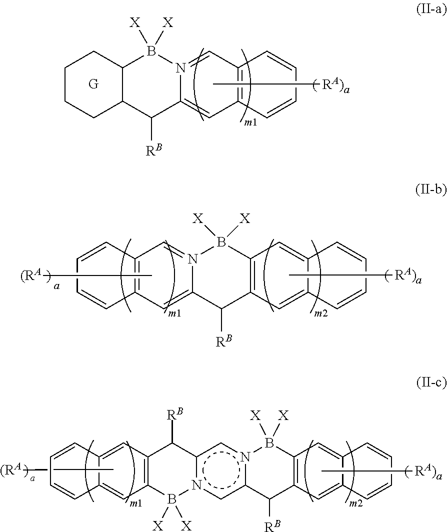

wherein
X is halogen; and
M is a metal ion.

Clause 21. The method of clause 20, further comprising converting a compound of formula (III-a), (III-b), or (III-c) to the compound of formula (II-a), (II-b), (II-c), respectively

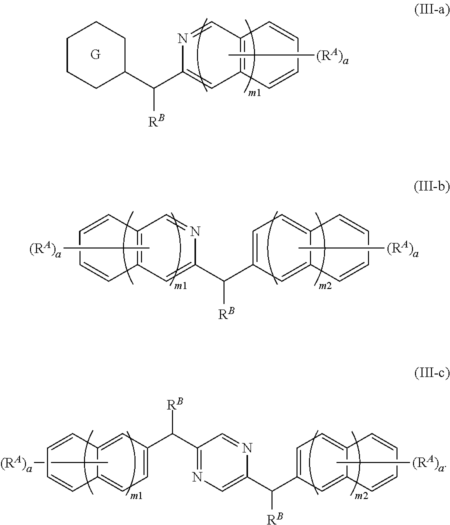

Clause 22. The method of clause 21, comprising converting the compound of (III-b) to the compound of formula (II-b), then reacting the compound of formula (II-b) with L and M⁺Z⁻, thereby producing the compound of formula (I-b).

Clause 23. The method of clause 22, comprising converting the compound of formula (III-b) to a compound of formula (IV-b), then converting the compound of formula (IV-b) to the compound of formula (II-b)

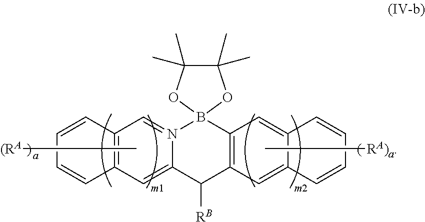

Clause 24. The method of any one of clauses 22-23, wherein m1 is 0.

Clause 25. The method of any one of clauses 22-24, wherein a is 0.

Clause 26. The method of any one of clauses 22-25, wherein m2 is 0 or 1.

Clause 27. The method of any one of clauses 22-26, wherein R^{B} is hydrogen.

Clause 28. The method of any one of clauses 22-27, wherein L is

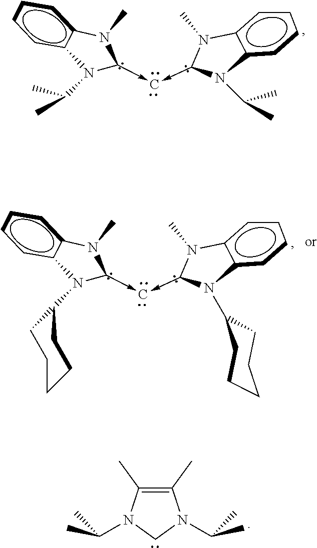

Clause 29. The method of any one of clauses 22-28, wherein the compound of formula (I-b) is

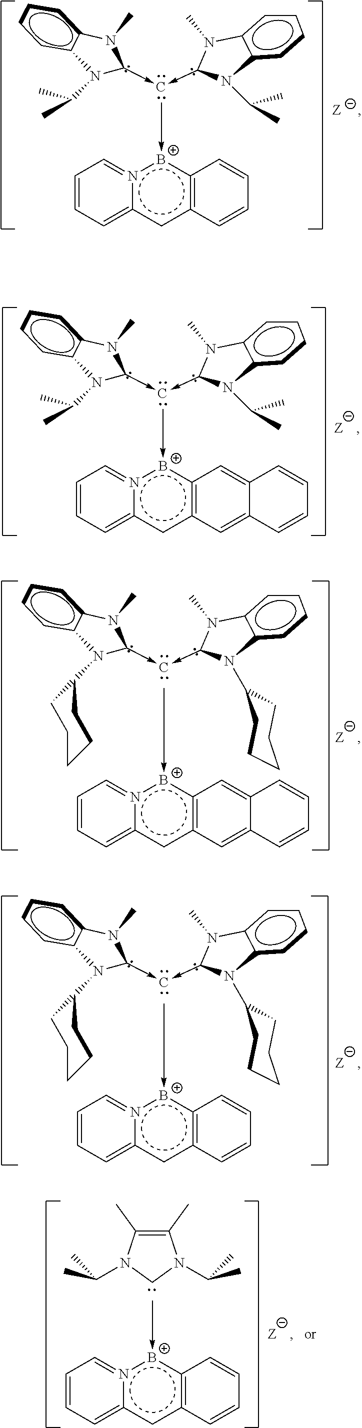

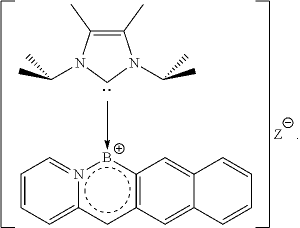

Clause 30. The method of any one of clauses 20-29, wherein Z is BPh₄.

Clause 31. The method of any one of clauses 20-30, wherein X is Cl.

Clause 32. The method of any one of clauses 20-31, wherein the reaction of the compound of formula (II-a), (II-b), or (II-c) with L and M Z is carried out under a light-free condition.

Clause 33. The method of clause 32, wherein the reaction is carried out at a temperature of 0-30° C.

Clause 34. An organic field-effect transistor device, comprising:
a source terminal;
a drain terminal;
a semiconductor channel comprising the compound of clause 1 electrically connecting the source terminal and the drain terminal; and
a gate terminal proximal to the semiconductor channel and electrically isolated from the source terminal, the drain terminal, and the semiconductor channel.

Clause 35. A method for controlling the flow of an electric current, comprising:
providing an organic field-effect transistor device comprising:
   a source terminal,
   a drain terminal,
   a semiconductor channel comprising the compound of clause 1 electrically connecting the source terminal and the drain terminal, and
   a gate terminal proximal to the semiconductor channel and electrically isolated from the source terminal, the drain terminal, and the semiconductor channel;
providing an electric current to the source terminal; and
applying an electric voltage to the gate terminal.

Clause 36. A photoluminescent emitter, comprising:
an anode;
a cathode; and
an emissive layer comprising the compound of clause 1, electrically connecting the anode and the cathode.

Clause 37. A method of producing electroluminescence, comprising:
providing a photoluminescent emitter comprising:
   an anode,
   a cathode, and
   an emissive layer comprising the compound of clause 1, electrically connecting the anode and the cathode; and
applying an electrical current to the cathode.

Clause 38. A single molecule electrical device, comprising:
a first electrode;
a second electrode; and
a molecular backbone comprising the compound of clause 1 covalently attached to the first electrode and the second electrode, forming an electrically conductive connection.

Clause 39. A method of transporting electrons, comprising:
providing a single molecule electrical device comprising
   a first electrode,
   a second electrode, and
   a molecular backbone comprising the compound of clause 1 covalently attached to the first electrode and the second electrode, forming an electrically conductive connection; and
applying a stimulus to the molecular backbone.

Clause 40. The method of clause 39, wherein the stimulus is selected from the group consisting of increasing or decreasing temperature, applying an electrical bias to the first or second electrodes, mechanically pulling the molecular backbone, mechanically compressing the molecular backbone, irradiating the molecular backbone, and any combinations thereof.

Clause 41. A ratiometric biosensor, comprising:
a photoluminescent substrate comprising the compound of clause 1, comprising:
   a first optical emission, and
   a second optical emission emitted in the presence of a target analyte.

Clause 42. A method of detecting a target analyte, comprising:
providing a photoluminescent substrate comprising the compound of clause 1, comprising
   a first optical emission having a first wavelength and a first intensity, and
   a second optical emission, having a second wavelength and a second intensity,
   and emitted in the presence of a target analyte;
detecting the first optical emission;
exposing the photoluminescent substrate to the target analyte;
detecting the second optical emission; and
comparing the first optical emission to the second optical emission, thereby detecting the target analyte.

Clause 43. A singlet fission device, comprising:
a singlet fission layer comprising the compound of clause 1;
a solar cell layer comprising a semiconductor and electrical contacts;
a transition layer positioned between the singlet fission layer and the solar cell layer.

Clause 44. A method of using a singlet fission device, comprising:
providing a singlet fission device comprising:
   a singlet fission layer comprising the compound of clause 1,
   a solar cell layer comprising
      a semiconductor comprising a semiconductor bandgap, and
      electrical contacts, and
   a transition layer positioned between the singlet fission layer and the solar cell layer;
illuminating the singlet fission layer with incident photons to produce singlet fission photons comprising an energy substantially equal to the semiconductor bandgap;
absorbing the singlet fission photons with the solar cell layer thereby producing an electrical current in the solar cell layer; and
collecting the electrical current from the electrical contacts.

1. A compound of formula (I-a), (I-b), or (I-c), 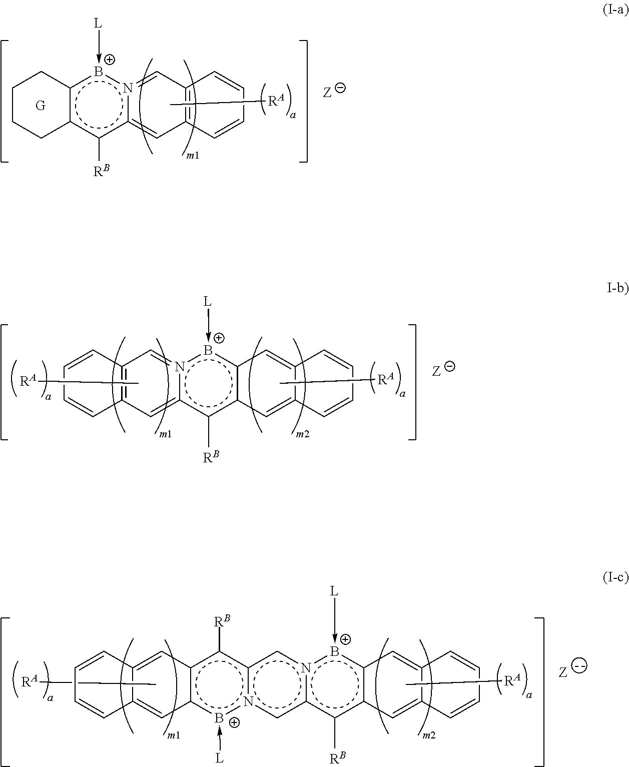
wherein
L is N-heterocyclic carbene (NHC) or a carbone having a structure of 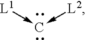
wherein each of L1 and L2 is independently a Lewis base;
G is a heteroaryl or heterocyclyl, which is optionally substituted;
R^{A} at each occurrence is independently alkyl, alkoxy, haloalkyl, aryl, cyano, halogen, N(R^{A1})(R^{A1}), S(R^{B}), or thiophenyl;
R^{B} at each occurrence is independently hydrogen, alkyl, an optionally substituted aryl, or C≡CSi(R^{B1})₃;
R^{A1} at each occurrence is independently hydrogen, alkyl, or aryl, or two R^{A1} together with the nitrogen atom to which they are attached form a ring;
R^{B1} at each occurrence is independently alkyl;
a at each occurrence is independently 0-20;
m1 is 0-10;
m2 is 0-10; and
Z is a counterion.

2. The compound of claim 1, which is a compound of formula (I-a-i) or (I-c-i) 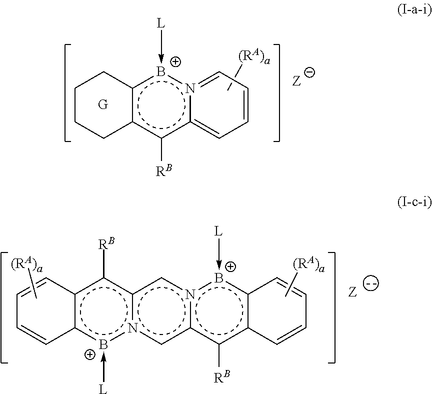
wherein a at each occurrence is independently 0, 1, 2, 3, or 4.

3. The compound of claim 1, which is a compound of formula (I-b), wherein m2 is 0 or 1.

4. The compound of claim 3, wherein m1 is 0 or 1.

5. The compound of claim 1, which is a compound of formula (I-b-i) 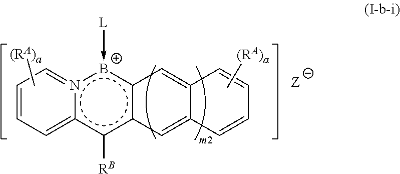
wherein
a at each occurrence is independently 0, 1, 2, 3, or 4; and
m2 is 0 or 1.

6. The compound of claim 5, wherein a at each occurrence is 0.

7. The compound of claim 1, wherein R^{A} at each occurrence is independently OMe, CN, CF₃, NMe₂, SMe, NPh₂, halogen, or Ph.

8. The compound of claim 1, wherein R^{B} is hydrogen,

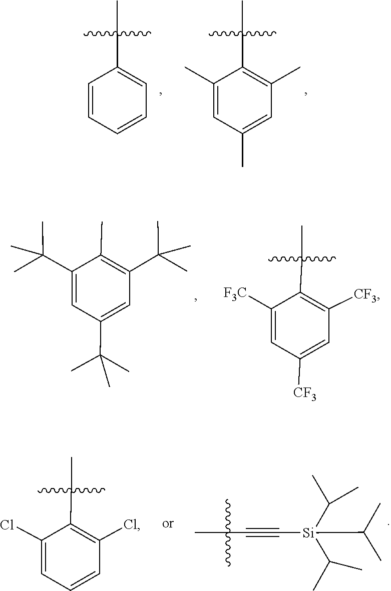

9. The compound of claim 1, wherein L is an N-heterocyclic carbene (NHC) of 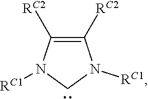
wherein
R^{C1} at each occurrence is independently alkyl, cycloalkyl, optionally substituted aryl, or optionally substituted heteroaryl;
R^{C2} at each occurrence is independently alkyl, cycloalkyl, optionally substituted aryl, or optionally substituted heteroaryl; or
R^{C1} and adjacent R^{C2}, together with the nitrogen and carbon atoms to which they are attached, respectively, form a ring; or
two adjacent R^{C2}, together with the carbon atoms to which they are attached form a ring.

10. The compound of claim 9, wherein L is

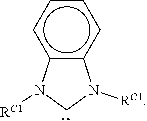

11. The compound of claim 10, wherein R^{C1} at each occurrence is independently methyl, isopropyl, cyclohexyl, or 2-pyridinyl.

12. The compound of claim 1, wherein
L is 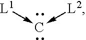
each of L1 and L2 is independently 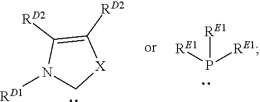
X is NR^{D1} or C(R^{D1}) (R^{D1});
R^{D1} at each occurrence is independently alkyl, cycloalkyl, optionally substituted aryl, or optionally substituted heteroaryl;
R^{D2} at each occurrence is independently alkyl, cycloalkyl, optionally substituted aryl, or optionally substituted heteroaryl; or
R^{D1} and adjacent R^{D2}, together with the nitrogen and carbon atoms to which they are attached, respectively, form a ring; or
two adjacent R^{D2}, together with the carbon atoms to which they are attached form a ring;
R^{E1} at each occurrence is independently alkyl, cycloalkyl, optionally substituted aryl, or optionally substituted heteroaryl; or
two or three R^{E1} together with the phosphorus atom to which they are attached form a ring.

13. The compound of claim 12, wherein
each of L1 and L2 is independently

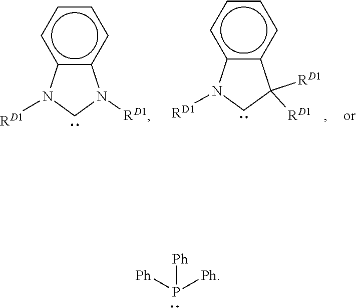

14. The compound of claim 13, wherein L is

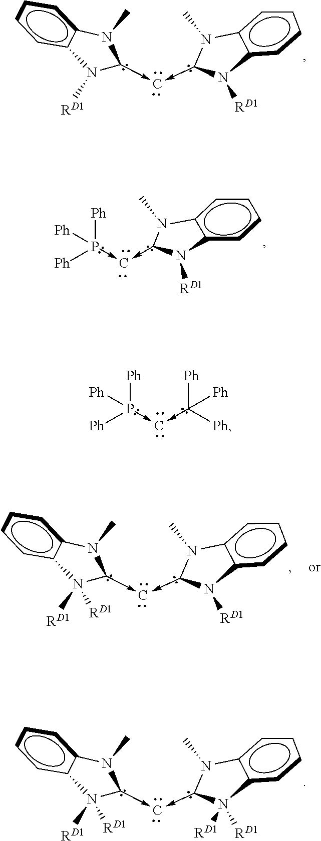

15. The compound of claim 14, wherein R^{D1} at each occurrence is independently methyl, isopropyl, cyclohexyl, or 2-pyridinyl.

16. The compound of claim 1, wherein L is

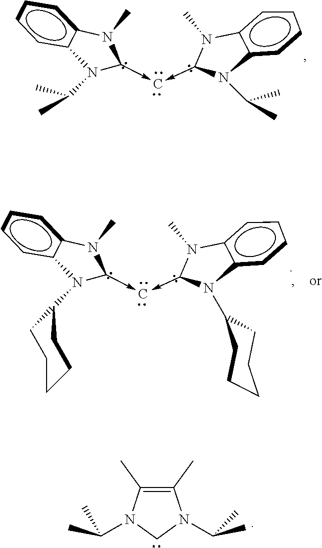

17. The compound of claim 1, which is

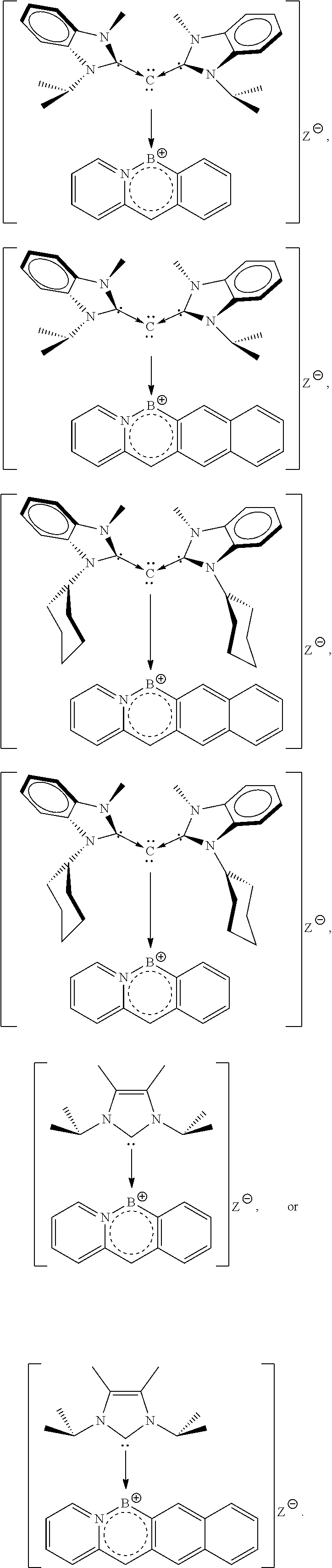

18. The compound of claim 1, wherein Z is Cl, Br, BF₄, BPh₄, PF₆, SbF₆, B[3,5-(CF₃)₂C₆H₃₁₄, or B(C₆F₅)₄.

19. The compound of claim 17, wherein Z is BPh₄.

20-33. (canceled)

34. An organic field-effect transistor device, comprising:
a source terminal;
a drain terminal;
a semiconductor channel comprising the compound of claim 1 electrically connecting the source terminal and the drain terminal; and
a gate terminal proximal to the semiconductor channel and electrically isolated from the source terminal, the drain terminal, and the semiconductor channel.

35. (canceled)

36. A photoluminescent emitter, comprising:
an anode;
a cathode; and
an emissive layer comprising the compound of claim 1, electrically connecting the anode and the cathode.

37. (canceled)

38. A single molecule electrical device, comprising:
a first electrode;
a second electrode; and
a molecular backbone comprising the compound of claim 1 covalently attached to the first electrode and the second electrode, forming an electrically conductive connection.

39. (canceled)

40. (canceled)

41. A ratiometric biosensor, comprising:
a photoluminescent substrate comprising the compound of claim 1, comprising:
a first optical emission, and
a second optical emission emitted in the presence of a target analyte.

42. (canceled)

43. A singlet fission device, comprising:
a singlet fission layer comprising the compound of claim 1;
a solar cell layer comprising a semiconductor and electrical contacts; and
a transition layer positioned between the singlet fission layer and the solar cell layer.

44. (canceled)
